(19) United States
(12) Patent Application Publication
(10) Pub. No.: US 2022/0123165 A1
(43) Pub. Date: Apr. 21, 2022

(54) MICRO LED SUCTION BODY, AND METHOD OF MANUFACTURING MICRO LED DISPLAY USING SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Sung Hyun BYUN, Gyeonggi-do (KR)

(73) Assignee: POINT ENGINEERING CO., LTD., Chungcheongnam-do (KR)

(21) Appl. No.: 17/607,030

(22) PCT Filed: May 7, 2020
(86) PCT No.: PCT/KR2020/005978

§ 371 Date: Oct. 28, 2021

(30) Foreign Application Priority Data
May 10, 2019 (KR) 10-2019-0054622

(51) Int. Cl. H01L 33/00; H01L 21/683; H01L 25/075

(52) U.S. Cl. CPC H01L 33/005; H01L 25/0753; H01L 21/6838

(57) ABSTRACT

The invention provides a micro LED suction body, and a method of manufacturing a micro LED display using the same. Proposed is a micro LED suction body for transferring micro LEDs from a first substrate to a second substrate and, more particularly, is a micro LED suction body for transferring micro LEDs by a vacuum suction method.

### BACKGROUND

### Technical Field

The present disclosure relates to a micro LED suction body that sucks micro LEDs using a vacuum suction force.

### Description of Related Art

Currently, the display market remains dominated by LCDs, but OLEDs are quickly replacing LCDs and emerging as mainstream products. In the current situation in which display makers are rushing to participate in the OLED market, micro light-emitting diode (hereinafter, referred to as micro LED) displays have emerged as another type of next generation display. Liquid crystal and organic materials are the core materials of LCDs and OLEDs, respectively, whereas the micro LED display uses 1 μm to 100 μm LED chips themselves as a light emitting material.

Since the term “micro LED” emerged in a patent “MICRO-LED ARRAYS WITH ENHANCED LIGHT EXTRACTION” in 1999 (Korean Patent No. 10-0731673, hereinafter referred to as ‘Related Art 1’) disclosed by Cree Inc., related research papers based thereon were subsequently published. In order to apply micro LEDs to a display, it is necessary to develop a customized microchip based on a flexible material and/or a flexible device using a micro LED device, and techniques of transferring micrometer-sized LED chips and accurately mounting the LED chips on a display pixel electrode are required.

Particularly, with regard to the transfer of the micro LED device to a display substrate, as the LED size is reduced to 1 μm to 100 μm, it is impossible to use a conventional pick-and-place machine, but a technology of a higher precision transfer head is required.

To meet this demand, technologies have been developed to use various forces such as electrostatic force, van der Waals force, and magnetic force instead of using vacuum suction force. Various other techniques have also been developed in association with the trend, such as that using a material whose bonding strength is variable by heat, laser, UV, electromagnetic waves, etc., that using a roller, and that using a fluid.

With respect to such a technology of a transfer head, several structures have been proposed as described below, but each proposed technology has some drawbacks.

Luxvue Technology Corp., USA, proposed a method of transferring a micro LED using an electrostatic head (Korean Patent Application Publication No. 10-2014-0112486, hereinafter referred to as ‘Related Art 2’). A transfer principle of Related Art Document 2 is that a voltage is applied to a head unit made of a silicone material so that the head unit comes into close contact with a micro LED due to electrification. However, this method may cause damage to micro LEDs due to electrification caused by the voltage applied to the head unit during induction of static electricity.

X-Celeprint Limited, USA, proposed a method of using an elastic polymer material as a transfer head and transferring micro LEDs positioned on a wafer to a desired substrate (Korean Patent Application Publication No. 10-2017-0019415, hereinafter referred to as ‘Related Art 3’). According to Related Art Document 3, there is no damage to micro LEDs as compared with the above-mentioned electrostatic head. However, adhesive force of the elastic transfer head is required to be higher than that of a target substrate in the transfer process to transfer micro LEDs stably, and an additional process for forming an electrode is required. In addition, maintaining adhesive force of the elastic polymer material is an important factor.

Korea Photonics Technology Institute proposed a method of transferring a micro LED using a ciliary adhesive-structured head (Korean Patent No. 10-1754528, hereinafter referred to as ‘Related Art 4’). However, in Related Art Document 4, it is difficult to manufacture a ciliary adhesive structure.

Korea Institute of Machinery and Materials has proposed a method of transferring a micro LED using a roller coated with an adhesive (Korean Patent No. 10-1757404, hereinafter referred to as ‘Related Art 5’). However, in Related Art Document 5, continuous use of the adhesive is required, and the micro LED may be damaged when pressed with the roller.

Samsung Display Co., Ltd proposed a method of transferring micro LEDs to an array substrate according to electrostatic induction by applying a negative voltage to first and second electrodes of the array substrate in a state in which the array substrate is immersed in a solution (Korean Patent Application Publication No. 10-2017-0026959, hereinafter referred to as ‘Related Art 6’). However, in Related Art Document 6, a solution is required since the micro LED is immersed in the solution to transfer to the array substrate, and a drying process is required.

LG Electronics Inc. proposed a method in which a head holder is disposed between multiple pick-up heads and a substrate and a shape of the head holder is deformed by movement of the multiple pick-up heads such that the multiple pick-up heads are allowed to move freely (Korean Patent Application Publication No. 10-2017-0024906, hereinafter referred to as ‘Related Art 7’). However, in Related Art Document 7, a process of applying a bonding material to the pick-up heads is required because the bonding material having adhesive force is required to be applied to bonding surfaces of the multiple pick-up heads to transfer the micro LED.

In order to solve such problems of the related arts, it is necessary to relieve the above-mentioned drawbacks while still adopting the basic principles adopted by the related arts. Since these drawbacks are derived from the basic principles adopted by the related arts, there is a limit to relieving the drawbacks while maintaining the basic principles. Accordingly, the applicant(s) of the present disclosure intends to propose a novel transfer method that has not been considered in the related arts, rather than merely relieving the drawbacks of the related arts.

### DOCUMENTS OF RELATED ART

### Patent Document

(Patent Document 1) Korean Patent No. 10-0731673;
(Patent Document 2) Korean Patent Application Publication No. 10-2014-0112486;
(Patent Document 3) Korean Patent Application Publication No. 10-2017-0019415;
(Patent Document 4) Korean Patent No. 10-1754528;
(Patent Document 5) Korean Patent No. 10-1757404;
(Patent Document 6) Korean Patent Application Publication No. 10-2017-0026959; and
(Patent Document 7) Korean Patent Application Publication No. 10-2017-0024906

### SUMMARY

### Technical Problem

Accordingly, the present disclosure has been made keeping in mind the above problems of micro LED transfer heads occurring in the related art, and an objective of the present disclosure is to provide a micro LED suction body adopting a vacuum-suction structure capable of being used for transferring micro LEDs.

### Technical Solution

In order to accomplish the above objective, one aspect of the present disclosure provides a micro LED suction body including: a suction member embodied by an anodic aluminum oxide film having vertical pores; and a support member having arbitrary pores and configured to support the suction member, wherein the suction member may include suction regions configured to suck micro LEDs using a vacuum suction force and a non-suction region configured not to suck the micro LEDs, and selectively transfers the micro LEDs.

Furthermore, the suction regions may be formed by removing a barrier layer formed during manufacture of the anodic aluminum oxide film so that the vertical pores are formed to have open upper and lower ends.

Furthermore, the suction regions may be formed by suction holes having open upper and lower ends and having a width larger than that of the vertical pores formed during manufacture of the anodic aluminum oxide film.

Furthermore, the non-suction region may be formed by a shielding portion that closes at least one of the upper and lower ends of the vertical pores formed during manufacture of the anodic aluminum oxide film.

Furthermore, the shielding portion may be a barrier layer formed during manufacture of the anodic aluminum oxide film.

Furthermore, the micro LED suction body may further include a buffer part provided on the suction member.

Another aspect of the present disclosure provides a micro LED suction body including: a suction member embodied by an anodic aluminum oxide film having vertical pores, and including suction regions configured to suck micro LEDs using a vacuum suction force applied through suction holes having a width larger than that of the vertical pores, and a non-suction region configured not to suck the micro LEDs by being equipped with a shielding portion configured to close at least one of upper and lower ends of the vertical pores; and a support member configured to support the suction member.

Another aspect of the present disclosure provides a micro LED suction body including: a suction member embodied by an anodic aluminum oxide film having vertical pores, and including suction regions configured to suck micro LEDs using a vacuum suction force applied through the vertical pores, and a non-suction region configured to not suck the micro LEDs by closing at least one of the upper and lower ends of the vertical pores; and a support member supporting the suction member.

Another aspect of the present disclosure provides a micro LED suction body including: a suction member including suction regions configured to suck micro LEDs using a vacuum suction force and a non-suction region configured not to suck the micro LEDs; and a support member formed separately from the suction member, and having a pore structure through which the suction force of a vacuum chamber is distributed and transmitted to the suction regions.

Another aspect of the present disclosure provides a micro LED suction body including: a suction member including suction regions configured to suck micro LEDs using a vacuum suction force and a non-suction region configured not to suck the micro LEDs; and a support member provided on a side opposite to a suction surface of the suction member and having arbitrary pores being in air communication with the suction regions.

Another aspect of the present disclosure provides a micro LED suction body including: a suction member including suction regions configured to suck micro LEDs using a vacuum suction force and a non-suction region configured to not to suck the micro LEDs; and a support member configured to support the suction member by sucking the non-suction region of the suction member using the vacuum suction force, and allow the micro LEDs to be sucked on the suction regions by performing air communication with the suction member.

Another aspect of the present disclosure provides a micro LED suction body including: a suction member sucking micro LEDs, and including suction regions configured to suck micro LEDs and a non-suction region configured not to suck the micro LEDs; a support member provided on the suction member and embodied by a porous material; and a vacuum chamber, wherein a vacuum pressure of the vacuum chamber may be reduced by the porous material of the support member and then transmitted to the suction regions of the suction member, thereby causing the micro LEDs to be sucked, and the vacuum pressure of the vacuum chamber is transmitted to the non-suction regions of the suction member through the porous material of the support member, thereby causing the suction member to be sucked.

Furthermore, the suction regions are formed by suction holes passing through the suction member from top to bottom, and the non-suction region may be a region where the suction holes are not formed.

Furthermore, the suction member may be made of at least one of an anodic aluminum oxide film, a wafer substrate, Invar, a metal, a non-metal, a polymer, paper, a photoresist, and PDMS.

Another aspect of the present disclosure provides micro LED suction body including: a suction member including suction regions each of which being formed by a through-hole and configured to suck micro LEDs and a non-suction region not provided with the through-hole, the suction member being embodied by a wafer substrate; and a support member having arbitrary pores and supporting the suction member, wherein a vacuum pressure may be reduced by the arbitrary pores of the support member and then transmitted to the through-holes of the suction member, thereby causing the micro LEDs to be sucked, and the vacuum pressure is transmitted to the non-suction regions of the suction member through the arbitrary pores of the support member, thereby causing the suction member to be sucked.

Furthermore, the micro LED suction body may further include: a protrusion provided outside the suction member, and formed to protrude from a suction surface of the suction member.

Furthermore, the protrusion may be made of an elastic material.

Furthermore, the protrusion may be embodied by a porous member.

Furthermore, the micro LED suction body may selectively suck the micro LEDs disposed on a first substrate, an x-direction pitch of the suction regions may be three times an x-direction pitch of the micro LEDs disposed on the first substrate, and a y-direction pitch of the suction regions may be equal to a y-direction pitch of the micro LEDs disposed on the first substrate.

Furthermore, the micro LED suction body may selectively suck the micro LEDs disposed on a first substrate, an x-direction pitch of the suction regions may be three times an x-direction pitch of the micro LEDs disposed on the first substrate, and a y-direction pitch of the suction regions may be three times a y-direction pitch of the micro LEDs disposed on the first substrate.

Furthermore, the micro LED suction body may selectively suck the micro LEDs disposed on a first substrate, and a diagonal-direction pitch of the suction regions may be equal to a diagonal-direction pitch of the micro LEDs disposed on the first substrate.

Furthermore, the micro LED suction body may selectively suck the micro LEDs disposed on a first substrate, an x-direction pitch of the suction regions may be twice an x-direction pitch of the micro LEDs disposed on the first substrate, and a y-direction pitch of the suction regions may be twice a y-direction pitch of the micro LEDs disposed on the first substrate.

Furthermore, the micro LED suction body may selectively suck the micro LEDs disposed on a first substrate, and a first-direction pitch of the suction regions may be M/3 times a first-direction pitch of the micro LEDs disposed on the first substrate, wherein M may be an integer equal to or greater than 4.

Another aspect of the present disclosure provides a method of manufacturing a micro LED display using the micro LED suction body.

Another aspect of the present disclosure provides a method of manufacturing a micro LED display, the method including: preparing a first substrate provided with micro LEDs; preparing a circuit board; and manufacturing a unit module by transferring the micro LEDs of the first substrate to the circuit board using a micro LED suction body being configured such that a first-direction pitch of suction regions is M/3 times a first-direction pitch of the micro LEDs disposed on the first substrate, in which M may be an integer equal to or greater than 4.

Furthermore, the method may further include: preparing a display wiring board; and mounting the unit module on the display wiring board by transferring the unit module to the display wiring board so that a micro LED pixel array in the display wiring board is formed to correspond to a micro LED pixel array in the unit module and a pixel pitch of the pixel array in the display wiring board is equal to a pixel pitch of the pixel array in the unit module.

Furthermore, the preparing of the first substrate provided with the micro LEDs may be a preparation step of manufacturing the micro LEDs on a growth substrate through an epitaxial process, or a preparation step of transferring the micro LEDs from the growth substrate to a carrier substrate.

Furthermore, the preparing of the first substrate provided with the micro LEDs may be a preparation step of providing the same type of micro LEDs to be arranged at a regular pitch, or a preparation step of providing different types of micro LEDs to form a pixel array.

Furthermore, the manufacturing of the unit module may be performed such that the different types of micro LEDs are mounted on the circuit board to form a pixel array.

Another aspect of the present disclosure provides a micro LED display including: a display wiring board; and multiple unit modules coupled to the display wiring board, wherein each of the unit modules may be constructed by mounting micro LEDs on a circuit board, a micro LED pixel array in the display wiring board may be formed to correspond to a micro LED pixel array in the unit module, and a pixel pitch of the pixel array in the display wiring board may be equal to a pixel pitch of the pixel array in the unit module.

### Advantageous Effects

As described above, a micro LED suction body according to the present disclosure can transfer micro LEDs from a first substrate to a second substrate using a vacuum suction force.

### BRIEF DESCRIPTION OF THE DRAWINGS

FIG. 1 is a view illustrating micro LEDs to be transferred by an embodiment of the present disclosure.

FIG. 2 is a view illustrating a micro LED structure transferred to a display substrate and mounted by the embodiment of the present disclosure.

FIG. 3 is a view illustrating a micro LED suction body according to a first embodiment of the present disclosure.

FIG. 4 is a view illustrating a micro LED suction body according to a second embodiment of the present disclosure.

FIGS. 5 to 7 are views illustrating modified examples of the second embodiment of the present disclosure.

FIG. 8 is a view illustrating a micro LED suction body according to a third embodiment of the present disclosure.

FIG. 9(a) is a view illustrating a fourth embodiment of the present disclosure.

FIG. 9(b) is a view illustrating a fifth embodiment of the present disclosure.

FIG. 10 is a view illustrating a sixth embodiment of the present disclosure.

FIGS. 11 to 13 are views illustrating an embodiment of a protrusion provided at the micro LED suction body according to the present disclosure.

FIG. 14 is a view illustrating an embodiment of a suction pipe constituting the micro LED suction body of the present disclosure.

FIGS. 15 to 17 are views illustrating embodiments of a suction region.

FIG. 18 is a view schematically illustrating a process of manufacturing a micro LED display using the micro LED suction body according to the present disclosure.

### DESCRIPTION OF THE EMBODIMENTS

Contents of the description below merely exemplify the principle of the disclosure. Therefore, those of ordinary skill in the art may implement the theory of the disclosure and invent various apparatuses which are included within the concept and the scope of the disclosure even though it is not clearly explained or illustrated in the description. Furthermore, in principle, all the conditional terms and embodiments listed in this description are clearly intended for the purpose of understanding the concept of the present disclosure, and one should understand that this disclosure is not limited to the exemplary embodiments and the conditions.

The above described objectives, features, and advantages will be more apparent through the following detailed description related to the accompanying drawings, and thus those of ordinary skill in the art may easily implement the technical spirit of the disclosure.

The embodiments of the present disclosure will be described with reference to cross-sectional views and/or perspective views which schematically illustrate ideal embodiments of the present disclosure. For explicit and convenient description of the technical content, sizes or thicknesses of films and regions and diameters of holes in the figures may be exaggerated. Therefore, variations from the shapes of the illustrations as a result, for example, of manufacturing techniques and/or tolerances, are to be expected. In addition, a limited number of multiple micro LEDs are illustrated in the drawings. Thus, the embodiments should not be construed as limited to the particular shapes of regions illustrated herein but are to include deviations in shapes that result, for example, from manufacturing.

Wherever possible, the same reference numerals will be used throughout different embodiments and the description to refer to the same or like elements or parts. In addition, the configuration and operation already described in other embodiments will be omitted for convenience.

Prior to describing exemplary embodiments of the present disclosure hereinbelow with reference to the accompanying drawings, a micro device may include a micro LED. A micro LED is not a package type covered with molding resin or the like, but a piece obtained by cutting it out from a wafer used for crystal growth, and scientifically refers to that with a size of 1 μm to 100 μm. However, the micro LED described herein is not limited to that with a size (one side length) of 1 μm to 100 μm, and includes those with a size of 100 μm or more or less than 1 μm.

In addition, the configurations of the exemplary embodiments of the present disclosure described below may be applied to transfer of micro devices without changing the technical idea of each embodiment.

A micro LED suction body may suck a micro LED ML using a vacuum suction force.

The structure of the micro LED suction body is not limited as long as it is a structure capable of generating a vacuum suction force.

The micro LED suction body may be a carrier substrate that receives a micro LED ML from a growth substrate 101 or a temporary substrate, or may be a micro LED transfer head that absorbs a micro LED ML of a first substrate such as the growth substrate 101 or the temporary substrate and transfers the micro LED to a second substrate such as the temporary substrate or a display substrate 301.

Hereinafter, a micro LED suction body 1 according to an embodiment capable of sucking a micro LED ML using a vacuum suction force will be described as being the micro LED transfer head.

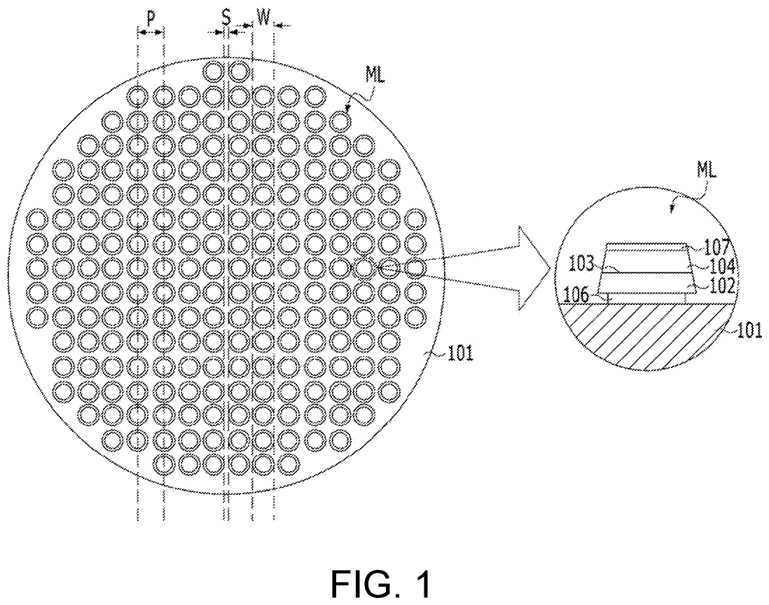

First, the micro LED ML to be transferred by the micro LED suction body 1 according to the present disclosure will be described with reference to FIG. 1.

FIG. 1 is a view illustrating multiple micro LEDs ML to be transferred by the micro LED suction body 1 according to the embodiment of the present disclosure. The micro LEDs ML are fabricated and disposed on the growth substrate 101.

The growth substrate 101 may be embodied by a conductive substrate or an insulating substrate. For example, the growth substrate 101 may be made of at least one selected from among the group consisting of sapphire, SiC, Si, GaAs, GaN, ZnO, Si, GaP, InP, Ge, and Ga203.

Each of the micro LEDs ML may include: a first semiconductor layer 102; a second semiconductor layer 104; an active layer 103 provided between the first semiconductor layer 102 and the second semiconductor layer 104; a first contact electrode 106; and a second contact electrode 107.

The first semiconductor layer 102, the active layer 103, and the second semiconductor layer 104 may be formed by performing metalorganic chemical vapor deposition (MOCVD), chemical vapor deposition (CVD), plasma-enhanced chemical vapor deposition (PECVD), molecular-beam epitaxy (MBE), hydride vapor phase epitaxy (HYPE), or the like.

The first semiconductor layer 102 may be implemented, for example, as a p-type semiconductor layer. A p-type semiconductor layer may be made of a semiconductor material having a composition formula of InxAlyGa1-x-yN (0≤x≤1, 0≤y≤1, 0≤x+y≤1) selected from among, for example, GaN, AlN, AlGaN, InGaN, InN, InAlGaN, AlInN, and the like, and the layer may be doped with a p-type dopant such as Mg, Zn, Ca, Sr, or Ba.

The second semiconductor layer 104 may be implemented, for example, as an n-type semiconductor layer. An n-type semiconductor layer may be made of a semiconductor material having a composition formula of InxAlyGa1-x-yN (0≤x≤1, 0≤y≤1, 0≤x+y≤1) selected from among, for example, GaN, AlN, AlGaN, InGaN, InN, InAlGaN, AlInN, and the like, and the layer may be doped with an n-type dopant such as Si, Ge, or Sn.

However, the present disclosure is not limited to this. The first semiconductor layer 102 may be implemented as an n-type semiconductor layer, and the second semiconductor layer 104 may be implemented as a p-type semiconductor layer.

The active layer 103 is a region where electrons and holes are recombined. As the electrons and the holes are recombined, the active layer 103 transits to a low energy level and generates light having a wavelength corresponding thereto. The active layer 103 may be made of a semiconductor material having a composition formula of InxAlyGa1-x-yN (0≤x≤1, 0≤y≤1, 0≤x+y≤1) and may have a single quantum well structure or a multi quantum well (MQW) structure. In addition, the active layer 103 may have a quantum wire structure or a quantum dot structure.

The first semiconductor layer 102 may be provided with the first contact electrode 106, and the second semiconductor layer 104 may be provided with the second contact electrode 107. The first contact electrode 106 and/or the second contact electrode 107 may include at least one layer and may be made of various conductive materials including a metal, conductive oxide, and conductive polymer.

The multiple micro LEDs ML formed on the growth substrate 101 are separated into individual pieces by cutting along a cutting line using a laser or the like or by etching. Then, it is possible to separate the individual micro LEDs ML from the growth substrate 101 by a laser lift-off process.

In FIG. 1, the letter “P” denotes a pitch between the micro LEDs ML, “S” denotes a separation distance between the micro LEDs ML, and “W” denotes a width of each micro LED ML. Although FIG. 1 illustrates the cross-section of the micro LEDs being circular, a cross-section of the micro LEDs is not limited thereto. For example, the micro LED ML may have a cross-section shape other than the circular cross-section, such as a quadrangular cross-section, according to a method of fabricating the micro LEDs ML on the growth substrate 101.

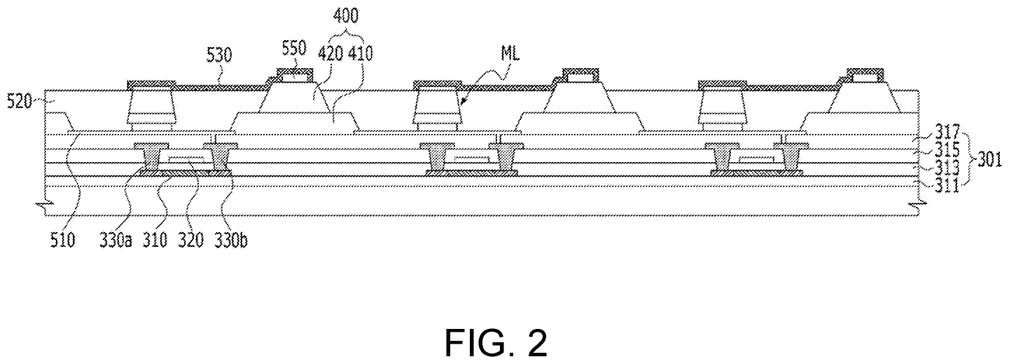

FIG. 2 is a view illustrating a micro LED structure formed by being transferred to and mounted on the display substrate 301 by the micro LED suction body according to the embodiment of the present disclosure.

The display substrate 301 may contain various materials. For example, the display substrate 301 may be made of a transparent glass material having SiO2 as a main component. However, the present disclosure is not limited thereto, and the display substrate 301 may be made of a transparent plastic material and thus have solubility. The plastic material may be an organic substance selected from among the group consisting of organic insulating substances, including polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), and cellulose acetate propionate (CAP).

In the case of a bottom emission type in which an image is implemented in a direction of the display substrate 301, the display substrate 301 is required to be made of a transparent material. However, in the case of a top emission type in which an image is implemented in a direction opposite to the display substrate 301, the display substrate 301 is not necessarily required to be made of a transparent material. In this case, the display substrate 301 may be made of a metal.

In the case of forming the display substrate 301 using metal, the display substrate 301 may be made of at least one metal selected from among the group consisting of iron, chromium, manganese, nickel, titanium, molybdenum, stainless steel (SUS), Invar alloy, Inconel alloy, and Kovar alloy, but is not limited thereto.

The display substrate 301 may include a buffer layer 311. The buffer layer 311 may provide a flat surface and block the penetration of foreign substances or moisture. For example, the buffer layer 311 may contain an inorganic substance such as silicon oxide, silicon nitride, silicon oxynitride, aluminum oxide, aluminum nitride, titanium oxide, and titanium nitride, or an organic substance such as polyimide, polyester, and acrylic. Alternatively, the buffer layer 311 may be formed into a multi-laminate of the exemplified substances.

A thin-film transistor (TFT) may include an active layer 310, a gate electrode 320, a source electrode 330a, and a drain electrode 330b.

Hereinafter, a case where the TFT is a top gate type in which the active layer 310, the gate electrode 320, the source electrode 330a, and the drain electrode 330b are sequentially formed will be described. However, the present embodiment is not limited thereto, and various types of TFTs such as a bottom gate TFT may be employed.

The active layer 310 may contain a semiconductor material, such as amorphous silicon and polycrystalline silicon. However, the present embodiment is not limited thereto, and the active layer 310 may contain various materials. As an alternative embodiment, the active layer 310 may contain an organic semiconductor material or the like.

As another alternative embodiment, the active layer 310 may contain an oxide semiconductor material. For example, the active layer 310 may contain an oxide of a metal element selected from Groups 12, 13, and 14 elements such as zinc (Zn), indium (In), gallium (Ga), tin (Sn), cadmium (Cd), and germanium (Ge), and a combination thereof.

A gate insulating layer 313 is formed on the active layer 310. The gate insulating layer 313 serves to electrically isolate the active layer 310 and the gate electrode 320. The gate insulating layer 313 may be formed into a multilayer or a single layer of a film made of an inorganic substance such as silicon oxide and/or silicon nitride.

The gate electrode 320 is provided on the gate insulating layer 313. The gate electrode 320 may be connected to a gate line (not illustrated) applying an on/off signal to the TFT.

The gate electrode 320 may be made of a low-resistivity metal. In consideration of adhesion with an adjacent layer, surface flatness of layers to be stacked, and processability, the gate electrode 320 may be formed into a multilayer or a single layer, which is made of at least one metal selected from among the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

An interlayer insulating film 315 is provided on the gate electrode 320. The interlayer insulating film 315 electrically isolates the source electrode 330a, the drain electrode 330b, and the gate electrode 320. The interlayer insulating film 315 may be formed into a multilayer or single layer of a film made of an inorganic substance. For example, the inorganic substance may be a metal oxide or a metal nitride. Specifically, the inorganic substance may include silicon dioxide (SiO2), silicon nitride (SiNx), silicon oxynitride (SiON), aluminum oxide (Al2O3), titanium dioxide (TiO2), tantalum pentoxide (Ta2O5), hafnium dioxide (HfO2), or zirconium dioxide (ZrO2).

The source electrode 330a and the drain electrode 330b are provided on the interlayer insulating film 315. The source electrode 330a and the drain electrode 330b may be formed into a multilayer or a single layer, which is made of at least one metal selected from among the group consisting of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). The source electrode 330a and the drain electrode 330b are electrically connected to a source region and a drain region of the active layer 310, respectively.

A planarization layer 317 is provided on the TFT. The planarization layer 317 is configured to cover the TFT, thereby eliminating a height difference caused by the TFT and planarizing the top surface. The planarization layer 317 may be formed into a single layer or a multilayer of a film made of an organic substance. The organic substance may include a general-purpose polymer such as polymethyl methacrylate (PMMA) and polystyrene (PS); a polymer derivative having a phenol group; an acrylic-based polymer, an imide-based polymer, an arylether-based polymer, an amide-based polymer, a fluorine-based polymer, a p-xylene-based polymer, a vinyl alcohol-based polymer; and a blend thereof. In addition, the planarization layer 317 may be formed into a multi-laminate of an inorganic insulating layer and an organic insulating layer.

A first electrode 510 is provided on the planarization layer 317. The first electrode 510 may be electrically connected to the TFT. Specifically, the first electrode 510 may be electrically connected to the drain electrode 330b through a contact hole formed in the planarization layer 317. The first electrode 510 may have various shapes, for example, may be patterned in an island layout. A bank layer 400 defining a pixel region may be disposed on the planarization layer 317. The bank layer 400 may include a receiving recess where each of the micro LEDs ML will be received. The bank layer 400 may include, for example, a first bank layer 410 defining the receiving recess. The height of the first bank layer 410 may be determined by a height and viewing angle of the micro LED ML. The size (width) of the receiving recess may be determined by resolution, pixel density, and the like, of a display device. In an embodiment, the height of the micro LED ML may be larger than the height of the first bank layer 410. The receiving recess may have a quadrangular cross-section, but the present disclosure is not limited thereto. The receiving recess may have various cross-section shapes, such as polygonal, rectangular, circular, conical, elliptical, and triangular.

The bank layer 400 may further include a second bank layer 420 on the first bank layer 410. The first bank layer 410 and the second bank layer 420 have a height difference, and the second bank layer 420 may be smaller in width than the first bank layer 410. A conductive layer 550 may be disposed on the second bank layer 420. The conductive layer 550 may be disposed in a direction parallel to a data line or a scan line, and may be electrically connected to a second electrode 530. However, the present disclosure is not limited thereto, and the second bank layer 420 may be omitted, and the conductive layer 550 may be disposed on the first bank layer 410. Alternatively, the second bank layer 420 and the conductive layer 500 may be omitted, and the second electrode 530 may be formed over the entire display substrate 301 so that the second electrode 530 serves as a shared electrode that pixels P share. The first bank layer 410 and the second bank layer 420 may contain a material absorbing at least a part of light, a light reflective material, or a light scattering material. The first bank layer 410 and the second bank layer 420 may contain an insulating material that is translucent or opaque to visible light (e.g., light in a wavelength range of 380 nm to 750 nm).

For example, the first bank layer 410 and the second bank layer 420 may be made of a thermoplastic such as polycarbonate (PC), polyethylene terephthalate (PET), polyethersulfone, polyvinyl butyral, polyphenylene ether, polyamide, polyetherimide, a norbornene system resin, a methacrylic resin, and a cyclic polyolefin system resin; a thermosetting plastic such as an epoxy resin, a phenolic resin, a urethane resin, an acrylic resin, a vinyl ester resin, an imide-based resin, an urethane-based resin, a urea resin, and melamine resin; or an organic insulating substance such as polystyrene, polyacrylonitrile, and polycarbonate, but are not limited thereto.

As another example, the first bank layer 410 and the second bank layer 420 may be made of an inorganic insulating substance such as inorganic oxide or inorganic nitride including SiOx, SiNx, SiNxOy, AlOx, TiOx, TaOx, or ZnOx, but are not limited thereto. In an embodiment, the first bank layer 410 and the second bank layer 420 may be made of an opaque material such as a black matrix material. The insulating black matrix material may include an organic resin; a resin or a paste including a glass paste and a black pigment; metal particles such as nickel, aluminum, molybdenum, an alloy thereof; metal oxide particles (e.g., chromium oxide); metal nitride particles (e.g., chromium nitride); or the like. In a modified example, the first bank layer 410 and the second bank layer 420 may be a distributed Bragg reflectors (DBRs) having high reflectivity or mirror reflectors made of a metal.

The micro LED ML is disposed in the receiving recess. The micro LED ML may be electrically connected to the first electrode 510 in the receiving recess.

The micro LED ML emits light having a wavelength of a red, green, blue, or white color and may realize white light by using a fluorescent material or by combining colored lights. The multiple micro LEDs ML may be picked up from the growth substrate 101 individually or collectively by the transfer head according to the embodiment of the present disclosure, transferred to the display substrate 301, and received in the respective receiving recesses of the display substrate 301.

The micro LED ML includes a p-n diode, the first contact electrode 106 disposed on one side of the p-n diode, and the second contact electrode 107 disposed on the opposite side of the first contact electrode 106. The first contact electrode 106 may be connected to the first electrode 510, and the second contact electrode 107 may be connected to the second electrode 530.

The first electrode 510 may include: a reflective layer made of Ag, Mg, Al, Pt, Pd, Au, Ni, Nd, Ir, Cr, or a compound thereof; and a transparent or translucent electrode layer provided on the reflective layer. The transparent or translucent electrode layer may include at least one selected from among the group consisting of indium tin oxide (ITO), indium zinc oxide (IZO), zinc oxide (ZnO), indium oxide (In2O3), indium gallium oxide (IGO), and aluminum zinc oxide (AZO).

A passivation layer 520 surrounds the micro LED ML in the receiving recess. The passivation layer 520 covers the receiving recess and the first electrode 510 by filling a space between the bank layer 400 and the micro LED ML. The passivation layer 520 may be made of an organic insulating substance. For example, the passivation layer 520 may be made of acrylic, poly (methyl methacrylate) (PMMA), benzocyclobutene (BCB), polyimide, acrylate, epoxy, polyester, or the like, but is not limited thereto.

The passivation layer 520 is formed to have a height not covering an upper portion of the micro LED ML, for example, a height not covering the second contact electrode 107, so that the second contact electrode 107 is exposed. The second electrode 530 may be formed on the passivation layer 520 electrically connected to the exposed second contact electrode 107 of the micro LED ML.

The second electrode 530 may be disposed on the micro LED ML and the passivation layer 520. The second electrode 530 may be made of a transparent conductive material such as ITO, IZO, ZnO, In2O3, or the like.

Although the vertical-type micro LED ML in which the first contact electrode 106 and the second contact electrode 107 are provided on upper and lower surfaces thereof has been described, the prevent disclosure is not limited thereto. The micro LED ML may be a lateral-type or flip-type micro LED ML in which both the first contact electrode 106 and the second contact electrode 107 are provided on any one of the upper and lower surfaces thereof. In this case, the first electrode 510 and the second electrode 530 may also be provided at appropriate positions.

### First Embodiment

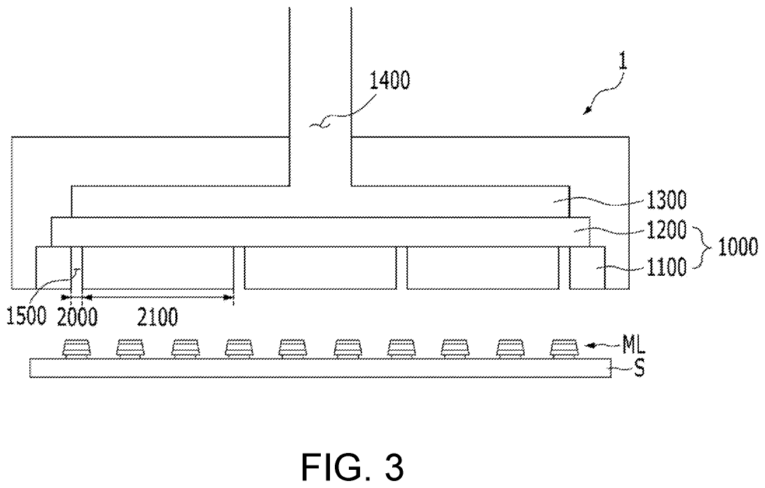

FIG. 3 is a view illustrating a micro LED suction body 1 according to a first embodiment of the present disclosure. The micro LED suction body 1 is an suction body that includes a porous member 1000 having pores, and transfers multiple micro LEDs ML from a first substrate (e.g., a grow substrate 101 or a temporary substrate) to a second substrate (e.g., a temporary substrate or a display substrate 301) by applying a vacuum to the porous member 1000 or releasing the applied vacuum.

A vacuum chamber 1300 is provided on the porous member 1000. The vacuum chamber 1300 is connected to a vacuum port providing or releasing a vacuum. The vacuum chamber 1300 functions to apply the vacuum supplied through a suction pipe 1400 to the porous member 1000 or release the applied vacuum, in response to the operation of the vacuum port. A structure of engaging the vacuum chamber 1300 with the porous member 1000 is not limited as long as it is suitable for preventing gas or air from leaking to other parts when applying the vacuum to the porous member 1000 or releasing the applied vacuum.

The porous member 1000 may contain a material having a large number of pores therein, and may be configured in the form of a powder, a thin film, a thick film, or a bulk form having an ordered or disordered pore structure with a porosity of about 0.2 to 0.95. The pores of the porous member 1000 are classified according to pore sizes thereof: micropores having a pore diameter of 2 nm or less, mesopores having a pore diameter of 2 nm to 50 nm, and macropores having a pore diameter of 50 nm or more. The porous member 1000 may include at least some of micropores, mesopores, and macropores. Porous materials of the porous member 1000 are classified according to constituent components thereof: organic, inorganic (ceramic), metal, and hybrid type. The porous member 1000 includes an anodic aluminum oxide film 1600 in which pores are formed in an ordered arrangement. The porous member 1000 may be configured in the form of a powder, a coating film, or a bulk form. The powder may have various shapes such as a sphere, a hollow sphere, a fiber, and a tube. The powder may be used as it is in some cases, but it is also possible to prepare a coating film or a bulk form with the powder as a starting material.

When the pores of the porous member 1000 has an arbitrary pore structure, the internal spaces disorderly present as a result of a manufacturing process such as sintering and foaming are connected to each other, thereby forming arbitrary pores. When the pores of the porous member 1000 have a disordered pore structure, multiple pores are connected to each other inside the porous member 1000 so that air flow paths are formed to connect upper and lower portions of the porous member 1000.

Meanwhile, when the pores of the porous member 1000 have a vertical pore structure, vertical pores are formed inside the porous member 1000 so that air flow paths are formed to pass through porous member 1000 from top to bottom. Here, the vertical pore structure means that the pores are formed in the direction from top to bottom of the porous member, and the pore shape does not mean a perfectly vertical form, but may be, for example, a form which is open at least one of the upper and lower ends, or a form which is open at both the upper and lower ends. The vertical pores may be pores formed during the manufacture of the porous member, or may be formed after the manufacture of the porous member by drilling separate holes. The vertical pores may be formed throughout the porous member, or may be formed only in a partial region of the porous member.

As described above, the arbitrary pores mean that the pores are disorderly arranged, and the vertical pores mean that the pores are vertically arranged.

As illustrated in FIG. 3, the porous member 1000 has a dual structure composed of first and second porous members 1100 and 1200.

The second porous member 1200 is provided on the first porous member 1100. The first porous member 1100 functions to vacuum-suck the micro LEDs ML and include a suction member. The second porous member 1200 is disposed between the vacuum chamber 1300 and the first porous member 1100 and functions to transfer a vacuum pressure of the vacuum chamber 1300 to the first porous member 1100 and support the first porous member 1200. The second porous member 1200 may include a support member supporting the suction member.

The first and second porous members 1100 and 1200 may have different porosity characteristics. For example, the first and second porous members 1100 and 1200 may have different characteristics in terms of the arrangement and size of the pores, and the material and the shape of the porous member 1000.

In terms of the arrangement of the pores, the first porous member 1100 may have a uniform arrangement of pores and the second porous member 1200 may have a disordered arrangement of pores. In terms of the size of the pores, any one of the first and second porous members 1100 and 1200 may have a larger pore size than the other. Here, the size of the pores may be the average size of the pores or may be the maximum size of the pores. In terms of the material of the porous member 1000, one of the first and second porous members may be made of one of organic, inorganic (ceramic), metal, and hybrid type porous materials, and the other may be made of one of organic, inorganic (ceramic), metal, and hybrid type porous materials different from the first material.

In terms of the shape of the porous member 1000, the first and second porous members 1100 and 1200 may have different shapes of pores. Specifically, the first porous member 1100 may be a porous member having an ordered arrangement of vertical pores. The first porous member 1100 is a porous member having vertical pores and includes the suction member 1100 functioning to suck the micro LEDs ML. The suction member 1100 may be: a suction member 1100 embodied by the anodized aluminum oxide film 1600, and having pores formed during manufacture or vertical pores formed by suction holes separately formed from the pores; a suction member 1100 embodied by a mask 3000 having openings 3000a, and having vertical pores formed by the openings 3000a; a suction member 1100 having vertical pores formed through laser processing; and a suction member 1100 having vertical pores formed through etching. As described above, the suction member 1100 may be configured in various structures having vertical pores. The second porous member 1200 may be a porous member having arbitrary pores formed in disordered arrangement. The second porous member 1200 may include the support member 1200 having the arbitrary pores and supporting the structure of the suction member 1100.

By varying the arrangement, size, material, and shape of the pores of the first and second porous members 1100 and 1200 as described above, the micro LED suction body 1000 has various functions and each of the first and second porous members 1100 and 1200 performs complementary functions.

The number of the porous members is not limited to two as in the case of the first and second porous members 1100 and 1200. As long as individual porous members have mutually complementary functions, providing two or more porous members is also possible. Hereinafter, the porous member 1000 will be described as having a dual structure composed of the first and second porous members 1100 and 1200.

As described above, the second porous member 1200 may be the porous member having the arbitrary pores, and may be embodied by a porous support functioning to support the first porous member 1100. The material of the second porous member 1200 is not limited as long as it has a function of supporting the first porous member 1100. The second porous member 1200 may be embodied by a rigid porous support capable of preventing sagging at the center of the first porous member 1100. For example, the second porous member 1200 may be made of a porous ceramic material. The second porous member 1200 functions not only to prevent the first porous member 1100 provided in the form of a thin film from being deformed by the vacuum pressure, but also to allow the vacuum pressure to be distributed and transmitted to the first porous member 1100. The vacuum pressure distributed or diffused by the second porous member 1200 is transmitted to a suction region of the first porous member 1100 to suck the micro LEDs ML, and is transmitted to a non-suction region of the first porous member 1100 to allow the second porous member 1200 to suck the first porous member 1100.

Alternatively, the first porous member 1100 may be embodied by a porous buffer for buffering the contact between the first porous member 1100 and the micro LEDs ML. The material of the second porous member 1200 is not limited as long as it has a function of buffering the first porous member 1100. The second porous member 1200 may be embodied by a soft porous buffer that helps to protect the micro LEDs ML from damage, which may occur when the micro LEDs ML and the first porous member 1100 are brought into contact with each other to suck the micro LEDs ML by vacuum. For example, the second porous member 1200 may be made of a porous elastic material such as a sponge or the like.

The first porous member 1100 includes suction regions 2000 on which the micro LEDs are sucked and a non-suction region 1130 on which the micro LEDs ML are not sucked. The suction regions 1110 are regions where vacuum of the vacuum chamber 1300 is transmitted and the micro LEDs ML are sucked. The non-suction region 1130 is a region where the vacuum of the vacuum chamber 1200 is not transmitted and thus the micro LEDs ML are not sucked.

The non-suction region 2100 may be formed by forming a shielding portion on at least a part of a surface of the first porous member 1100. The shielding portion is formed to close the pores exposed at least a part of surfaces of the first porous member 1100.

The shielding portion is not limited in material, shape, and thickness as long as it functions to close the pores exposed at the surface of the first porous member 1100. Preferably, the shielding portion may be further provided and made of a photoresist (PR, including dry film PR), PDMS, or a metal or may be provided by the structure of the first porous member 1100 itself. In the case the shielding portion is embodied by the structure of the first porous member 1100, for example, in the case the first porous member 1100 is embodied by the anodic aluminum oxide film 1600, the shielding portion may be a barrier layer or a metal base material.

The micro LED suction body 1 may be provided with a monitoring unit monitoring the degree of vacuum of the vacuum chamber 1300. The monitoring unit may monitor the degree of vacuum generated in the vacuum chamber 1300, and a control unit may control the degree of vacuum of the vacuum chamber 1300 according to the monitored degree of vacuum of the vacuum chamber 1300. When the monitoring unit monitors that the degree of vacuum of the vacuum chamber 1300 is lower than a predetermined degree of vacuum, the control unit may determine that some of the micro LEDs ML to be vacuum-sucked on the first porous member 1100 have failed to be vacuum-sucked or may determine that there is a vacuum leak, and thus instruct the micro LED suction body 1 to operate again. As described above, the micro LED suction body 1 transfers the micro LEDs ML without error in response to the degree of vacuum in the vacuum chamber 1300.

The size of a horizontal area of each of the suction regions 1110 may be smaller than that of a horizontal area of an upper surface of each micro LED ML. Thus, it is possible to vacuum-suck the micro LED ML while preventing a vacuum leak, thereby facilitating vacuum suction.

The suction regions 2000 may be configured to suit the structure of the first porous member 1100. Specifically, in the case the first porous member 1100 is embodied by the anodic aluminum oxide film 1600 including a barrier layer in which pores are not formed and a porous layer in which pores are formed, the suction regions 2000 may be formed by only the porous layer having the pores by removing at least parts of the barrier layer. Alternatively, the suction regions 2000 may be formed by suction holes 1500 formed by etching at least parts of the anodic aluminum oxide film 1600 from top to bottom and having a width larger than that of the pores of the porous layer.

On the other hand, the first porous member 1100 may be embodied by a wafer such as sapphire or a silicon wafer, and the suction region 2000 may be formed by vertical pores formed through laser processing or etching.

On the other hand, in the case the first porous member 1100 is the suction member 1100 embodied by the mask 3000 in which second openings 3000a are formed with a regular pitch, the suction regions 2000 may be provided by opening forming regions where the openings 3000a are formed. The material of the mask 3000 here is not limited as long as it can be configured in the form of a thin film.

The suction regions 1110 may be formed with a pitch equal to that of the micro LEDs ML disposed on the growth substrate 101. Thus, it is possible to collectively vacuum-suck all the micro LEDs ML from the growth substrate 101. The micro LEDs ML to be sucked on the suction regions 2000 may be disposed on the growth substrate 101, a temporary substrate, a carrier substrate, or may be disposed on the display substrate 301 or a target substrate TS. A substrate S described below may be at least one of the first substrate including the growth substrate 101, the temporary substrate, and the carrier substrate and the second substrate including the display substrate 301, the target substrate TS, a circuit board HS, the temporary substrate, and the carrier substrate.

The suction regions 2000 may be formed with a column-direction (x-direction) pitch three times a column-direction (x-direction) pitch of the micro LEDs ML disposed on the first substrate. According to the above configuration, the micro LED suction body 1 vacuum-sucks and transfers only the micro LEDs ML located at (3n)th column. Here, each of the micro LEDs ML transferred to the (3n)th column may be any one of red, green, blue, and white micro LEDs. With such a configuration, it is possible to transfer the micro LEDs ML of the same luminous color to be mounted on the second substrate with a pitch three times the column-direction (x-direction) pitch of the micro LEDs ML disposed on the first substrate. The micro LED suction body 1 may be implemented as illustrated in FIG. 3, in which the suction regions 2000 are formed with a pitch three times the column-direction (x-direction) pitch of the micro LEDs ML disposed on the first substrate. In this case, the micro LEDs ML to be sucked from the substrate S are the micro LEDs ML located at 1st, 4th, 7th, and 10th positions with reference to the left side of FIG. 3.

On the other hand, the suction regions 2000 may be formed with a row-direction (y-direction) pitch three times a row-direction (y-direction) pitch of the micro LEDs ML disposed on the first substrate. According to the above configuration, it is possible to vacuum-suck and transfer only the micro LEDs ML located at (3n)th row. Here, each of the micro LEDs ML transferred to the (3n)th row may be any one of red, green, blue, and white micro LEDs. With such a configuration, it is possible to transfer the micro LEDs ML of the same luminous color to be mounted on the second substrate with a pitch three times the row-direction (y-direction) pitch of the micro LEDs ML disposed on the first substrate.

On the other hand, the suction regions 2000 may be arranged in a diagonal direction of the micro LEDs ML disposed on the first substrate. In this case, the suction regions 2000 may be formed with a column-direction (x-direction) pitch and a row-direction (y-direction) pitch that are respectively three times the column-direction (x-direction) pitch and the row-direction (y-direction) pitch of the micro LEDs ML disposed on the first substrate. Here, each of the micro LEDs ML transferred to the (3n)th row and the (3n)th column may be any one of red, green, blue, and white micro LEDs. With such a configuration, it is possible to transfer the micro LEDs ML of the same luminous color to be mounted on the second substrate with a pitch three times the column-direction (x-direction) pitch and the row-direction (y-direction) pitch of the micro LEDs ML disposed on the first substrate, so that the micro LEDs ML of the same luminous color are transferred to diagonal positions.

The micro LED suction body 1 according to the present disclosure may transfer the micro LEDs ML in the following manner. First, the micro LED suction body 1 is moved to a position over the first substrate, and then the micro LED suction body 1 is lowered. At this point, a vacuum pressure generated in the vacuum port is applied to the porous member 1000, thereby causing the micro LEDs ML to be sucked. The micro LED suction body 1 sucks the micro LEDs ML so that the porous member 1000 of the micro LED suction body 1 is brought into intimate contact with the micro LEDs ML. However, the micro LEDs ML are likely to be damaged upon intimate contact with the porous member 1000. Thus, the micro LEDs ML may be allowed to be sucked on a lower surface of the first porous member 1100 by a vacuum suction force in a state where the lower surface of the first porous member 1100, which is the actual suction surface on which the micro LEDs ML are sucked, and upper surfaces of the micro LEDs ML are spaced apart from each other by a predetermined distance.

Then, the micro LED suction body 1 is raised while maintaining the vacuum suction force acting on the micro LEDs ML, and then moved.

Thereafter, the micro LED suction body 1 is moved to a position over the second substrate, and then the micro LED suction body 1 is lowered. At this point, the vacuum pressure applied to the porous member 1000 from the vacuum port is released, thereby allowing the micro LEDs ML to be transferred to the second substrate.

### Second Embodiment

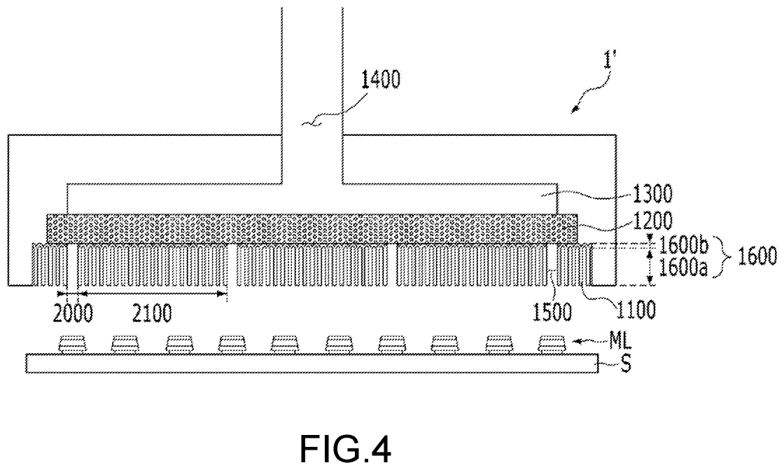

FIG. 4 is a view illustrating a micro LED suction body 1′ according to a second embodiment of the present disclosure. The micro LED suction body 1′ according to the second embodiment is configured such that the first porous member 1100 and the second porous member 1200 described in the first embodiment are respectively a suction member 1100 embodied by an anodic aluminum oxide film 1600 having vertical pores, and a support member 1200 having arbitrary pores and supporting the suction member 1100. The micro LED suction body 1′ according to the second embodiment includes the suction member 1100 and the support member 1200.

Manners of holding the suction member 1100 on the micro LED suction body 1′ include a manner of holding the suction member 1100 on the micro LED suction body 1′ using a vacuum suction force of the support member 1200, a manner of holding the suction member on the micro LED suction body 1′ using a sub-pipe separate from a pipe for forming a vacuum in the support member 1200, a manner of holding the suction member on the micro LED suction body 1′ using a physical means such as clips or clamps, or a manner of holding the suction member on the micro LED suction body 1′ using a chemical means such as an adhesive.

According to the manner of holding the suction member 1100 on the micro LED suction body 1′ using the vacuum suction force of the support member 1200, the support member 1200 sucks the suction member 1100 by sucking a non-suction region 1200 of the suction member 1100 using the vacuum suction force applied through the pores of the support member 1200.

According to the manner of holding the suction member to the micro LED suction body 1′ using the sub-pipe separate from the pipe forming the vacuum pressure in the support member 1200, the sub-pipe for sucking the suction member 1100 and a main pipe for applying the vacuum to suction regions 2000 through the support member 1200 are separately provided. Thus, the suction member 1100 is always held on the micro LED suction body 1′ using the sub-pipe, and the main pipe is operated only when the micro LED suction body 1′ sucks micro LEDs ML so that the suction member 100 sucks the micro LEDs ML. According to the above configuration using the sub-pipe separate from the main pipe, the main pipe is operated only when the micro LED suction body 1′ sucks the micro LEDs ML. Thus, it is possible to prevent vortexes from being generated by intake air caused by the operation of the main pipe before sucking the micro LEDs ML. As a result, the micro LED suction body 1′ can suck the micro LEDs ML more accurately and reliably.

The micro LED suction body 1′ according to the second embodiment of the present disclosure includes the suction member 1100 embodied by the anodic aluminum oxide film 1600 having the vertical pores, and the support member 1200 having the arbitrary pores and supporting the suction member 1100. The suction member 1100 includes the suction regions 2000 on which the micro LEDs are sucked by the vacuum suction force and the non-suction region 2100 on which the micro LEDs are not sucked, and selectively transfers the micro LEDs ML.

The suction regions 2000 may be formed removing a barrier layer 1600b formed during the manufacture of the anodic aluminum oxide film 1600 so that the vertical pores are formed to have open upper and lower ends, or may be formed by suction holes 1500 having open upper and lower ends and having a width larger than that of the vertical pores formed during the manufacture of the anodic aluminum oxide film 1600.

The non-suction region 2100 may be formed by forming a shielding portion that closes at least one of the upper and lower ends of the vertical pores formed during the manufacture of the anodic aluminum oxide film 1600, and the barrier layer 1600b formed during the manufacture of the anodic aluminum oxide film 1600 may serve as the shielding portion.

It should be noted that the second embodiment will be described with particular emphasis on characteristic components as compared with the first embodiment, and descriptions of the same or similar components as those of the first embodiment will be omitted.

The suction member 1100 is embodied by the anodic aluminum oxide film 1600 having the vertical pores, and includes the suction regions 2000 on which the micro LEDs ML are sucked by the vacuum suction force applied through the suction holes 1500 having a width larger than that of the vertical pores, and the non-suction region 2100 on which the micro LEDs ML are not sucked by being equipped with the shielding portion that closes at least one of the upper and lower ends of the vertical pores.

The anodic aluminum oxide film 1600 serving as the suction member 1100 denotes a film formed by anodizing a metal that is a base material, and the pores denote pores formed in a process of forming the anodic aluminum oxide film 1600 by anodizing the metal. For example, when the base metal is aluminum (Al) or an aluminum alloy, the anodization of the base material forms the anodic aluminum oxide film 1600 consisting of anodized aluminum (Al2O3) on a surface of the base material. The anodic aluminum oxide film 1600 thus formed includes the barrier layer 1600b in which pores are not formed and a porous layer 1600a in which pores are formed. The barrier layer 1600b is positioned on the base material, and the porous layer 1600a is positioned on the barrier layer. After removing the base material on which the anodic aluminum oxide film 1600 having the barrier layer 1600b and the porous layer 1600a is formed, only the aluminum oxide film 1600 consisting of anodized aluminum (Al2O3) remains.

The anodic aluminum oxide film 1600 has the pores that have a uniform diameter, are formed in a vertical shape, and have an ordered arrangement. Therefore, when the barrier layer 1600b is removed, the pores have a vertical structure with open upper and lower ends. This facilitates the generation of the vacuum pressure in a vertical direction.

The anodic aluminum oxide film 1600 includes the suction regions 2000 on which the micro LEDs ML are vacuum-sucked and the non-suction region 2100 on which the micro LEDs ML are not sucked. The suction regions 2000 of the anodic aluminum oxide film 1600 may be formed by removing the barrier layer 1600b formed during the manufacture of the anodic aluminum oxide film so that the vertical pores formed to have the open upper and lower ends.

Therefore, the suction member 1100 is embodied by the anodic aluminum oxide film 1600 having the vertical pores, and includes the suction regions 2000 on which the micro LEDs ML are sucked by the vacuum suction force applied through the vertical pores, and the non-suction region 2100 on which the micro LEDs ML are not sucked by closing at least one of the upper and lower ends of the vertical pores.

The support member 1200 is provided on the anodic aluminum oxide film 1600, and a vacuum chamber 1300 is provided on the support member 1200. The vacuum chamber 1300 functions to apply a vacuum to the support member 1200 and to the vertical pores of the suction member 1100 embodied by the anodic aluminum oxide film 1600 or release the applied vacuum, in response to the operation of a vacuum port providing the vacuum.

When sucking the micro LEDs ML, the vacuum applied to the vacuum chamber 1300 is transmitted to the pores of the anodic aluminum oxide film 1600 to generate a vacuum suction force for sucking the micro LEDs ML.

The suction member 1100 embodied by the anodic aluminum oxide film 1600 includes the suction regions 2000 on which the micro LEDs ML are sucked by the vacuum suction force and the non-suction region 2100 on which the micro LEDs ML are not sucked, and selectively transfers the micro LEDs ML. The suction member 1100 selectively transfers the micro LEDs ML or collectively transfers the micro LEDs ML according to the pitch of the suction regions 2000.

The suction regions 2000 of the suction member 1100 embodied by the anodic aluminum oxide film 1600 may be formed by the porous layer 1600a where the vertical pores are formed by removing at least parts of the barrier layer 1600b, or as illustrated in FIG. 4, may be formed by the suction holes 1500 having the open upper and lower ends and having a width larger than that of the vertical pores formed during the manufacture of the anodic aluminum oxide film 1600.

As described above, the suction regions 2000 may be formed by the porous layer 1600a by removing the barrier layer 1600b, or the suction regions 2000 may be formed by removing both the barrier layer 1600b and the porous layer 1600a. FIG. 4 illustrates the suction regions 2000 being formed by removing both the barrier layer 1600b and the porous layer 1600a.

In the second embodiment, as illustrated in FIG. 4, the suction regions 2000 are described as being formed by the suction holes 1500 passing through the anodic aluminum oxide film 1600 from top to bottom.

The suction member 1100 is further provided with the suction holes 1500 in addition to the pores formed naturally in the anodic aluminum oxide film 1600. The suction holes 1500 pass through upper and lower surfaces of the anodic aluminum oxide film 1600. The suction holes 1500 have a width larger than that of the pores. With such a configuration in which the suction regions 2000 on which the micro LEDs ML are sucked are formed by the suction holes 1500 having a width larger than that of the pores, it is possible to increase the vacuum suction area for the micro LEDs ML, compared to the configuration in which the micro LEDs ML are sucked only by the pores.

The suction holes 1500 may be formed by vertically etching the anodic aluminum oxide film 1600 after forming the anodic aluminum oxide film 1600 and the pores. By forming the suction holes 1500 through etching, the suction holes 1500 are easily formed without damaging the side surfaces of the pores, thereby preventing damage to the suction holes 1500.

The non-suction region 2100 may be a region where the suction holes 1500 are not formed. The non-suction region 2100 may be a region where at least one of the upper and lower ends of the pores are closed. The non-suction region 2100 may be formed by the shielding portion that closes at least one of the upper and lower ends of the vertical pores formed during the manufacture of the anodic aluminum oxide film 1600. In the second embodiment, the shielding portion may be the barrier layer 1600b formed during the manufacture of the anodic aluminum oxide film 1600. The barrier layer 1600b may be formed on at least one of the upper and lower surfaces of the anodic aluminum oxide film 1600 and may serve as the shielding portion.

As illustrated in FIG. 4, the non-suction region 2100 according to the second embodiment may be configured such that any one of the upper and lower ends of each of the vertical pores is closed by the barrier layer 1600b formed during the manufacture of the anodic aluminum oxide film 1600.

FIG. 4 illustrates that the barrier layer 1600b is positioned on the anodic aluminum oxide film 1600 and the porous layer 1300a having the pores is provided thereunder. However, the anodic aluminum oxide film 1600 illustrated in FIG. 4 may be inverted such that the barrier layer 1600b is positioned under the anodic aluminum oxide film 1600 and forms the non-suction region 2100.

Although it has been described that the non-suction region 2100 is a region where any one of the upper and lower ends of each of the pores is closed by the barrier layer 1600b, a coating layer may be further provided on the surface opposite to the surface where the barrier layer 1600b is provided so that both the upper and lower ends of each of the pores are closed. In forming the non-suction region 2100, the configuration in which both the upper and lower surfaces of the anodic aluminum oxide film 1600 are closed is advantageous in that it is possible to reduce the possibility that foreign substances remain in the pores of the non-suction region 2100 compared to the configuration in which at least one of the upper and lower surfaces of the anodic aluminum oxide film 1600 is closed.

The suction member 1100 may be made of at least one of the anodic aluminum oxide film 1600, a wafer substrate, Invar, a metal, a non-metal, a polymer, paper, a photoresist, and PDMS.

In the case the suction member 1100 is made of a metal, it is possible to prevent the generation of static electricity during the transfer of the micro LEDs ML. In the case the suction member 1100 is made of a non-metal, it is possible to minimize the influence of the suction member 1100 on the micro LEDs ML having the property of metal. In the case the suction member 1100 is made of silicone or PDMS, it is possible to function as a buffer and minimize damage which may be caused by collision between a lower surface of the suction member 1100 and upper surfaces of the micro LEDs ML. In the case the suction member 1100 is made of a resin, it is possible to facilitate the manufacture of the suction member 1100.

The suction member 1100 including the suction regions 2000 on which the micro LEDs ML are sucked by the vacuum suction force and the non-suction region 2100 on which the micro LEDs ML are not sucked may be supported by the support member 1200 having the arbitrary pores being in air communication with the suction regions 2000.

The support member 1200 may be provided on the suction member 1100 and embodied by a porous material. Specifically, the support member 1200 may be embodied by a porous material having arbitrary pores.

The support member 1200 supports the suction member 1100 by sucking the non-suction region 2100 of the suction member 1100 using the vacuum suction force and allows the micro LEDs ML to be sucked on the suction regions 2000 by performing air communication with the suction regions 2000 of the suction member 1100.

The micro LED suction body 1′ according to the second embodiment includes the suction member 1100, the support member 1200, and the vacuum chamber 1300, so that the vacuum pressure of the vacuum chamber 1300 is reduced by the porous material of the support member 1200 and then transmitted to the suction regions 2000 of the suction member 1100, thereby causing the micro LEDs ML to be sucked. In this case, the vacuum pressure of the vacuum chamber 1300 is transmitted to the non-suction regions 2100 of the suction member 1100 through the porous material of the support member 1200, thereby causing the suction member 1100 to be sucked.

As described above, the suction regions 2000 of the suction member 1100 may be formed by the porous layer 1600a where the vertical pores are formed by removing at least parts of the barrier layer 1600b, or may be formed by the suction holes 1500 having the open upper and lower ends and having a width larger than that of the vertical pores formed during the manufacture of the anodic aluminum oxide film 1600.

As illustrated in FIG. 4, the suction regions 2000 may be formed with a column-direction (x-direction) pitch three times a column-direction (x-direction) pitch of the micro LEDs ML disposed on a substrate S. Here, the substrate S may mean a first substrate (e.g., a growth substrate 101 or a temporary substrate).

In other words, the micro LED suction body 1′ may selectively suck the micro LEDs ML disposed on the first substrate by being configured such that the x-direction pitch of the suction regions 2000 is three times the x-direction pitch of the micro LEDs ML disposed on the first substrate, and a y-direction pitch of the suction regions 2000 is equal to a y-direction pitch of the micro LEDs ML disposed on the first substrate. According to the above configuration, the micro LED suction body 1′ vacuum-sucks and transfers only the micro LEDs ML located at (3n)th column of the substrate S. In this case, the micro LED suction body 1′ sucks the micro LEDs ML located at 1st, 4th, 7th, and 10th positions with reference to the left side of FIG. 4.

In a modified example of the suction regions 200 to be described later, it is also described that the column-direction (x-direction) pitch thereof is three times the column-direction (x-direction) pitch of the micro LEDs ML.

On the other hand, the micro LED suction body 1′ may selectively suck the micro LEDs ML disposed on the first substrate by being configured such that the x-direction pitch of the suction regions 2000 is three times the x-direction pitch of the micro LEDs ML disposed on the first substrate, and the y-direction pitch of the suction regions 2000 is three times the y-direction pitch of the micro LEDs ML disposed on the first substrate.

On the other hand, the micro LED suction body 1′ may selectively suck the micro LEDs ML disposed on the first substrate by being configured such that a diagonal-direction pitch of the suction regions 2000 is equal to a diagonal-direction pitch of the micro LEDs ML disposed on the first substrate.

The column-direction (x-direction) pitch and the row-direction (y-direction) pitch of the suction regions 2000 are not limited to the accompanying drawings. For example, the column-direction (x-direction) pitch or the row-direction (y-direction) pitch of the suction regions 2000 may be three times the column-direction (x-direction) pitch or the row-direction (y-direction) pitch of the micro LEDs ML disposed on the substrate S. Alternatively, the column-direction (x-direction) pitch and the row-direction (y-direction) pitch of the suction regions 2000 may be configured to be suitable for a pixel array in which the micro LEDs ML are to be transferred and disposed on a substrate (e.g., a second substrate such as a display substrate 301), such as the diagonal-direction pitch of the micro LEDs ML disposed on the substrate S.

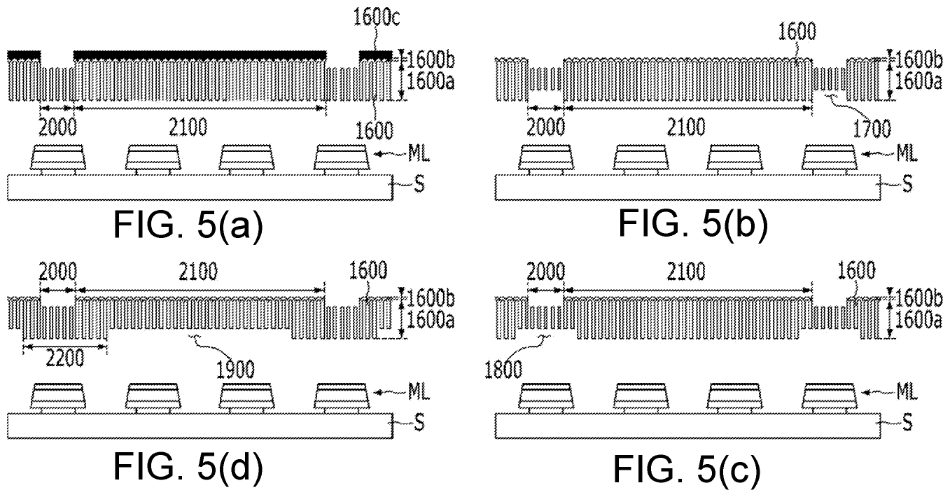

FIGS. 5 to 7 are views illustrating modified examples of the second embodiment of the present disclosure. The modified examples of the second embodiment remains the same as the second embodiment in that the suction member 1100 is embodied by the anodic aluminum oxide film 1600, but differs from the second embodiment in that the structure and configuration of the suction member 1100 in which the suction regions 2000 on which the micro LEDs ML are sucked is modified or a new configuration is further provided. However, since the following description of various modified examples of the second embodiment is to describe a special structure and configuration of the second embodiment, it is to be understood that various other configurations are within the scope of the second embodiment. Hereinafter, the suction member 1100 will be mainly described with reference to characteristic components.

FIG. 5(a) is a view illustrating a first modified example of the second embodiment. FIG. 5(a) illustrates a part of a suction member 1100 embodied by an anodic aluminum oxide film 1600 of a micro LED suction body 1′ according to the first modified example of the second embodiment. A supporting portion 1600c is further provided on a non-suction region 2100 to increase the strength of the anodic aluminum oxide film 1600. For example, the supporting portion 1600c may be a metal base material. In the case the metal base material used for the anodization is not removed and left on a barrier layer 1600b, the metal base material may serve as the supporting portion 1600c. Referring to FIG. 5(a), in the non-suction region 2100, the metal base material, the barrier layer 1600b, and a porous layer 1600a having pores are provided. In the suction regions 2000, the metal base material and the barrier layer 1600b are removed, so that the pores are formed to have open upper and lower ends. Since the pores having open upper and lower ends are formed in the suction regions 2000, the thickness of the anodic aluminum oxide film 1600 in the suction regions 2000 is smaller than that of the anodic aluminum oxide film 1600 in the non-suction region 2100. The metal base material is provided in the non-suction region 2100 to secure the strength of the anodic aluminum oxide film 1600. As the strength of the anodic aluminum oxide film 1600 which has a relatively weak strength is increased by the supporting portion 1600c, it is possible to increase the area of the micro LED suction body 1′ including the anodic aluminum oxide film 1600.

In this case, as illustrated in FIG. 5(a), the suction regions 2000 may be formed by the porous layer 1600a where the barrier layer 1600b is removed, or may be formed by the suction holes 1500 where both the barrier layer 1600b and the porous layer 1600a are removed.

FIG. 5(b) illustrates a part of a suction member 1100 embodied by an anodic aluminum oxide film 1600 of a micro LED suction body 1′ according to a second modified example of the second embodiment. Suction regions 2000 are formed by removing a base material of the anodic aluminum oxide film 1600, and removing at least parts of a barrier layer 1600b. Suction recesses 1700 are further provided at lower portions of suction regions 2000 of the anodic aluminum oxide film 1600. Each of the suction recesses 1700 has a horizontal area larger than that of pores or suction holes 1500 but smaller than that of an upper surface of a micro LED ML. Thus, the suction recesses 1700 further increase the vacuum suction area for micro LEDs ML and provide a uniform vacuum suction area for the micro LEDs ML. Each of the suction recesses 1700 may be formed by etching at least a part of a lower portion of an associated one of the suction regions 2000 of the anodic aluminum oxide film 1600 to a predetermined depth after forming the anodic aluminum oxide film 1600 and the pores.

In this case, as illustrated in FIG. 5(b), the suction regions 2000 may be formed by a porous layer 1600a where the barrier layer 1600b is removed, or may be formed by the suction holes 1500 where both the barrier layer 1600b and the porous layer 1600a are removed.

FIG. 5(c) illustrates a part of a suction member 1100 embodied by an anodic aluminum oxide film 1600 of a micro LED suction body 1′ according to a third modified example of the second embodiment. Receiving recesses 1800 are further provided at lower portions of suction regions 2000 of the anodic aluminum oxide film 1600. Each of the receiving recesses 1800 has a horizontal area larger than that of an upper surface of a micro LED ML. The micro LEDs ML are inserted and seated in the receiving recesses 1800, so that the positions of the micro LEDs ML are restricted while the micro LED suction body 1′ moves. Each of the receiving recesses 1800 may be formed by etching at least a part of a lower portion of an associated one of the suction regions 2000 of the anodic aluminum oxide film 1600 to a predetermined depth after forming the anodic aluminum oxide film 1600 and pores. In this case, since the receiving recess 1800 has a larger horizontal area than the upper surface of the micro LED ML, the anodic aluminum oxide film 1600 may have a form in which at least a part of a lower portion of a non-suction region 2100 is etched to a predetermined depth due to the shape of the receiving recess 1800. The suction regions 2000 are formed by removing a base material of the anodic aluminum oxide film 1600, and removing at least parts of a barrier layer 1600b.

On the other hand, unlike illustrated in FIG. 5(c), the suction regions 2000 may be formed by suction holes 1500 where both the barrier layer 1600b and a porous layer 1600a are removed. In this case, the receiving recesses 1800 may be formed at lower portions of the suction holes 1500 to have a width larger than that of the suction holes 1500.

FIG. 5(d) illustrates a part of a suction member 1100 embodied by an anodic aluminum oxide film 1600 of a micro LED suction body 1′ according to a fourth modified example of the second embodiment. An escape recess 1900 is further provided at a lower portion of a non-suction region 2100 of the anodic aluminum oxide film 1600. When lowering the micro LED suction body 1′ to vacuum-suck micro LEDs ML at a predetermined position, column, or row, the escape recess 1900 functions to prevent the interference with micro LEDs ML which are not to be sucked. The escape recess 1900 may be formed by etching at least a part of a lower portion of the non-suction region 2100 to a predetermined depth. As the escape recess 1900 is formed, protruding regions 2200 are formed around the escape recess 1900 of the suction member 1100. Suction regions 2000 are centrally formed in the protruding regions 2200. The micro LEDs ML are sucked on the suction regions 2000 as the micro LEDs ML are sucked on lower portions of the protruding regions 2200. Each of the protruding regions 2200 may have a horizontal area equal to or larger than that of an upper surface of a micro LED ML, and each of the suction regions 2000 centrally formed in the protruding regions 2200 by removing a barrier layer 1600b may have a width smaller than that of the upper surface of the micro LED ML in order to prevent a vacuum leak. The suction regions 2000 are formed by removing a base material of the anodic aluminum oxide film 1600, and removing at least parts of a barrier layer 1600b.

On the other hand, unlike illustrated in FIG. 5(d), the suction regions 2000 may be formed by suction holes 1500 where both a barrier layer 1600b and a porous layer 1600a are removed.

The horizontal area of the escape recess 1900 is larger than that of at least one micro LED ML. FIG. 5(d) illustrates that the escape recess 1900 has a horizontal area equal to a value obtained by summing twice the horizontal area of two micro LEDs ML and twice the horizontal pitch between the micro LEDs ML. Thus, when lowering the micro LED suction body 1′ to vacuum-suck the micro LEDs ML to be sucked, it is possible to prevent the interference with the micro LEDs ML not to be sucked.

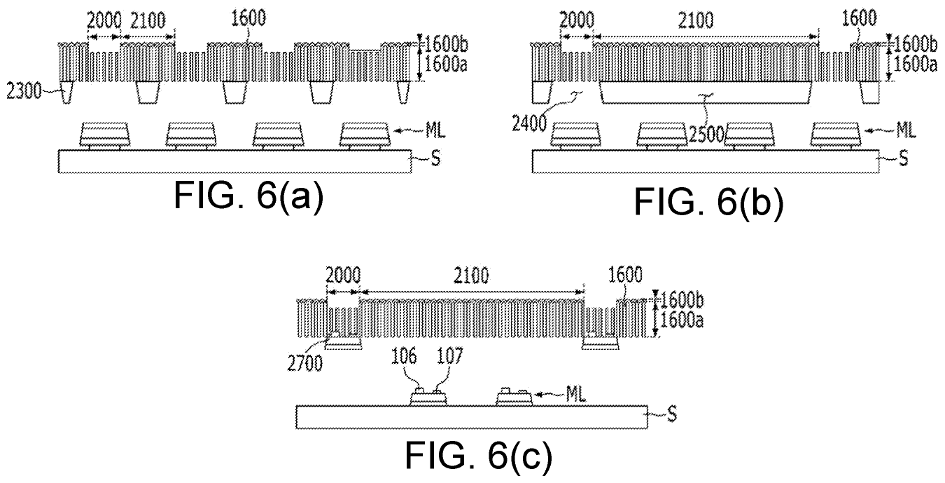

FIG. 6(a) illustrates a part of a suction member 1100 embodied by an anodic aluminum oxide film 1600 of a micro LED suction body 1′ according to a fifth modified example of the second embodiment. The suction member 1100 according to the fifth modified example includes suction regions 2000 formed by removing a base material of the anodic aluminum oxide film 1600, and removing at least parts of a barrier layer 1600b. On the other hand, the suction regions 2000 may be formed by suction holes 1500 where both the barrier layer 1600b and a porous layer 1600a are removed.

The suction member 1100 according to the fifth modified example is provided with a first protrusion dam 2300 at a lower portion thereof. Specifically, the first protruding dam 2300 is provided at a lower portion of a non-suction region 2100 of the suction member 1100. The first protruding dam 2300 may be provided at the lower portion of the non-suction region 2100 in a shape surrounding the suction regions 2000.

The first protruding dam 2300 may be made of a photoresist (PR, including dry film PR), PDMS, or a metal. The material of the first protruding dam 2300 is not limited as long as it can be formed on a surface of the suction member 1100 to have a predetermined height. The first protruding dam 2300 may be made of an elastic material.

The cross-sectional shape of the first protruding dam 2300 may be any protruding shape such as a quadrangle, a circle, and a triangle. The cross-sectional shape of the first protruding dam 2300 may be configured in consideration of the shape of the micro LEDs ML. For example, in the case the micro LEDs ML have a structure in which an upper portion thereof is wider than a lower portion thereof, when the first protruding dam 2300 has a structure in which a lower portion thereof has a narrower cross-section than an upper portion thereof, it is advantageous in terms of prevention of the interference between the first protruding dam 2300 and the micro LEDs ML. Referring to FIG. 6(a), the first protruding dam 2300 has a cross-section tapered downward.

When lowering the micro LED suction body 1′ to the suction position to vacuum-suck the micro LEDs ML disposed on a growth substrate 101, an error in a driving means of the micro LED suction body 1′ may cause erroneous contact between the suction member 1100 and the micro LEDs ML, leading to damage to the micro LEDs ML.

In order to prevent damage to the micro LEDs ML, it is preferable that a lower surface of the suction member 1100 and upper surfaces of the micro LEDs ML are spaced apart from each other at the position where the micro LED suction body 1′ sucks the micro LEDs ML. However, when such a gap exists between the lower surface of the suction member 1100 and the micro LEDs ML, a larger vacuum pressure is required compared to the case where the micro LEDs ML and the suction member 1100 are in contact with each other.

However, the configuration in which the first protruding dam 2300 is provided at the lower portion of the non-suction region 2100 of the suction member 1100 according to the fifth modified example reduces the amount of air flowing into the suction regions 2000 from the peripheral region. Thus, the suction member 1100 can vacuum-suck the micro LEDs ML by a smaller vacuum pressure compared to the configuration in which the first protruding dam 2300 is not provided.

FIG. 6(b) illustrates a part of a suction member 1100 embodied by an anodic aluminum oxide film 1600 of a micro LED suction body 1′ according to a sixth modified example of the second embodiment. The sixth modified example may include depressions 2400 provided in a lower surface of the suction member 1100. The suction member 1100 includes suction regions 2000 formed by removing a base material of the anodic aluminum oxide film 1600, and removing at least parts of a barrier layer 1600b. On the other hand, the suction regions 2000 may be formed by suction holes 1500 where both the barrier layer 1600b and a porous layer 1600a are removed.

The depressions 2400 are provided on lower surfaces of the suction regions 2000 of the suction member 1100 and function to provide spaces where micro LEDs ML are inserted when the micro LED suction body 1′ sucks the micro LEDs ML.

The depressions 2400 have a shape depressed on the lower surface of the suction member 1100. The depressions 2400 may have a circular or quadrangular cross-section. The shape of the depressions 2400 may vary depending on the cross-sectional shape of the micro LEDs ML. For example, when the micro LEDs ML have a quadrangular cross-section, the depressions 2400 may have a quadrangular cross-section corresponding to the cross-sectional shape of the micro LEDs ML.

The depressions 2400 may be formed by further providing a land 2500 on the lower surface of the suction member 1100.

When the micro LEDs ML are sucked and inserted into the depressions 2400, upper surfaces of the micro LEDs ML are brought into contact with the regions of the lower surface of the suction member 1100 where the depressions 2400 are formed. Therefore, the regions of the lower surface of the suction member 1100 where the depressions 2400 are formed serve as the suction regions 2000.

Each of the depressions 2400 has an inclined portion 2400a inclined outwardly from top to bottom of the micro LED suction body F. As the inclined portion 2400a is formed, the cross-sectional area of the depression 2400 increases from top to bottom of the micro LED suction body F. Here, the cross-sectional area means an area on a horizontal plane parallel to a lower surface of the micro LED suction body F. The cross-sectional area of the depression 2400 decreases from bottom to top due to the shape of the inclined portion 2400a.

By the depressions 2400 provided on the lower surface of the suction member 1100, the land 2500 has a shape that protrudes downwardly from the suction member 1100 than the depressions 2400. The land 2500 may be provided on a lower surface of a non-suction region 2100 to form the depressions 2400 on the lower surface of the suction region 2000.

As described above, in the micro LED suction body 1′ according to the sixth modified example, as the depressions 2400 and the land 2500 are provided, the suction regions 2000 and the non-suction region 2100 are formed on the lower surface of the suction member 1100. The depressions 2400 serve as the suction regions 2000 because they allow the micro LEDs ML to be inserted thereinto and sucked on the lower surface of the suction member 1100, and the land 2500 serves as the non-suction region 2100 because it is provided on the lower surface of the non-suction region 2100.

The depressions 2400 may be formed only at positions corresponding to the micro LEDs ML to be sucked. In this case, the micro LEDs ML to be sucked in FIG. 6(b) are the micro LEDs ML at 1st and 4th positions with reference to the left side of the drawing.

When the micro LED suction body 1′ provided with the depressions 2400 sucks the micro LEDs ML, the micro LEDs ML are picked up toward the depressions 2400 by a suction force and inserted into the depressions 2400. This is because even in a state in which the upper surfaces of the micro LEDs ML and the lower surface of the micro LED suction body 1′ are controlled to be spaced apart from each other by a predetermined distance, the suction force of the suction member 1100 causes the micro LEDs ML to be picked up toward the depressions 2400.

As the suction force is generated from the suction member 1100 as described above, the micro LED suction body 1′ is controlled such that the lower surface thereof, i.e., the lower surface of the land 2500, is spaced apart from the upper surfaces of the micro LEDs ML by a predetermined distance, and the micro LED suction body 1′ picks up the micro LEDs ML.

Since the depressions 2400 have the inclined portions 2400a, when the micro LEDs ML are picked up from a growth substrate 101 and inserted into the depressions 2400, the inclined portions 2400a guide the micro LEDs ML to allow the micro LEDs ML to be sucked at correct positions. Therefore, it is possible to prevent a positional error that may occur during the vacuum suction of the micro LEDs ML, thereby enabling the micro LEDs ML to be accurately transferred to correct positions on a display substrate 301.

FIG. 6(c) illustrates a part of a suction member 1100 embodied by an anodic aluminum oxide film 1600 of a micro LED suction body 1′ according to a seventh modified example of the second embodiment. The seventh modified example includes terminal avoidance recesses 2700 formed in a surface of the suction member 1100. Suction regions 2000 are formed by removing a base material of the anodic aluminum oxide film 1600, and removing at least parts of a barrier layer 1600b. The terminal avoidance recesses 2700 may be formed to effectively vacuum-suck micro LEDs ML without the influence of terminals protruding from surfaces of the micro LEDs ML. Therefore, the terminal avoidance recesses 2700 may be formed in the surface of the suction member 1100 at respective positions corresponding to surfaces of the suction regions 2000 on which the micro LEDs ML are sucked.

The terminal avoidance recesses 2700 may have a shape corresponding to the terminals formed on the surfaces of the micro LEDs ML and the shape thereof may vary depending on the size, number, and position of the terminals. FIG. 6(c) illustrates the micro LEDs ML each having an upper surface provided with first and second terminals 106 and 107 performing the same function as first and second contact electrodes 106 and 107. In this case, the micro LED ML is a flip-type of lateral-type micro LEDs ML that has the same configuration and function as the micro LED ML described with reference to FIGS. 1 and 2, but differs only in the positions of the first and second contact electrodes 106 and 107. As illustrated in FIG. 6(c), the first and second terminals 106 and 107 may have different heights, or may have the same height. In other words, the micro LED ML is not limited to the shape illustrated in FIG. 6(c).

In the case the terminals are formed to protrude from the surfaces of the micro LEDs ML, when the micro LED suction body 1′ sucks the micro LEDs ML, the terminals may hinder the vacuum suction of the micro LED suction body 1′, thereby reducing suction force. Therefore, in the seventh modified example, the problem of a reduction in the micro LED suction force due to the protruding terminals is prevented by the terminal avoidance recesses 2700 formed in the surfaces of the suction regions 2000 of the suction member 1100 on which the micro LEDs ML are sucked.

The area of each of the terminal avoidance recesses 2700 may be larger than the area of an associated one of the terminals of the micro LED ML. The height of the each of the terminal avoidance recesses 2700 is equal to that of an associated one of the terminals of the micro LED ML. The terminal avoidance recess 2700 having the above-described area and height can facilitate the insertion of the micro LED ML into the terminal avoidance recess 2700 due to the area thereof, and allow an upper surface of the terminal of the micro LED ML to be sucked on an upper surface of the terminal avoidance recess 2700 due to the height thereof.

Each of the terminal avoidance recesses 2700 may be formed by removing at least a part of an associated one of the suction regions 2000 through etching or the like at a position corresponding to an associated one of the terminals of the micro LEDs ML so that the terminal avoidance recess 2700 has a larger area than and the same height as the terminal.

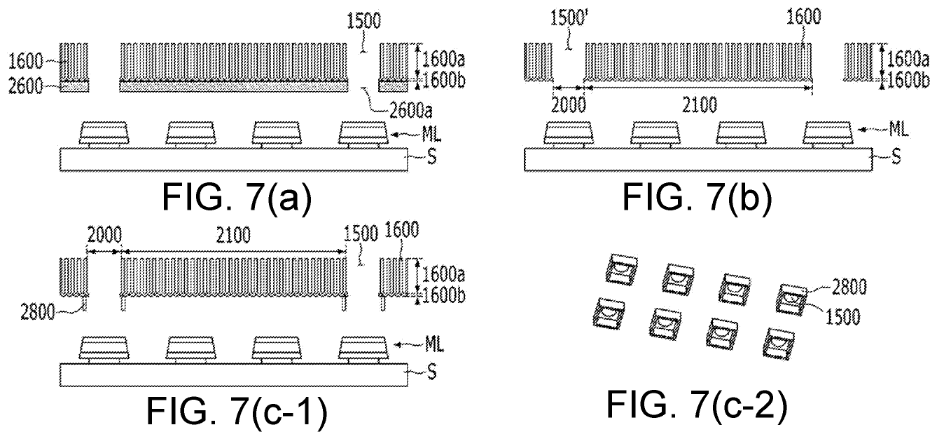

FIG. 7(a) illustrates a part of a suction member 1100 embodied by an anodic aluminum oxide film 1600 of a micro LED suction body 1′ according to an eighth modified example of the second embodiment. In the eighth modified example, a shielding portion may be formed under the suction member 1100. Specifically, the suction member 1100 according to the eighth modified example embodied by the anodic aluminum oxide film 1600 has a barrier layer 1600b formed on a lower surface of the anodic aluminum oxide film 1600. The barrier layer 1600b closes lower ends of pores, so that a non-suction region 2100 is formed in the suction member 1100. The suction member 1100 according to the eighth modified example has suction holes 1500 formed by etching to pass through the anodic aluminum oxide film 1600 from top to bottom. Suction regions 2000 are formed by the suction holes 1500.

As illustrated in FIG. 7(a), a buffer part 2600 is provided on the suction member 1100. The buffer part 2600 is provided on a suction surface of the suction member 1100 where micro LEDs ML are sucked. In other words, the buffer part 2600 is provided on a surface of the suction member 1100. The buffer part 2600 may be provided on the surface of the suction member 1100 in a shape surrounding the suction regions 2000 formed by the suction holes 1500.

The buffer part 2600 may be made of an elastic material. In this case, when detaching micro LEDs ML from a first substrate using a laser lift-off (LLO) process, the buffer part 2600 functions as a buffer to prevent damage to the micro LEDs ML. For example, in the case the first substrate is a growth substrate 101, when detaching the micro LEDs ML from the growth substrate 101 using the LLO process, the micro LEDs ML may be repelled from the growth substrate 101 toward the micro LED suction body 1′ due to the gas pressure. In this case, the buffer part 2600 made of an elastic material supports the micro LEDs ML upwardly in a state in contact with the micro LEDs ML and simultaneously functions as a buffer against the micro LEDs ML.

Also in the case the first substrate is a temporary substrate or a carrier substrate, the buffer part 2600 made of an elastic material prevents damage to the micro LEDs ML. For example, in the case GaN is selected for semiconductor materials of a first semiconductor layer 102 and a second semiconductor layer 104 of each of the micro LEDs ML, the first semiconductor layer 102 and the second semiconductor layer 104 may be damaged due to weak rigidity of GaN when the micro LED suction body 1′ and the micro LEDs ML are brought into intimate contact with each other. However, as the buffer part 2600 made of an elastic material is provided, the buffer part 2600 serves as a buffer upon the intimate contact between the micro LED suction body 1′ and the micro LEDs ML, thereby preventing damage to specific layers of the micro LEDs ML such as the first semiconductor layer 102 and the second semiconductor layer 104.

The buffer part 2600 may be made of a photoresist (PR), PDMS, or a metal, and may be formed through an exposure process. Alternatively, the buffer part 2600 may be formed through sputtering.

The buffer part 2600 is provided on the surface of the suction member 1100 except for the openings of the suction regions 2000 so that openings are formed by the suction regions 2000. The openings 2600a of the buffer part 2600 may be formed with a regular interval in the same number as the suction regions 2000, and may be formed at respective positions corresponding to the suction regions 2000.

The openings 2600a of the buffer part 2600 may be formed with a pitch equal to that of the micro LEDs ML on a substrate S. Since the openings 2600a of the buffer part 2600 and the suction regions 2000 are formed at positions corresponding to each other, the suction regions 2000 may also be formed with a pitch equal to that of the micro LEDs ML of the first substrate. With such a configuration, the micro LED suction body 1′ according to the eighth modified example can vacuum-suck the micro LEDs ML on the substrate S selectively and collectively.

The buffer part 2600 may be provided on the entire surface of the anodic aluminum oxide film 1600 except for the openings of the suction regions 2000, or may be provided on at least a part of the surface of the anodic aluminum oxide film 1600 in a shape surrounding the openings of the suction regions 2000.

FIG. 7(b) illustrates a part of a suction member 1100 embodied by an anodic aluminum oxide film 1600 of a micro LED suction body 1′ according to a ninth modified example of the second embodiment. In the ninth modified example, a barrier layer 1600b serving as a shielding portion may be formed under the suction member 1100. That is, the suction member 1100 embodied by the anodic aluminum oxide film 1600 has the barrier layer 1600b formed on a lower surface of the anodic aluminum oxide film 1600. The barrier layer 1600b closes lower ends of pores, so that a non-suction region 2100 is formed in the suction member 1100. The suction member 1100 according to the ninth modified example has suction holes 1500′ formed by etching to pass through the anodic aluminum oxide film 1600 from top to bottom. Suction regions 2000 are formed by the suction holes 1500′.

The suction holes 1500′ according to the ninth modified example may have a quadrangular cross-section. The suction holes 1500′ having a quadrangular cross-section can minimize a vacuum pressure loss area for micro LEDs ML when sucking the micro LEDs ML. In the case the suction holes 1500′ have a circular cross-section, when sucking the micro LEDs ML, an upper surface of each of the micro LEDs ML is directly brought into contact with a surface of an associated one of the suction regions 2000 in an area equal to that of each of the suction holes 1500′. However, the suction holes 1500′ having a circular cross-section may have a larger vacuum pressure loss area for sucking the micro LEDs ML than the suction holes 1500′ having a quadrangular cross-section as in the ninth modified example. For example, when the suction holes 1500′ of a circular cross-section and the suction holes 1500′ of a quadrangular cross-section have the same horizontal and vertical widths, and micro LEDs ML having the same horizontal and vertical widths are sucked by the respective suction holes 1500′, a vacuum pressure loss area for the micro LEDs ML in the suction holes 1500′ of a quadrangular cross-section can be minimized.

The pitch of the suction holes 1500′ of a quadrangular cross-section may be equal to a column-direction (x-direction) pitch and a row-direction (y-direction) pitch of the micro LEDs ML disposed on a substrate S, or may be equal to or greater than twice the same. FIG. 7(b) illustrates that the suction holes 1500′ having a quadrangular cross-section are formed with a pitch three times the column-direction (x-direction) pitch and the row-direction (y-direction) pitch of the micro LEDs ML disposed on a substrate S, and the micro LEDs ML located at the 1st and 4th positions on the substrate S are sucked on the suction regions 2000 formed by the suction hole 1500′ of the suction member 1100.

Unlike illustrated in FIG. 7(b), each of the suction holes 1500′ having a quadrangular cross-section may be formed by removing at least a part of the suction member 1100 to a predetermined depth, and the suction hole 1500′, or may be formed by further providing a communication hole having a width different from the horizontal and vertical widths of the rectangular cross-section of the suction hole 1500′.

The communication hole is formed to have a quadrangular cross-section having horizontal and vertical widths smaller than those of the quadrangular cross-section of each of the suction holes 1500′, so that an area through which air is discharged is relatively small. This ensures that the time for forming a vacuum pressure formed as the air inside the suction hole 1500′ and the communication hole is discharged to the outside during the operation of a vacuum pump can be shortened compared to the embodiment. In the case of the micro LED suction body 1′ according to the second modified example, by configuring the communication hole formed at an upper portion of the suction hole 1500′ to have smaller horizontal and vertical widths that the quadrangular cross-section of the suction hole 1500′, it is possible to obtain the effect of shortening the vacuum pressure formation time and improving the efficiency of transferring the micro LEDs ML.

Since the suction regions 2000 are formed by the suction holes 1500′, the above-described shape may be a modified example of the shape of the suction regions 2000. FIG. 7(c-1) illustrates a part of a suction member 1100 embodied by an anodic aluminum oxide film 1600 of a micro LED suction body 1′ according to a tenth modified example of the second embodiment, and FIG. 7(c-2) illustrates a perspective view of a part of a second protruding dam 2800 provided in the tenth modified example. The suction member 1100 according to the tenth modified example has the same shape as the suction member 1100 according to the eighth modified example illustrated in FIG. 7(a). A detailed description thereof will be omitted with reference to that of the eighth modified example.

First, as illustrated in FIG. 7(c-1), the micro LED suction body 1′ according to the tenth modified example includes second protruding dams 2800. The second protruding dams 2800 are provided on a lower surface of the suction member 1100 embodied by the anodic aluminum oxide film 1600 in a shape surrounding lower portions of suction regions 2000. As illustrated in FIG. 7(c-2), each of the second protruding dams 2800 is independently provided in a shape surrounding an associated one of suction holes 1500 formed in the suction member 1100, thereby surrounding an associated one of the suction regions 2000. The second protruding dams 2800 may have a shape standing independently and individually. The second protruding dams 2800 surrounds the suction regions 2000 and protrude from the lower surface of the suction member 1100. Although the second protruding dams 2800 are illustrated as having a quadrangular cross-section in FIG. 7(c-2), the shape of the second protruding dams 2800 is not limited thereto, and may be other shapes such as a circular frame.

A vacuum pressure applied to the suction regions 2000 is transmitted to the inside of the second protruding dams 2800 to generate a suction force therein. The suction member 1100 sucks micro LEDs ML using the suction force generated inside the second protruding dams 2800. When lowering the micro LED suction body 1′ to suck the micro LEDs ML, lower surfaces of the second protruding dams 2800 provided under the suction member 1100 are brought into contact with upper surfaces of the micro LEDs ML. The second protruding dams 2300 may be made of an elastic material. Therefore, the second protrusion dams 2800 can function as buffers upon contact with the micro LEDs ML, thereby enabling the micro LEDs ML to be sucked on the micro LED suction body 1′ without being damaged.

In the case the second protrusion dams 2800 is made of an elastic material, when detaching the micro LEDs ML from a first substrate using a laser lift-off (LLO) process, the second protrusion dams 2800 function as a buffer to prevent damage to the micro LEDs ML. For example, in the case the first substrate is a growth substrate 101, when detaching the micro LEDs ML from the growth substrate 101 using the LLO process, the micro LEDs ML may be repelled from the growth substrate 101 toward the micro LED suction body 1′ due to the gas pressure. In this case, the second protrusion dams 2800 made of an elastic material support the micro LEDs ML upwardly in a state in contact with the micro LEDs ML and simultaneously functions as a buffer against the micro LEDs ML.

Also in the case the first substrate is a temporary substrate or a carrier substrate, the second protrusion dams 2800 made of an elastic material prevent damage to the micro LEDs ML. For example, in the case GaN is selected for semiconductor materials of a first semiconductor layer 102 and a second semiconductor layer 104 of each of the micro LEDs ML, the first semiconductor layer 102 and the second semiconductor layer 104 may be damaged due to weak rigidity of GaN when the micro LED suction body 1′ and the micro LEDs ML are brought into intimate contact with each other. However, as the second protrusion dams 2800 made of an elastic material are provided, the second protrusion dams 2800 serve as buffers upon the intimate contact between the micro LED suction body 1′ and the micro LEDs ML, thereby preventing damage to specific layers of the micro LEDs ML such as the first semiconductor layer 102 and the second semiconductor layer 104.

The second protrusion dams 2800 may be made of a photoresist (PR), PDMS, or a metal, and may be formed through an exposure process. Alternatively, the buffer part 2600 may be formed through sputtering.

The micro LED suction body 1′ provided with the second protruding dams 2800 may perform a micro LED ML suction process even in a state spaced apart from the micro LEDs ML. When the micro LED suction body 1′ according to the tenth modified example performs the micro LED ML suction process in a state as illustrated in FIG. 7(c-1), the micro LED suction body 1′ may suck the micro LEDs ML in a state spaced apart from the micro LEDs ML. In the case of the micro LED suction body 1′ according to the tenth modified example, since the second protruding dams 2800 are provided at a lower portion thereof, the second protruding dams 2800 and the micro LEDs ML may be in a state spaced apart from each other.

In the case the micro LED suction body 1′ is provided with the second protruding dams 2800, the vacuum pressure of the vacuum pump is applied to the inside of the second protruding dams 2800. Since the second protruding dams 2800 surround the suction regions 2000, a vacuum suction force greater than that generated in the suction regions 2000 is generated therein. In order to form a large vacuum suction force, increasing the area of the suction regions 2000 may be considered, but it is necessary to change the capacity of the vacuum pump to a large capacity or high output by an amount equal to the increased area. However, when the second protrusion dams 2800 are provided, it is possible to efficiently suck the micro LEDs ML in a spaced apart state without changing the capacity of the vacuum pump to a large capacity or high output.

The second protruding dams 2800 may be made of a material that is elastically deformable, so that even when the micro LEDs ML have different heights, the second protruding dams 2800 enables the micro LEDs ML to be sucked on the micro LED suction body 1′ by accommodating such a height difference through elastic deformation.

Although the modified examples illustrated in FIGS. 5 to 7 have been described as being implemented by the suction member 1100 embodied by the anodic aluminum oxide film 1600 according to the second embodiment, they may be implemented by a porous member having vertical pores, which is embodied by a material other than the anodic aluminum oxide film 1600.

### Third Embodiment

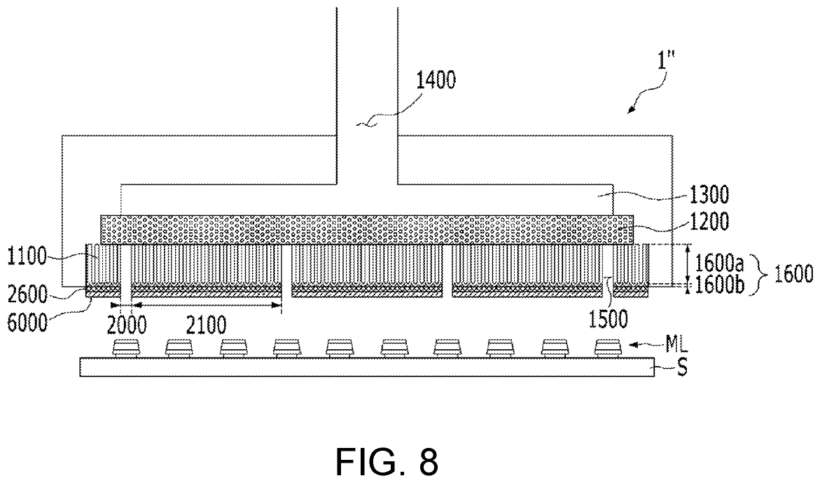

FIG. 8 is a view illustrating a micro LED suction body 1″ according to a third embodiment of the present disclosure. The third embodiment includes: a suction member 1100 embodied by an anodic aluminum oxide film 1600 and including a suction region 2000 on which micro LEDs ML are sucked and a non-suction region 2100 on which the micro LEDs ML are not sucked; and a support member 1200 having arbitrary pores and provided on an upper surface of the suction member 1100 to support the suction member 1100.

The third embodiment differs from the second embodiment in that the suction member 1100 has a structure in which a barrier layer 1600b is located at a lower portion of the anodic aluminum oxide film 1600. Also, third embodiment differs from the second embodiment in that a buffer part 2600 and a metal part 6000 are provided under the suction member 1100. The third exemplary embodiment described below will be mainly described with respect to characteristic components as compared with the second exemplary embodiment, and detailed descriptions of the same or similar components as those of the second exemplary embodiment will be omitted.

The suction member 1100 includes the suction regions 2000 on which the micro LEDs ML are sucked by a vacuum suction force and the non-suction region 2100 on which the micro LEDs ML are not sucked.

The suction member 1100 is supported by the support member 1200 provided thereon.

The support member 1200 is formed separately from the suction member 1100 and has a pore structure through which the suction force of a vacuum chamber 1300 is distributed and transmitted to the suction force to the suction regions 2000. Therefore, the vacuum suction force is generated in the suction member 1100, allowing the micro LEDs ML to be sucked on a suction surface of the suction member 1100.

As illustrated in FIG. 8, the support member 1200 is provided on a side opposite to the suction surface of the suction member 1100 and has the arbitrary pores being in air communication with the suction regions 2000. The support member 1200 supports the suction member 1100 by sucking the non-suction region 2100 of the suction member 1100 using the vacuum suction force and allows the micro LEDs ML to be sucked on the suction regions 2000 by performing air communication with the suction member 1100.

As illustrated in FIG. 8, the suction member 1100 may be embodied by the anodic aluminum oxide film 1600 including a porous layer 1600a and the barrier layer 1600b. The anodic aluminum oxide film 1600 is configured such that the barrier layer 1600b is located at the lower portion of the anodic aluminum oxide film 1600 and the porous layer 1600a is positioned on the barrier layer 1600b.

The barrier layer 1600b may have a planar surface. Therefore, in the case the barrier layer 1600b is located at the lower portion of the anodic aluminum oxide film 1600, the non-suction region 2100 provided by the barrier layer 1600b may have a planar surface.

In the case the barrier layer 1600b is located at the lower portion of the anodic aluminum oxide film 1600, the suction member 1100 may have a planar lower surface. This makes it easier to form the buffer part 2600 preventing damage to the micro LEDs ML when sucking the micro LEDs ML and to form the metal part 6000 preventing the generation of static electricity.

Specifically, as illustrated in FIG. 5, since the barrier layer 1600b is provided at the lower portion of the anodic aluminum oxide film 1600, it is possible to form a planar lower surface of the anodic aluminum oxide film 1600 compared to a configuration in which the porous layer 1600a is located at the lower portion of the anodic aluminum oxide film 1600. When the micro LED suction body 1″ sucks the micro LEDs ML, as at least a part of the lower exposed surface of the suction member 1100 is brought into contact with the micro LEDs ML, the micro LEDs ML are sucked on the suction regions 2000. Here, the lower exposed surface of the suction member 1100 may be the non-suction region 2100. In this case, the micro LEDs ML may be damaged by the contact with the suction member 1100 embodied by the anodic aluminum oxide film 1600 having high rigidity. Therefore, it is preferable to combine the buffer part 2600 serving as a buffer with the lower exposed surface of the suction member 1100.

The buffer part 2600 may be made of an elastic material. The buffer part 2600 may be made of a photoresist (PR), PDMS, or a metal, and may be formed through an exposure process. Alternatively, the buffer part 2600 may be formed through sputtering.

In this case, when detaching micro LEDs ML from a first substrate using a laser lift-off (LLO) process, the buffer part 2600 functions as a buffer to prevent damage to the micro LEDs ML. For example, in the case the first substrate is a growth substrate 101, when detaching the micro LEDs ML from the growth substrate 101 using the LLO process, the micro LEDs ML may be repelled from the growth substrate 101 toward the micro LED suction body 1″ due to the gas pressure. In this case, the buffer part 2600 made of an elastic material supports the micro LEDs ML upwardly in a state in contact with the micro LEDs ML and simultaneously functions as a buffer against the micro LEDs ML.

Also, in the case the first substrate is a temporary substrate or a carrier substrate, the buffer part 2600 made of an elastic material prevents damage to the micro LEDs ML. For example, in the case GaN is selected for semiconductor materials of a first semiconductor layer 102 and a second semiconductor layer 104 of each of the micro LEDs ML, the first semiconductor layer 102 and the second semiconductor layer 104 may be damaged due to weak rigidity of GaN when the micro LED suction body 1″ and the micro LEDs ML are brought into intimate contact with each other. However, as the buffer part 2600 made of an elastic material is provided, the buffer part 2600 serves as a buffer upon the intimate contact between the micro LED suction body 1″ and the micro LEDs ML, thereby preventing damage to specific layers of the micro LEDs ML such as the first semiconductor layer 102 and the second semiconductor layer 104.

The metal part 6000 is provided under the buffer part 2600 provided on the exposed surface of the non-suction region 2100. The metal part 1700 having openings formed at positions corresponding to openings of the suction member 1100 and openings of the buffer part 2600 may be provided and bonded to the exposed surface except for the openings of the suction member 1100 and the openings of the buffer part 2600.

As illustrated in FIG. 8, the metal part 6000 may have the openings formed at the positions corresponding to the openings of the suction member 1100 and the openings of the buffer part 2600. In this case, the area of the openings of the metal part 6000 may be equal to that of the openings of the suction member 1100 and that of the openings of the buffer part 2600.

The metal part 6000 may be made of a metal material. This prevents the generation of electrostatic force that hinders the process in which the micro LED suction body 1″ transfers the micro LED ML.

Specifically, an electrostatic force caused by electrification may undesirably occur between the first substrate (e.g., the growth substrate 101, a temporary substrate, or a carrier substrate C) and the micro LED suction body 1″ or between a second substrate (e.g., a display substrate 301, a temporary substrate, a target substrate, or a circuit board HS) and the micro LED suction body 1″ due to friction or the like in the process in which the micro LED suction body 1″ transfers the micro LEDs ML. This undesirable electrostatic force has a great influence on the micro LEDs ML having a size of 1 μm to 100 μm even when the electrostatic force is caused by small charges.

In other words, after the micro LED suction body 1″ sucks the micro LEDs ML from the first substrate, when an electrostatic force is generated in the unloading process in which the micro LEDs ML are mounted on the second substrate, the micro LEDs ML may be attached to the micro LED suction body 1″ and unloaded at wrong positions on the second substrate, or unloading may fail to be performed.

As the metal part 6000 is provided on the exposed surface of the buffer part 2600, it is possible to remove the undesirable electrostatic force generated in the process in which the micro LED suction body 1″ transfers the micro LEDs ML.

In addition, the metal part 6000 may be embodied in the form of an electrode pattern and thus electrically connected to the contact electrodes 106 and 107 of the micro LEDs ML, thereby checking whether the micro LEDs ML are defective in an electrical manner.

### Fourth Embodiment

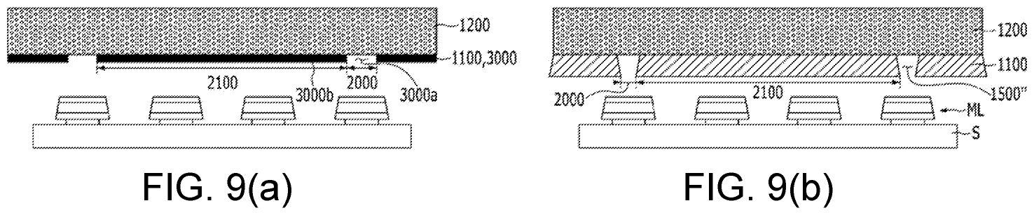

FIG. 9(a) is an enlarged view of a part of a porous member 1000 constituting a micro LED suction body according to a fourth embodiment of the present disclosure. In the fourth embodiment, a mask 3000 having second openings 3000a serves as a first porous member 1100. Therefore, the first porous member 1100 according to the fourth embodiment may be a suction member 1100 embodied by the mask 3000 having the openings 3000a formed therein. The fourth exemplary embodiment described below will be mainly described with respect to characteristic components as compared with the first exemplary embodiment, and detailed descriptions of the same or similar components as those of the first exemplary embodiment will be omitted.

As illustrated in FIG. 9(a), the suction member 1100 embodied by the mask 3000 serving as the first porous member 1100 is provided on a lower surface of a support member 1200 having arbitrary pores. The second openings 3000a of the mask 3000 are formed at a regular interval to form suction regions 2000 on which micro LEDs ML are sucked, and a region of the mask 3000 where the second openings 3000a are not formed forms a non-suction region 2100 on which the micro LEDs ML are not sucked.

The second openings 3000a of the mask 3000 may be formed with a pitch equal to that of the micro LEDs ML on a growth substrate 101 or may be formed with a regular pitch to selectively suck the micro LEDs ML.

When a substrate S illustrated in FIG. 9(a) is the growth substrate 101, the second openings 3000a of the mask 3000 may be formed with a pitch three times a column-direction (x-direction) pitch of the micro LEDs ML disposed on the growth substrate 101. Accordingly, the micro LED suction body selectively sucks the micro LEDs ML located at 1st and 4th positions on the substrate S.

The mask 3000 includes the second openings 3000a and a non-opening region 3000b. The non-opening region 3000b may close a part of the lower surface of the support member 1200 having the arbitrary pores so that a large vacuum suction force is formed in the second openings 3000a.

The support member 1200 having the arbitrary pores may be configured such that gas flow paths are formed in the entire inside thereof to allow a vacuum suction force for sucking the micro LEDs ML to be generated over the entire lower surface thereof. Therefore, when the mask 3000 is provided on the surface of the support member 1200, portions where the second openings 3000a of the mask 3000 are located may be the suction region 2000 substantially sucking the micro LEDs ML. In other words, in the fourth embodiment, as the mask 3000 is provided on the lower surface of the support member 1200, the suction regions 2000 substantially sucking the micro LEDs ML are defined. In this case, the second openings 3000a provided in the mask 3000 may be vertical pores.

The region of the mask 3000 where the second openings 3000a are not formed serves as a shielding portion closing the pores of the lower surface of the support member 1200. This ensures that a vacuum pressure generated as the vacuum of a vacuum chamber 1300 is transmitted to the support member 1200 can be increased by the second openings 3000a of the mask 3000.

As illustrated in FIG. 9(a), the area of each of the second openings 3000a may be smaller than the horizontal area of an upper surface of each of the micro LEDs ML. In this case, the mask 3000 may be made of an elastic material. The mask 3000 made of an elastic material and having the second openings 3000a each having an area smaller than the horizontal area of the upper surface of each of the micro LEDs ML functions as a buffer to prevent damage to the micro LEDs ML when the micro LED suction body sucks the micro LEDs ML. Specifically, the micro LEDs ML are sucked on the micro LED suction body as at least a part of the upper surface of each of the micro LEDs ML is brought into contact with at least a part of the non-opening region 3000b where the second openings 3000a are not formed, the at least the part of the non-opening region 3000b being formed around each of the second openings 3000a of the mask 3000. In other words, the micro LEDs ML are sucked on the micro LED suction body as the horizontal area of the upper surface of each of the micro LEDs ML except for an area equal to the area of each the second openings 3000a of the mask 3000 is brought into contact with the exposed surface of the mask 3000. Since the region of the mask 3000 directly brought into contact with the micro LEDs ML is the exposed surface, the micro LEDs ML can be sucked on the micro LED suction body without being damaged.

On the other hand, the area of each of the second openings 3000a may be larger than the horizontal area of the upper surface of each of the micro LEDs ML.

When the area of each of the second openings 3000a of the mask 3000 is larger than the horizontal area of the upper surface of each of the micro LEDs ML, the vacuum pressure of the second porous member 1200 is generated in the second opening 3000a of the mask 3000 as the vacuum of the vacuum chamber 1300 is transmitted, so that the micro LEDs ML are sucked on the lower surface of the support member 1200 by the vacuum pressure.

The mask 3000 may be made of various materials such as Invar, an anodic aluminum oxide film, a metal material, a film material, a paper material, and an elastic material (PR, PDMS, etc.).

Meanwhile, the mask 3000 may be a coating layer formed by applying a liquid material to the surface of the support member 1200 having the arbitrary pores and then curing the liquid material. In this case, the region to which the liquid material is applied is a non-suction region serving as the non-opening region 3000b, and the regions to which the liquid material is not applied are suction regions serving as the second openings 3000a. The coating layer is configured such that openings are arranged with a regular interval to form the suction regions on which the micro LEDs ML are sucked and a surface where the openings are not formed forms the non-suction region on which the micro LEDs ML are not sucked, and may be integrally formed on the surface of the porous member.

In the case the area of each of the second openings 3000a is smaller than the horizontal area of the upper surface of each of the micro LEDs ML as described above, it is preferable that the mask 3000 is made of an elastic material since it functions to form the suction regions 2000 and functions as a buffer.

In the case the mask 3000 is made of Invar having a low coefficient of thermal expansion, it is possible to prevent surface distortion which may occur due to temperature changes.

On the other hand, when the mask 3000 is made of a metal material, it is possible to facilitate the formation of the second openings 3000a. Since the metal material is easy to process, it is possible to easily form the second openings 3000a of the mask 3000. As a result, the ease of manufacturing can be improved.

In addition, in the case the mask 3000 is made of a metal material, when a metal bonding technique is used for bonding a micro LED ML to a first contact electrode 106 of a display substrate 301, a bonding metal (alloy) is heated by heating an upper surface of the micro LED ML through the mask 3000 of the micro LED suction body without the need to apply power to the display substrate 301, thereby bonding the micro LED ML to the first contact electrode 106.

On the other hand, the mask 3000 may be made of a film material. When the micro LED suction body having the mask 3000 sucks the micro LEDs ML, foreign substances may be attached to the surface of the mask 3000. The mask 3000 can be cleaned and reused, but it is troublesome to clean the mask 3000 each time. However, in the case the mask 3000 is made of a film material, it is easy to remove and replace the mask 3000 when the foreign substances are attached to the mask 3000. On the other hand, the mask 3000 may be made of a paper material. Also, in the case the mask 3000 is made of a paper material, when foreign substances are attached to the surface of the mask 3000, it is easy to remove and replace the mask 3000 without the need for a separate cleaning process.

On the other hand, the mask 3000 may be made of an elastic material. In this case, the mask 3000 serves as a buffer to prevent damage to the micro LEDs ML.

Specifically, when the micro LED suction body is lowered, a transfer error may occur in the micro LED suction body due to mechanical tolerance. This causes the micro LEDs ML corresponding to the non-suction region 2100 to be brought into contact with the non-suction region 2100. In this case, the mask 3000 made of an elastic material accommodates such a transfer error, thereby preventing damage to the micro LEDs ML in contact with the non-suction region 2100.

The mask 3000 may have different shapes of the second openings 3000a. Specifically, the mask 3000 may be configured such that an end of each of the second openings 3000a of the mask 3000 that is in contact with the lower surface of the support member 1200 has an inner diameter larger than the horizontal area of the upper surface of each of the micro LEDs ML and the inner diameter gradually increases toward the upper surface of the micro LED ML. Accordingly, an inner surface of each of the second openings 3000a may be inclined such that the inner diameter thereof gradually decreases in a downward direction in which the micro LED suction body is lowered. With such a configuration, the mask 3000 guides the micro LEDs ML to vacuum-sucking positions when the micro LEDs ML are sucked on the suction regions 2000 of the micro LED suction body, so that the micro LEDs ML can be sucked at correct positions on the suction regions 2000.

The mask 3000 is sucked on the lower surface of the support member 1200 by a vacuum suction force. The micro LED suction body having the mask 3000 obtains the vacuum pressure through a vacuum port and applies the vacuum pressure to the support member 1200 to vacuum-suck the micro LEDs ML. Thereafter, the micro LED suction body is moved to a position over the display substrate 301, and then lowered. The mask 3000 and the micro LEDs ML vacuum-sucked on the lower surface of the support member 1200 are transferred to the display substrate 301 by releasing the vacuum pressure applied to the support member 1200 through the vacuum port. Each of the micro LEDs ML transferred to the display substrate 301 may be bonded to the first contact electrode 106 of the display substrate 301 by applying power to the display substrate 301. Thereafter, the micro LED suction body obtains the vacuum pressure through the vacuum port and applies the vacuum pressure to the support member 1200 to retrieve the mask 3000 transferred to the display substrate 301. Since each of the micro LEDs ML is bonded to the first contact electrode 106, only the mask 3000 is vacuum-sucked on the lower surface of the support member 1200. Although the present disclosure describes that the mask 3000 transferred to the display substrate 301 is retrieved and removed by the micro LED suction body, the mask 3000 may be removed by other suitable means.

The mask 3000 serves as the suction member 1100 for sucking the micro LEDs ML. Therefore, the mask 3000 may be configured according to the modified examples of the second embodiment described above.

As the micro LED suction body according to the present disclosure is provided with the mask 3000, it is possible to further increase the vacuum pressure for sucking the micro LEDs ML is generated through the second openings 3000a of the mask 3000. The increased vacuum pressure causes the micro LEDs ML to be directly brought into contact with the lower surface of the support member 1200 having uniform flatness, thereby preventing detachment of the micro LEDs ML, which may occur during the vacuum suction of the micro LEDs ML.

### Fifth Embodiment

FIG. 9(b) is an enlarged view of a part of each of first and second porous members 1100 and 1200 constituting a micro LED suction body according to a fifth embodiment of the present disclosure. In the fifth embodiment, a suction member 1100 having vertical pores of tapered shape formed through laser processing is embodied by the first porous member 1100. Suction holes 1500″ according to the fifth embodiment have a tapered shape. The suction holes 1500″ form suction regions 2000 on which micro LEDs ML are sucked and the region where the suction holes 1500″ are not formed forms a non-suction region 2100 on which the micro LEDs ML are not sucked.

As illustrated in FIG. 9(b), the suction holes 1500″ are formed to vertically pass through the suction member 1100 from top to bottom, and have a width gradually decreasing toward a suction surface on which the micro LEDs ML are sucked. Accordingly, each of the suction holes 1500″ may have an inclined inner surface.

The lower width of the suction holes 1500″ having the smallest inner diameter may be smaller than the horizontal width of an upper surface of each of the micro LEDs ML. In the case of the suction holes 1500″, as long as a vacuum pressure capable of sucking the micro LEDs ML can be generated therein, even when the width of each thereof gradually decreases toward the suction surface so that the lower width thereof is smaller than the horizontal width of the upper surface of each of the micro LEDs ML, it is possible to suck the micro LEDs ML without worrying about the detachment of the micro LEDs ML and reducing the micro LED suction efficiency.

The suction holes 1500″ may be formed through laser processing in an inverted tapered shape in which the width thereof gradually increases from an upper end thereof toward a lower end thereof. However, it is more difficult for the suction holes 1500″ of such a shape to satisfy high alignment precision considering a mechanical error of the micro LED suction body when sucking a micro LED having a relatively small size compared to a packaged LED or a heavy semiconductor chip. In addition, when the shape having a wide lower width causes a position alignment error attributable to the mechanical error of the micro LED suction body, the vacuum of the suction holes 1500″ may leak. In addition, the lower horizontal area of the non-suction region of the suction member is formed in a pointed shape narrowing downwardly due to the shape of the suction holes 1500″ having a wide lower end. This may cause a problem of damage to the micro LEDs ML.

However, as in the fifth embodiment, in the case the suction holes 1500″ are formed to have a width decreasing toward the suction surface, it is possible to suck the micro LEDs ML even when the alignment accuracy is relatively low. This is because since the lower width of each of the suction holes 1500″ is smaller than the horizontal width of each of the micro LEDs ML, the micro LED ML is sucked by the suction hole 1500″ as long as the suction hole 1500″ is located within the width of the upper surface of the micro LED ML. This ensures that even when the alignment accuracy of the micro LED suction body with respect to the micro LEDs ML is relatively low, it is possible to suck the micro LEDs ML without lowering the efficiency of sucking the micro LEDs ML. In addition, since the lower width of each of the suction holes 1500″ is smaller than the horizontal width of each of the micro LEDs ML, the micro LED ML is sucked by the suction hole 1500″ when the suction hole 1500″ is located within the width of the upper surface of the micro LED ML. This reduces the possibility of a vacuum leak in the suction holes 1500″. Also, since the lower width of each of the suction holes 1500″ is smaller than the upper width thereof, a relatively strong vacuum pressure is generated in the lower width of the suction hole 1500″ compared to the upper width thereof, thereby causing the micro LED ML to be sucked without detachment. In addition, even when the distance between the micro LEDs ML is as narrow as several μm, the suction of the micro LEDs ML is facilitated due to the fact that the lower width of each of the suction holes 1500″ is smaller than the horizontal width of each of the micro LEDs ML. In addition, air is discharged to outside from a narrow lower end of each of the suction holes 1500″ toward a wide upper end thereof during the generation of vacuum pressure. This reduces the probability of occurrence of vortexes, thereby reducing the probability that the micro LEDs ML fail to be sucked, which may occur when the vacuum pressure is not generated due to vortexes.

The shape of the suction holes 1500″ in which the upper end thereof is wider than the lower end thereof ensures that a uniform vacuum pressure of the suction member 1100 is generated. Referring back to FIG. 9b, the air discharged from the inside of the suction holes 1500″ to the outside can be efficiently gathered in one place due to the tapered shape of the suction holes 1500″. In other words, all the air in the suction holes 1500″ formed in the suction member 1100 is gathered in one place, and thus a uniform vacuum pressure is generated in the suction holes 1500″. This enables the micro LED suction body to suck all the micro LEDs ML simultaneously on the suction surface without any missing micro LEDs, thereby improving the suction efficiency.

The suction holes 1500″ may have a circular cross-section when the suction member 1100 is viewed from a lower side thereof. For example, in the case the suction holes 1500″ are formed through laser processing to have a shape in which the width thereof gradually decreases toward the suction surface, it may be easier to form the suction holes 1500″ having a circular cross-section.

The suction holes 1500″ formed in the suction member 1100 of the micro LED suction body are spaced apart from each other with a regular interval in an x-(row) direction and a y-(column) direction. Here, the pitch of the suction holes 1500″ in at least any one of the x-direction and the y-direction are spaced apart from each other with an interval is equal to or greater than twice the x-direction pitch and the y-direction pitch of the micro LEDs ML disposed on a donor part.

As illustrated in FIG. 9(b), the pitch of the suction holes 1500″ may be three times the pitch of the micro LEDs ML disposed on a substrate S in the x-direction. As a result, the non-suction region 2100 in which the suction holes 1500″ are not formed is provided in the suction member 1100. The micro LEDs ML disposed on the substrate S at positions corresponding to a lower surface of the non-suction region 2100 are not sucked on the suction member 1100.

The suction member 1100 according to the fifth embodiment, which has the vertical pores formed through laser processing, may be configured according to the modified examples of the second embodiment described above. However, in the case the suction member 1100 is a porous member having vertical pores formed through laser processing, the pores vertically passing through the porous member may not have a uniform shape. Therefore, the suction holes 1500 of a quadrangular cross-section according to the ninth modified example may be difficult to form in the porous member having the vertical pores formed through laser processing.

As described above, in the case of the micro LED suction body according to the fifth embodiment, the suction regions 2000 are formed by forming the multiple suction holes 1500″ in the suction body 1100 sucking the micro LEDs ML in a shape in which the width thereof gradually decreases toward the suction surface. This facilitates the suction of the micro LEDs ML even when the distance between the micro LEDs ML is narrow. In addition, due to the shape of the suction holes 1500″ in which the width thereof gradually decreases toward the suction surface so that the upper end thereof is wider than the lower end thereof, the air discharged from the inside of the suction holes 1500′ to the outside can be gathered in one place. As a result, a uniform vacuum pressure can be formed throughout the multiple suction holes 1500″, thereby allowing all the micro LEDs ML to be sucked on the entire suction surface. Thus, it is possible to improve the micro LED ML suction efficiency.

### Sixth Embodiment

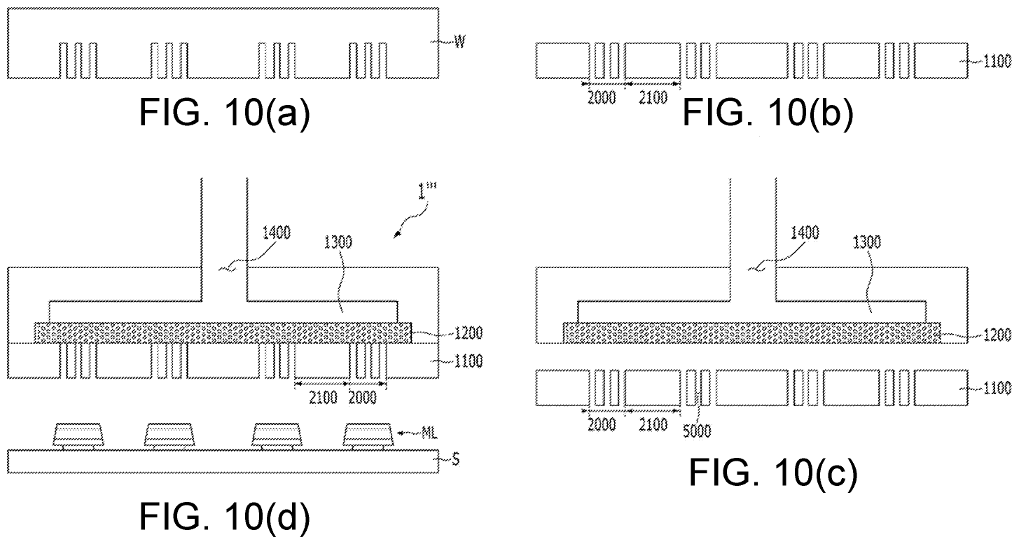

FIG. 10 is a view schematically illustrating a process of constructing a micro LED suction body 1′″ according to a sixth embodiment of the present disclosure. The sixth embodiment includes a suction member 1100 having vertical pores formed by etching, and a support member 1200 supporting the suction member 1100 on an upper surface of the suction member 1100. The suction member 1100 according to the sixth embodiment is configured such that through-holes 5000 formed by etching form one suction region 2000. Although FIG. 10 illustrates that multiple vertical pores form one suction region 2000, one vertical pore formed by etching may form one suction region 2000.

The suction member 1100 includes suction regions 2000 each of which being formed by the through-holes 5000 and on which micro LEDs ML are sucked and a non-suction region not provided with the through-holes 5000, and may be embodied by a wafer substrate w.

The through-holes 5000 may be vertical pores formed by etching. The suction member 1100 is configured such that the suction region 2000 is formed by forming the through-holes 5000 to pass through the suction member 1100 from top to bottom. The through-holes 5000 may perform the same function as the suction holes 1500 forming the suction regions 2000 of the micro LED suction bodies according to the above-described embodiments.

First, the wafer substrate w made of silicon is provided to form the suction member 1100 in which the suction region 2000 is formed by the through-holes 5000.

Then, as illustrated in FIG. 10(a), the through-holes 5000 are formed by etching. Each of the through-holes 5000 may be formed by etching at least a part of the wafer substrate w. Although FIG. 10 (a) illustrates that the wafer substrate w is partly etched from the bottom thereof in a depth direction to form the multiple through-holes 5000, the wafer substrate w may be partly etched from the top in the depth direction. An etching method here may be wet etching, dry etching, or the like which is conventionally used in a semiconductor manufacturing process.

The suction regions 2000 of the suction member 1100 according to the sixth embodiment are formed by the through-holes 5000. The multiple through-holes 5000 forming one suction region 2000 are formed by etching, and the same process is repeated to form the multiple suction regions 2000. As a result, the multiple suction regions 2000 on which the micro LEDs ML of a substrate S are sucked are provided. In this case, each of the suction regions 2000 is formed to have an area smaller than the horizontal area of an upper surface of each of the micro LEDs ML, thereby preventing a vacuum leak.

The suction regions 2000 formed by the through-holes 5000 may be formed with a pitch equal to or three times a column-direction (x-direction) pitch and a row-direction (y-direction) pitch of the micro LEDs ML disposed on the substrate S. FIG. 10 illustrates the suction regions 2000 being formed with a column-direction (x-direction) pitch equal to the column-direction (x-direction) pitch of the micro LEDs ML disposed on the substrate S.

FIG. 10(a) illustrates a process of forming the through-holes 5000 constituting the suction regions 2000. In this case, the multiple through-holes 5000 that form one suction region 2000 are formed with a regular pitch, and then the multiple through-holes 5000 are formed with a regular pitch at positions spaced apart from the previous through-holes 5000 in consideration of the pitch of the suction regions 2000. Although FIG. 10 illustrates that three through-holes 5000 form one suction region 2000, the number of the multiple through-holes 5000 forming one suction region 2000 is not limited. However, since each of the suction regions 2000 has an area smaller than the horizontal area of the upper surface of each of the micro LEDs ML, the multiple through-holes 5000 are preferably provided so that each of the suction regions 2000 has an area smaller than the horizontal area of each of the micro LEDs ML.

Then, as illustrated in FIG. 10(b), the opposite surface of the etched surface of the wafer substrate w is removed. As result, the multiple through-holes 5000 illustrated in FIG. 10(a) are formed to pass through the wafer substrate w from top to bottom, thereby obtaining the suction member 1100 having the through-holes 5000 formed by etching. The multiple suction regions 2000 formed by the through-holes 5000 are formed in the suction member 1100. The suction member 1100 may be configured in the same manner as that described for the second embodiment.

Then, as illustrated in FIG. 10(c), the suction member 1100 is coupled to a lower portion of the support member 1200 having the arbitrary pores and supporting the suction member 1100. The support member 1200 supports the suction member 1100 from the upper surface of the suction member 1100. In the case the wafer substrate w provided in the form of a thin plate is etched to form tens of thousands of through-holes and not provided with a support member, there is a high possibility that brittle fracture occurs in the suction member 1100 due to a high vacuum suction force. Therefore, it is required to support the suction member 1100 using the support member 1200 such as a porous ceramic member.

FIG. 10(d) is a view illustrating the micro LED suction body 1′″ according to the sixth embodiment before sucking the micro LEDs ML disposed on the substrate S. In the case of the micro LED suction body 1′″ according to the sixth embodiment being provided with the suction member 1100 described with reference to FIGS. 10(a) to 10(c) in which the multiple suction regions 2000 are formed by the vertical pores formed by etching the wafer, the pitch of the suction regions 2000 is equal to or three times the column-direction (x-direction) pitch and the row-direction (y-direction) pitch of the micro LEDs ML disposed on the substrate S, so that the micro LED suction body 1′″ collectively sucks and transfers all the micro LEDs ML from the substrate S, or selectively sucks and transfers the micro LEDs ML from the substrate S.

In the case of the micro LED suction body 1′″ according to the sixth embodiment, a vacuum pressure is reduced by the arbitrary pores of the support member 1200 and then transmitted to the through-holes 5000 of the suction member 1100, thereby causing the micro LEDs ML to be sucked, and is transmitted to the non-suction regions 2100 of the suction member 1100 through the arbitrary pores, thereby causing the suction member 1100 to be sucked.

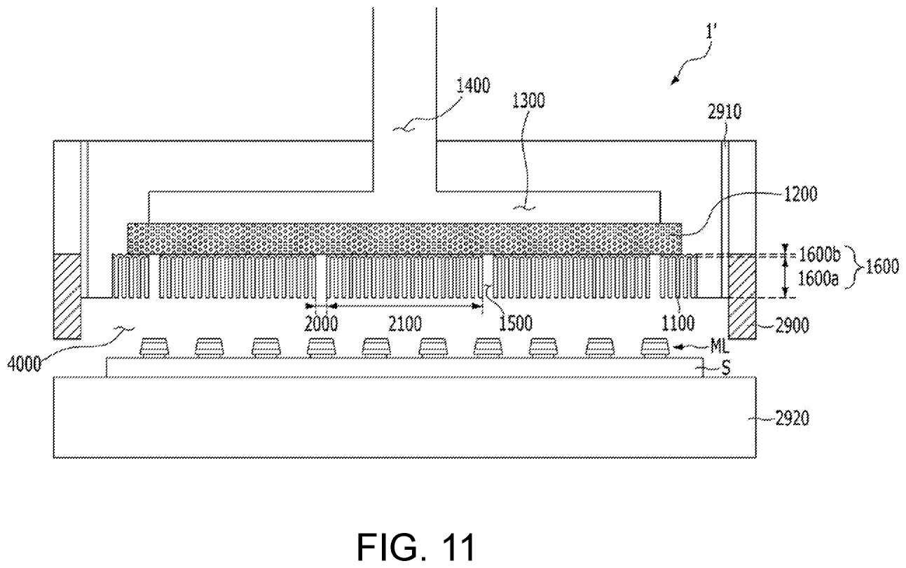

Hereinafter, a protrusion 2900 provided on the edge of the micro LED suction body at a position outside the suction member 1100 of the micro LED suction body will be described with reference to FIGS. 11 to 13.

The micro LED suction body according to the present disclosure includes the protrusion 2900 provided outside the suction member 1100 in a shape protruding downwardly from a suction surface of the suction member 1100.

The protrusion 2900 may be provided on the edge of the micro LED suction body at a position outside the suction member 1100 in a shape protruding downwardly from a lower surface of the suction member 1100. Here, the edge of the micro LED suction body means an outer portion of a micro LED suction surface of the micro LED suction body, which corresponds to a micro LED present region where the micro LEDs ML are formed on an upper surface of the substrate S. In addition, the edge of the micro LED suction body to be mentioned below also means the edge of the micro LED suction body F.

The protrusion 2900 may be continuously or discontinuously provided on the edge of the micro LED suction body. However, when the protrusion 2900 functions to seal a specific space (a transfer space 4000 and a cleaning space to be described later) and block factors that hinder the function of the space, it is provided only in a shape continuously formed on the edge of the micro LED suction body.

In the case the protrusion 2900 is continuously provided on the edge of the micro LED suction body, it functions to seal the transfer space 4000 in which the micro LED suction body sucks and transfers the micro LEDs ML.

The protrusion 2900 may be made of an elastic material such as sponge, rubber, silicone, foam, and polydimethylsiloxane (PDMS). In this case, the protrusion 2900 functions as a buffer to prevent damage to the micro LEDs ML by a collision between the micro LED suction body 1′ and the micro LEDs ML.

The protrusion 2900 may be provided in consideration of the material shrinkage rate of the components of the elastic material. Specifically, when the protrusion 2900 is made of an elastic material, the components of the elastic material may have different material shrinkage rates. In the case when it is desired to have a length larger than the height of the micro LEDs ML disposed on the substrate S when the protrusion 2900 maximally contracts by the lowering of the micro LED suction body, the protrusion 2900 may be made of an elastic material having a material shrinkage rate suitable for this. In the case when it is desired to have a length that allows upper surfaces of the micro LEDs ML disposed on the substrate S and the suction surface of the micro LED suction body 1′ when the protrusion 2900 maximally contracts by the lowering of the micro LED suction body, the protrusion 2900 may be made of an elastic material having a material shrinkage rate suitable for this.

The protrusion 2900 functions to alleviate a warpage phenomenon of the substrate S which occurs when it is thermally deformed during a high-temperature process. When the substrate S has such warpage, the micro LEDs ML disposed on the substrate S may have different heights. Therefore, it is preferable that the protrusion 2900, which functions to alleviate the warpage phenomenon of the substrate S, is made of an elastic material configured such that the maximum contraction length of the protrusion 2900 contracted by the lowering of the micro LED suction body is larger than the height of a highest micro LED ML among the micro LEDs ML on the substrate S.

In FIGS. 11 to 13, the protrusion 2900 is illustrated, as an example, as being provided at the micro LED suction body 1′ according to the second embodiment, but the micro LED suction body 1′ provided with the protrusion 2900 is not limited to the second embodiment, and the protrusion 2900 may also be provided at the micro LED suction bodies 1′ according to the first to sixth embodiments. In addition, although FIGS. 11 to 13 illustrates as an example in which the suction member 1100 embodied by an anodic aluminum oxide film 1600 is an anodic aluminum oxide film 1600 including a barrier layer 1600b and a porous layer 1600a, the suction member 1100 is not limited thereto. In addition, although FIGS. 11 to 13 illustrates as an example in which the pitch of the suction regions 2000 of the suction member 1100 is three times the column-direction (x direction) pitch of the micro LEDs ML disposed on the substrate S, the pitch of the suction regions 2000 is not limited thereto. As illustrated in FIG. 11, the suction regions 2000 may be formed by suction holes 1500, or may be formed by the porous layer 1600a from which the barrier layer 1600b is removed.

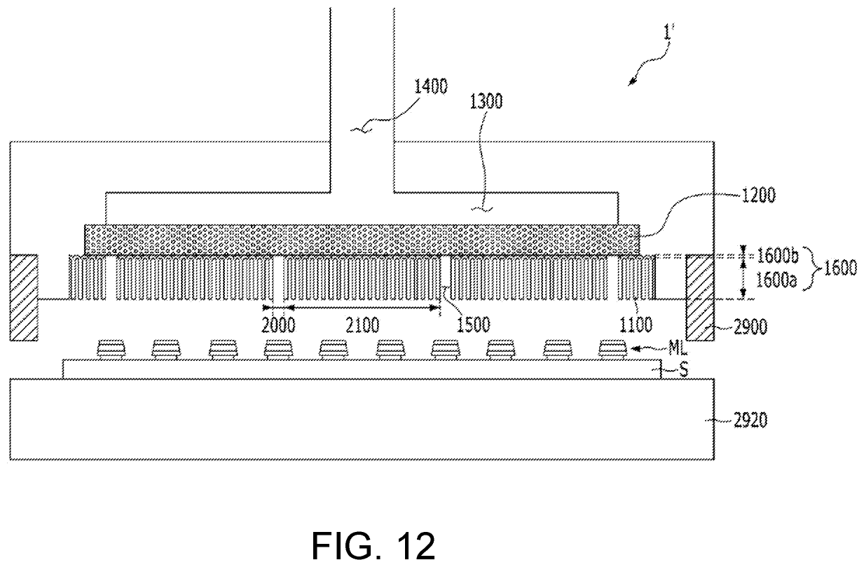

First, the protrusion 2900 continuously provided on the edge of the micro LED suction body 1′ will be described with reference to FIGS. 11 and 12. As illustrated in FIG. 11, the micro LED suction body 1′ includes the protrusion 2900 provided outside the suction member 1100 in a shape protruding downwardly from the suction surface of the suction member 1100.

When the micro LED suction body 1′ is lowered to vacuum-suck the micro LEDs ML, the protrusion 2900 continuously formed on the edge of the micro LED suction body 1′ prevents the micro LEDs ML located on the edge side of the substrate S from being shaken due to a vortex generated by the outside air.

When the micro LED suction body 1′ sucks the micro LEDs ML, a vortex is generated by the vacuum pressure of the micro LED suction body 1′ and the outside air, so that the micro LEDs located at positions near the edge of the substrate S may be shaken. This may cause a problem of lowering the suction and transfer efficiency of the micro LED suction body F.

However, in the case of the micro LED suction body 1′ according to the present disclosure, since the protrusion 2900 is continuously provided on the edge of the micro LED suction body 1′ in a shape protruding downwardly from the lower surface of the suction member 1100, it is possible to prevent the shaking of the micro LEDs ML of the substrate S from occurring due to the vortex generation during the process of sucking the micro LEDs ML.

When the micro LED suction body 1′ is lowered toward the upper surfaces of the micro LEDs ML, the protrusion 2900 is brought into contact with an upper surface of a substrate support member 2920 supporting the substrate S. Thus, the transfer space 4000 is sealed, which is formed as the micro LED suction body 1′ and the micro LEDs ML are spaced apart from each other. As a result, it is possible to prevent the micro LEDs ML from shaking due to the outside air flowing into the transfer space 4000 during the process of vacuum-sucking the micro LEDs ML by the micro LED suction body F.

The transfer space 4000 sealed by the protrusion 2900 during the lowering of the micro LED suction body 1′ is prevented from inflow of the outside air so that an environment is created where the micro LEDs ML can be effectively vacuum-sucked.

The protrusion 2900 may be made of an elastic material. The micro LED suction body 1′ provides the vacuum pressure through a vacuum chamber 1300 to decompress the transfer space 4000. As the transfer space 4000 is in the reduced pressure state, the protrusion 2900 made of an elastic material is elastically deformed and the height there of is lowered. The height of the protrusion 2900 is elastically deformed so that the suction surface of the suction member 1100 and the upper surfaces of the micro LEDs ML are brought into contact with each other, thereby allowing the micro LEDs ML to be sucked on the micro LED suction body F. In the case the protrusion 2900 is made of an elastic material, the protrusion 2900 is elastically deformed and the height thereof is lowered, thereby causing the micro LEDs ML to be sucked on the micro LED suction body 1′ as they are brought into contact therewith. In other words, as the height of the protrusion 2900 is elastically deformed, the lower surface of the suction member 1100 and the upper surfaces of the micro LEDs ML come close to each other gradually and are brought into contact with each other, so that the micro LEDs ML are sucked on the lower surface of the suction member 1100. It is preferable that at least a part of the protrusion 2900 protruding downwardly from the lower surface of the suction member 110 in an elastically undeformed position has a height that does not allow the upper surfaces of the micro LEDs ML and the lower surface of the suction member 1100 to be brought into contact each other when the lower surface of the protrusion 2900 is brought into contact with an upper surface of the substrate support member 2920 during the lowering of the micro LED suction body F.

During the lowering of the micro LED suction body 1′, the protrusion 2900 made of an elastic material seals the transfer space 4000, thereby increasing the transfer efficiency of the micro LED suction body 1′, and functions as a buffer between the micro LED suction body 1′ and the micro LEDs ML. A transfer error may occur due to a mechanical tolerance of the micro LED suction body 1′ during the lowering of the micro LED suction body F. However, the protrusion 2900 made of an elastic material is elastically deformed while being brought into contact with the upper surface of the substrate support member 292, thereby accommodating the mechanical tolerance of the micro LED suction body F. As a result, it is possible to prevent a collision between the micro LED suction body 1′ and the micro LEDs ML.

The protrusion 2900 may be embodied by a porous member having pores. The protrusion 2900 can seal the transfer space 4000 while allowing a small amount of outside air to be introduced through the pores, thereby alleviating the sudden rise of the vacuum pressure as the transfer space 4000 is sealed.

In addition, when the protrusion 2900 is embodied by a porous member, it is possible to prevent the occurrence of a vortex in the transfer space 4000, which may be caused by high vacuum state. For example, when the micro LED suction body 1′ uses a high-vacuum pump and forms the transfer space 4000 in a high vacuum state to increase the vacuum suction force, a vortex is generated in the transfer space 4000 due to the high vacuum state, causing the micro LEDs ML to be shaken or the micro LEDs ML not to be sucked. However, in the case the protrusion 2900 is embodied by the porous member having the pores, a small amount of outside air is introduced into the transfer space 4000. Accordingly, it is possible to prevent the occurrence of a vortex in the transfer space 4000 which may be caused by high vacuum state and to achieve efficient suction of the micro LEDs ML.

Although FIGS. 11 to 13 illustrates that the horizontal area of the substrate support member 2920 is larger than the horizontal area of the substrate S, the horizontal area of the substrate S may be equal to the horizontal area of the substrate support member 2920 so that the protrusion 2900 is brought into contact with the upper surface of the substrate S during the lowering of the micro LED suction body 1′, thereby sealing the transfer space 1600.

As described above, in the case the protrusion 2900 is continuously provided on the edge of the micro LED suction body 1′ in a shape protruding downwardly from the lower surface of the suction member 1100, the transfer space 4000 is sealed by the protrusion 2900, thereby increasing the micro LED ML suction efficiency. In this case, the micro LED suction body 1′ may be further provided with a passage 2910 through which the outside air is introduced into the transfer space 4000. As illustrated in FIG. 11, the passage 2910 is formed inside the protrusion 2900 because it functions to introduce the outside air into the transfer space 4000. Since the transfer space 4000 is sealed by the protrusion 2900 and the passage 2910 functions to introduce the outside into the sealed transfer space 4000, the passage 2910 may be formed at a position inside the protrusion 2900 and communicating with the transfer space 4000.

The micro LED suction body 1′ introduces the outside air into the transfer space 4000 sealed by the protrusion 2900 through the passage 2910. The transfer space 4000 sealed by the protrusion 2900 is in a high vacuum state. However, the passage 2910 lowers the vacuum pressure of the transfer space 4000 by introducing the outside air into the transfer space 4000, so that the micro LED suction body 1′ can be easily lifted. The passage 2910 is provided with an opening means (not illustrated) being opened to introduce the outside air when the micro LED suction body 1′ is lifted or being closed when the micro LED suction body 1′ transfers the micro LEDs ML from a first substrate (e.g., a growth substrate 101) to a second substrate (e.g., a display substrate 301). Therefore, during the transfer of the micro LEDs ML, the outside air is not introduced into the transfer space 4000, and the transfer efficiency in the transfer space 4000 sealed by the protrusion 2900 can be maintained. The opening means of the passage 2910 may be a slide-type cover. Alternatively, in the case the passage 2910 is formed in a circular tube, the opening means may be a conical stopper which can be detachably coupled to an upper portion of the passage 2910. However, the shape of the opening means is not limited thereto, and it may be provided in a suitable shape for opening/closing the passage 2910.

On the other hand, the passage 2910 for introducing the outside air into the transfer space 4000 may be formed in at least a part of the protrusion 2900 protruding downwardly from the lower surface of the suction member 1100 in a shape passing through the protrusion 2900. In the case the passage 2910 is formed in at least a part of the protrusion 2900, it is preferably formed at a position that directly seals the transfer space 4000.

On the other hand, the passage 2910 may be formed on the edge of the substrate support member 2920 in a shape passing through the substrate support member 2920 from top to bottom. In this case, the passage 2910 is preferably formed inside the position corresponding to the protrusion 2900. Here, the edge of the substrate support member 2920 means an inner portion located inside the position corresponding to the protrusion 2900, which corresponds to an outer portion of a substrate providing region where the substrate S on which the micro LEDs ML are formed is provided.

In the case the passage 2910 is formed in the substrate support member 2920, the substrate S on which the micro LEDs ML are formed has a horizontal area smaller than that of the upper surface of the substrate support member 2920. This is to allow the outside air to be introduced into the transfer space 4000 through the passage 2910 provided at the edge side of the substrate support member 2920.

As described above, the protrusion 2900 is continuously provided on the edge of the micro LED suction body 1′ to seal the transfer space 4000 in which the micro LED suction body 1′ sucks and transfers the micro LEDs ML, thereby preventing the micro LEDs ML from being shaken due to a vortex generated by the outside air during transfer. In this case, the openable passage 2910 is provided in the micro LED suction body 1′ to introduce the outside air into the transfer space 4000. The passage 2910 is opened after the micro LED ML are sucked on the suction surface of the micro LED suction body 1′ to introduce the outside air into the transfer space 4000. As the vacuum pressure of the transfer space 4000 is lowered, the lower surface of the protrusion 2900 can be easily detached from the upper surface of the substrate support member 2920, and the micro LED suction body 1′ can be lifted thereby.

The protrusion 2900 seals the transfer space 4000 to block an external factor that hinders the micro LED ML suction force from entering into the transfer space 4000. In this case, since the protrusion 2900 mainly functions to block the external factor from entering into the transfer space 4000, as illustrated in FIG. 12, the micro LED suction body 1′ provided with the protrusion 2900 may not be further provided with the passage 2910 for introducing the outside air into the transfer space 4000.

The external factor that hinders the suction force for the micro LEDs ML in the transfer space 4000 may be, for example, foreign substances and outside air.

When the external factor that hinders the suction force of for micro LEDs ML is foreign substances, the foreign substances may block the suction regions 2000 of the suction member 1100. As a result, some of the suction regions 2000 may fail to suck the micro LEDs, leading to a reduction in the micro LED ML transfer efficiency.

In the case the external factor that hinders the suction force for the micro LEDs ML is the outside air, a vortex may be generated in the transfer space 4000. This may cause the micro LEDs ML to be shaken, and thus the suction of the micro LEDs ML may not be performed properly.

In the case the protrusion 2900 mainly functions to block the external factor from entering into the transfer space 4000, it is preferable that the protrusion 2900 is made of an elastic material to simultaneously function as a buffer and as a blocker to prevent the external factor from entering into the transfer space 4000.

The protrusion 2900 formed on the edge of the micro LED suction body 1′ as illustrated in FIG. 12 may be formed on the substrate support member 2920. In this case, the protrusion 2900 is formed to protrude upwardly on the edge of the substrate support member 2920, which corresponds to an outer portion of the substrate S provided on the upper surface of the substrate support member 2920. In the case the horizontal area of the substrate S provided on the upper surface of the substrate support member 2920 is equal to that of the substrate support member 2920, the protrusion 2900 is provided to protrude upwardly on the edge of the substrate S. Here, the edge of the substrate S means an outer portion of a micro LED present region where the micro LEDs ML are formed on the substrate S.

The protrusion 2900, which is formed on the edge of the substrate support member 2920 or the substrate S in a shape that protrudes upwardly, prevents the external factor that hinders the suction force from entering into the transfer space 4000 when the micro LED suction body 1′ sucks the micro LEDs ML. In this case, the protrusion 2900 made of an elastic material accommodates a transfer error caused by a mechanical tolerance of the micro LED suction body 1′, thereby functioning as a buffer to prevent a collision between the micro LED suction body 1′ and the upper surfaces of the micro LEDs ML so as not to damage the micro LEDs ML.

The protrusion 2900 also functions to seal a cleaning space during a cleaning process of cleaning foreign substances on the suction surface of the micro LED suction body 1′, i.e., on the lower surface of the suction member 1100. The foreign substances may be generated on the suction surface of the micro LED suction body 1′ due to the repeated suction in the process of transferring the micro LEDs ML. These foreign substances may hinder the suction function of the suction regions 2000 of the suction member 1100. Therefore, the micro LED suction body 1′ is cleaned of the foreign substances that hinder the suction function of the micro LED suction body 1′ during the cleaning process.

During the cleaning process, the protrusion 2900 functions to seal the cleaning space and prevent a factor (e.g., external foreign substances) that hinders the cleaning process from being entering into the cleaning space.

The protrusion 2900 may be formed to protrude upwardly on the edge of the support member supporting the substrate on which the micro LEDs ML are formed during the cleaning process, or may be formed to protrude upwardly on the edge of the substrate having a horizontal area equal to that of the support member.

Since the cleaning space is sealed by the protrusion 2900, external foreign substances that hinder the cleaning of the suction surface of the micro LED suction body 1′ is blocked from entering into the cleaning space.

The protrusion 2900 continuously provided on the edge of the micro LED suction body 1′ functions to seal a specific space (the transfer space 4000 and the cleaning space) to prevent the inflow and hindrance of the foreign substances, and also function to alleviate the warpage phenomenon occurring in the substrate S.

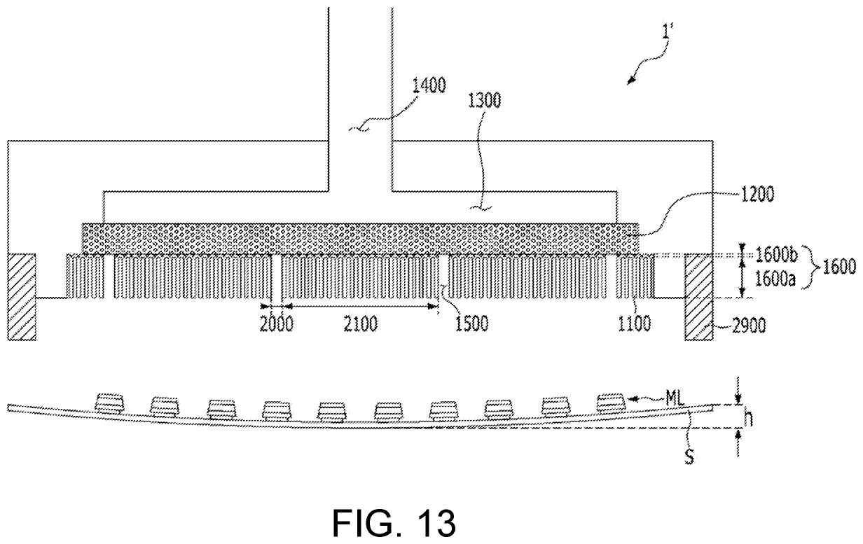

As illustrated in FIG. 13, the substrate S may undergo warpage as it is thermally deformed during a high temperature process. The substrate S may warp in a crying (n) shape or may warp in a smiling (U) shape as illustrated in FIG. 13. The letter “h” illustrated in FIG. 13 denotes a warpage height of the substrate S. In the case of the substrate S, when a crying shape warpage or a smiling shape warpage occurs, the substrate S may warp toward the micro LED present region on the substrate S. At this point, the protrusion 2900 continuously or discontinuously formed on the edge of the micro LED suction body 1′ is brought into contact with the substrate S during the lowering of the micro LED suction body 1′ to alleviate the warpage. This enables the micro LED suction body 1′ to suck the micro LEDs ML without damaging the micro LEDs ML.

As described with reference to FIGS. 11 and 12, the protrusion 2900 functioning to alleviate the warpage of the substrate S and functioning as a buffer against the micro LEDs ML is formed on the edge of the micro LED suction body 1′ in a shape protruding from the lower surface of the suction member 1100 and may be in a continuous or discontinuous form.

As illustrated in FIG. 13, due to the warpage of the substrate S, the height of each of the micro LEDs ML formed on the substrate S varies. This may cause a change in contact position at which each of the micro LEDs ML is brought into contact with an associated one of the suction regions 2000 during the suction of the micro LEDs ML, thereby causing damage to the micro LEDs ML. Specifically, when the micro LED suction body 1′ is lowered to suck the micro LEDs ML from the substrate S where the warpage has occurred, the micro LEDs ML formed at a highest position on the substrate S where the warpage has occurred are primarily sucked on an associated suction region 2000. Then, when the micro LED suction body 1′ is further lowered to secondarily suck the remaining micro LEDs ML, the previous micro LEDs ML may be excessively pressed, leading to a problem of damage to the micro LEDs ML.

However, the protrusion 2900 provided on the edge of the micro LED suction body 1′, which corresponds to the outer portion of the micro LED present region on the substrate S, contracts only to the maximum contraction length, thereby limiting the lowering position of the micro LED suction body 1′, and at the same time functions to alleviate the warpage of the substrate S, thereby enabling the micro LED suction body 1′ to suck the micro LEDs ML from the substrate S where the warpage has occurred without damaging to the micro LEDs ML.

Specifically, the protrusion 2900 may be made of an elastic material having a maximum contraction length larger than the height of the highest micro LED ML on the substrate S. The micro LED suction body 1′ provided with the protrusion 2900 is allowed to be lowered by an amount corresponding to the maximum contraction length of the protrusion 2900 so that the lowering position thereof is limited. The lowering position of the micro LED suction body 1′ limited by the protrusion 2900 may be a position higher than the highest micro LED ML on the substrate S.

The protrusion 2900 limiting the lowering position of the micro LED suction body 1′ presses and deforms the substrate S while contracting to the maximum contraction length. In this case, the protrusion 2900 may have a modulus of elasticity lower than that of the substrate S. The protrusion 2900 deforms the substrate S on which the warpage has occurred while being brought into press-contact with a contact surface with the substrate S. In this case, the contact surface between the substrate S and the protrusion 2900 may be at least any part of the substrate S, which has a highest height as a result of the warpage. This ensures that the flatness of the substrate S can be improved.

As described above, the protrusion 2900 continuously or discontinuously provided on the edge of the micro LED suction body 1′ presses and deforms the substrate S while contracting to the maximum contraction length.

In the case the protrusion 2900 is discontinuously provided on the edge of the micro LED suction body 1′, the number of the protrusion 2900 of a discontinuous form is not limited, and multiple protrusions may be independently provided at positions suitable for improving the flatness of the substrate S.

The micro LED suction body 1′ provided with the protrusion 2900 of a continuous or discontinuous form on the edge thereof can efficiently suck micro LEDs of a substrate having low flatness as well as the substrate S where the warpage has occurred.

Specifically, the protrusion 2900 is brought into in contact with an upper surface of the substrate having low flatness when the micro LED suction body 1′ is lowered. When the protrusion 2900 functions to control the flatness of the substrate S, preferably multiple protrusions 2900 are discontinuously provided on the edge of the micro LED suction body F. When the micro LED suction body 1′ is lowered, at least a part of the protrusions 2900 are primarily brought into contact with an upper surface of the substrate having low flatness, thereby pressing and deforming the substrate to control the flatness, and then the remaining part of the protrusions 2900 are secondarily brought into contact with the substrate, thereby improving the flatness.

As described above, the protrusion 2900 is provided around the suction member 1100 of the micro LED suction body 1′ at a position on the edge of the micro LED suction body 1′, which is the outer portion of the micro LED present region on the substrate S. Thus, it is possible to prevent damage to the micro LEDs ML which may occur due to excessive lowering of the micro LED suction body F. In addition, it is possible for the micro LED suction body 1′ to efficiently suck the micro LEDs ML from the substrate S where the warpage has occurred or the flatness thereof is low.

In the case the micro LED suction body 1′ is provided with the protrusion 2900 on the edge thereof and the protrusion 2900 functions to alleviate the warpage of the substrate S and improve the flatness thereof, a stop member may be further provided to limit the amount of pressing of the protrusion 2900. The stop member may have a height lower than that of the protrusion 2900, and may be provided around the protrusion 2900 at a position on the edge of the micro LED suction body F. Since the stop member has a lower height than the protrusion 2900, there may be a height difference between the stop member and the protrusion 2900. The stop member limits the amount of pressing of the protrusion 2900 due to the height difference between the stop member and the protrusion 2900.

The stop member may be made of a material having a modulus of elasticity lower than that of the protrusion 2900. Therefore, the protrusion 2900 may be made of a material having a high modulus of elasticity as opposed to the stop member. The stop member has a property that is not easily deformed in response to application of an external force, while the protrusion 2900 has a property that is deformed relatively easily in response to application of an external force. Therefore, when the micro LED suction body 1′ is lowered, the protrusion 2900 brought into contact with the upper surface of the substrate S before the stop member contracts by an amount corresponding to the height difference with the stop member. Due to the protrusion 2900 contracted by the amount corresponding to the height difference with the stop member, a lower surface of the stop member is brought into contact with the upper surface of the substrate S. At this point, the stop member hardly contracts due to the property of having a low modulus of elasticity, thereby stopping the contraction of the protrusion 2900 and limiting the amount of pressing of the protrusion 2900.

The stop member can contribute to enabling the protrusion 2900 to more efficiently perform warpage alleviation and flatness control of the substrate S. Specifically, the protrusion 2900 primarily alleviates the warpage of the substrate S and controls the flatness thereof while contracting by the amount corresponding to the height difference with the stop member. Then, the stop member secondarily alleviates the warpage of the substrate S and controls the flatness thereof while being brought into contact with the upper surface of the substrate S.

The stop member may be provided continuously or discontinuously around the protrusion 2900 along the periphery of the protrusion 2900. In the case the stop member is provided continuously, the shape thereof is not limited to any shape and may be a shape having a circular cross-section or a quadrangular cross-section. On the other hand, in the case the stop member is provided discontinuously around the protrusion 2900, preferably at least two stop members are provided. The at least two discontinuous stop members are provided around the protrusion 2900, but preferably are provided at opposite positions.

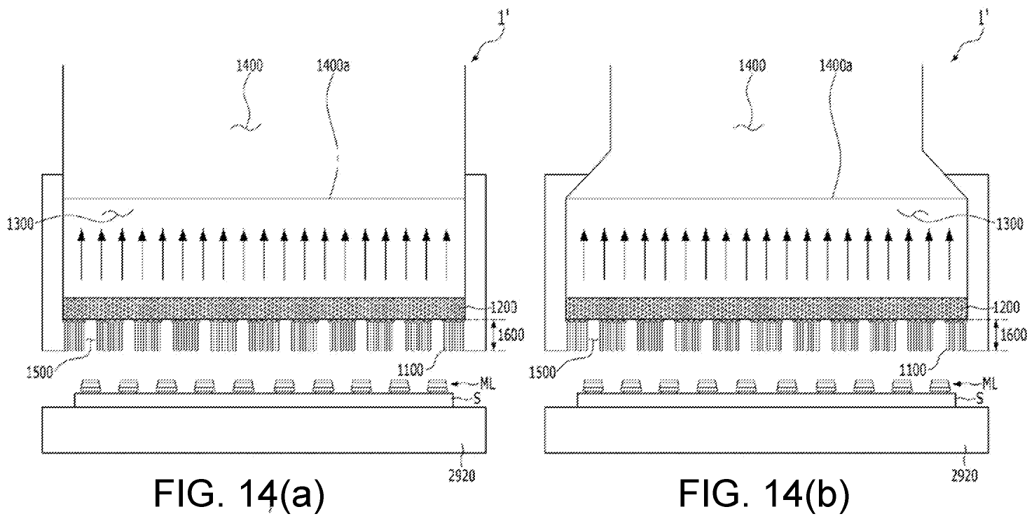

FIG. 14 is a view illustrating embodiments of a suction pipe constituting the micro LED suction body of the present disclosure. In FIG. 14, the micro LED suction body 1′ according to the second embodiment is illustrated as an example, the micro LED suction body is not limited thereto, and the micro LED suction bodies according to the first to sixth embodiments may be possible.

In the case of the micro LED suction body according to the present disclosure, the suction pipe 1400 includes a connection portion 1400a. The connection portion 1400a connects between the vacuum chamber 1300 and the vacuum chamber 1300 to supply a vacuum pressure to the vacuum chamber 1200. The connection portion 1400a has a horizontal area equal to that of an upper surface of the porous member 1000.

The micro LED suction body 1′ may be configured such that the suction member 1100 is embodied by the anodic aluminum oxide film 1600 including the barrier layer 1600b and the second porous member 1100b is embodied by a porous member having arbitrary pores. In this case, the suction member 1100 may be the suction member 1100 embodied by the anodic aluminum oxide film 1600 as an example or may be embodied by a porous member having vertical pores. The suction member 1100 may configured according to the modified examples of the second embodiment.

As illustrated in FIG. 12, the suction pipe 1400 is provided on the vacuum chamber 1300, and the connection portion 1400a is provided between the vacuum chamber 1300 and the suction pipe 1400. The vacuum chamber 1300 and the suction pipe 1400 are connected to each other by the connection portion 1400a. The horizontal area of the connection portion 1400a is equal to that of the upper surface of the suction member 1100 functioning to suck the micro LEDs ML.

The suction pipe 1400 connected to an upper portion of the vacuum chamber 1300 in the vertical direction by the connection portion 1400a having the horizontal area equal to that of the upper surface of the suction member 1100 may have a horizontal area equal to that of the suction member 1100. Since the connection portion 1400a has the same horizontal area as the suction member 1100, a uniform vacuum suction force is generated over the entire suction surface of the suction member 1100 of the micro LED suction body F.

Specifically, the connection portion 1400a functions to connect between the vacuum chamber 1300 and the suction pipe 1400 to allow the vacuum pressure to be introduced into the vacuum chamber 1300 when the vacuum pressure supplied from the vacuum pump is introduced through the suction pipe 1400. In this case, a horizontal range of the vacuum pressure introduced into the support member 1200 and the suction member 1100 may vary depending on the horizontal area of the connection portion 1400a. For example, the horizontal area of the connection portion 1400a connecting between the vacuum chamber 1300 and the suction pipe 1400 is smaller than that of the upper surface of the suction member 1100, and the vacuum pressure supplied from the vacuum pump is transmitted to the support member 1200 and the suction member 1100 through the suction pipe 1400 and the connection portion 1400a. In this case, when the vacuum pressure supplied to the suction pipe 1400 is introduced into the vacuum chamber 1300 through the connection portion 1400a and then sequentially transmitted to the vacuum chamber 1300, the support member 1200 and the suction regions 2000 of the suction member 1100 embodied by the anodic aluminum oxide film 1600, a more vacuum pressure is transmitted to the suction regions 2000 at positions corresponding to a position where the connection portion 1400a is provided. In the case the connection portion 1400a has a horizontal area smaller than that of the upper surface of the suction member 1100, the suction regions 2000 at the positions corresponding to the position where the connection portion 1400a is provided and the suction regions 2000 at positions corresponding to a position where the connection portion 1400a is not provided may receive different amounts of vacuum pressure from the vacuum chamber 1300 through the connection portion 1400a. As a result, the suction force acting on the suction surface of the micro LED suction body 1′ may become uneven.

However, in the case of the micro LED suction body 1′ according to the present disclosure, since the connection portion 1400a connecting between the vacuum chamber 1300 and the suction pipe 1400 has the same horizontal area as the upper surface of the suction member 1100, a uniform suction force is generated over the entire micro LED suction surface which is the lower surface of the suction member 1100, compared to the configuration in which the connection portion 1400a has a smaller horizontal area than the upper surface of the suction member 1100. As a result, it is possible to solve the problem in which when the micro LED suction body 1′ sucks the micro LEDs ML, the micro LEDs ML located at the edge side of the substrate S fail to be sucked on the suction surface due to uneven suction force acting on the suction surface and the micro LEDs ML are detached thereby.

The arrows illustrated in FIG. 14(a) indicate a direction of the uniform suction force generated on the suction surface of the suction member 1100 due to the vacuum pressure supplied from the vacuum chamber 1300.

On the other hand, the suction pipe 1400 may have a horizontal area equal to that of the connection portion 1400a but have different shapes.

As illustrated in FIG. 14(b), the suction pipe 1400 is configured such that a lower portion thereof is expanded and the connection portion 1400a has the same horizontal area as the upper surface of the suction member 1100. The suction pipe 1400 has a shape in which the outer diameter of the lower portion thereof increases downwardly toward the vacuum chamber 1300 and is connected to the vacuum chamber 1300. Therefore, the suction pipe 1400 has a structure in which the lower portion is expanded as the outer diameter increases downwardly and the horizontal area of the connection portion 1400a of the suction pipe 1400 is equal to that of the upper surface of the suction member 1100.

With such a structure, the vacuum chamber 1300 allows a uniform suction force to generate on the suction surface of the suction member 1100. As a result, the uniform suction force acts on the suction surface of the micro LED suction body 1′, thereby allowing the micro LEDs ML to be sucked from the substrate S without the problem of the micro LEDs ML failing to be sucked on the suction surface as the suction force is weakened at any positions on the suction surface.

The connection portion 1400a of the suction pipe 1400 may be provided with a distribution member. The distribution member may be provided in the suction pipe 1400 or in the connection portion 1400a of the suction pipe 1400 inside the vacuum chamber 1300. The distribution member functions as a buffer to make air pressure generated by the vacuum pump uniform in the support member 1200 and the suction member 1100. The distribution member may be embodied by a porous member having arbitrary pores or a porous member having vertical pores. In the case the distribution member is embodied by the porous member having the arbitrary pores, it is possible to disperse the air pressure in a horizontal direction. This makes the vacuum pressure uniform in the suction member 1100 that provides the suction surface. Alternatively, in the case the distribution member is embodied by the porous member having the vertical pores, it is possible to solve the phenomenon in which the vacuum pressure is concentrated at the center of the suction member 1100 that provides the suction surface. The distribution member may have a whole structure in which the number of lower holes provided at a lower end portion thereof is larger than that of upper holes provided at an upper end portion thereof. In this case, the upper holes and the lower holes may communicate with each other via multiple air flow paths. With this structure, the distribution member can uniformize the air pressure at positions corresponding to the lower holes.

On the other hand, multiple suction pipes 1400 may be provided and supply the vacuum pressure to the vacuum chamber 1300. Each of the suction pipes 1400 includes a connection portion 1400a. In the case of the multiple suction pipes 1400, the micro LED suction body 1′ may include a collective pipe connecting the multiple suction pipes 1400 in a collective manner.

The multiple suction pipes 1400 may be provided at positions where the vacuum pressure can be uniformly transmitted to the upper surface of the suction member 1100 via the vacuum chamber 1300. In this case, the multiple suction pipes 1400 may be provided in consideration of the micro LED present region where the micro LEDs ML are formed on the substrate S.

For example, in the case the suction body 1′ is provided with three suction pipes 1400, a first suction pipe, a second suction pipe, and a third suction pipe are provided. The first, second, and third pipes respectively include a first connection portion at a position connected to the center of the vacuum chamber 1300, a second connection portion at a position connected to the outer periphery of the vacuum chamber 1300, and a third connection portion. Here, the center of the vacuum chamber 1300 means a position corresponding to the center in the micro LED present region, and the outer periphery of the vacuum chamber 1300 means a position corresponding to one end and the other end in the micro LED present region. The first to third suction pipes are connected to each other via the collective pipe, and the vacuum pressure supplied from the vacuum pump is transmitted to the multiple suction pipes 1400 via the collective pipe.

The horizontal area of the first connection portion of the first suction pipe may be different from that of the connection portion of each of the second and third suction pipes. Specifically, the first connection portion, which is connected to the center of the vacuum chamber 1300 and into which the vacuum pressure supplied from the vacuum pump is easy to introduce, has a smaller horizontal area than the second and third connection portions, which are connected to the outer periphery of the vacuum chamber 1300 and into which the vacuum pressure is difficult to introduce. As the first to third connection portions have different horizontal areas, the micro LED transfer head controls the amount of vacuum pressure to be introduced, thereby generating a uniform suction force on the suction surface. In other words, in the case of the multiple suction pipes 1400, respective connection portions 1400a of the suction pipes 1400 have different horizontal areas in consideration that the inflow amount of vacuum pressure supplied from the vacuum pump varies depending on the positions of the suction pipes 1400. This ensures that a uniform suction force can be generated on the suction surface.

In the case of the multiple suction pipes 1400, a vortex generating means in the form of a spiral member may be provided in each of the suction pipes 1400. The vortex generating means may be provided inside the second and third suction pipes connected to the outer periphery of the vacuum chamber 1300. The vortex generating means functions to induce the flow of air to be accelerated so that the vacuum pressure supplied from the vacuum pump can be easily transmitted to the suction chamber 1200 via the second and third connection portions.

The multiple suction pipes 1400 may not be connected with each other via the collective pipe but may be connected to individual vacuum pumps capable of being controlled individually to supply the vacuum pressure.

On the other hand, the multiple suction pipes 1400 may include a first suction pipe connected to the center of the vacuum chamber 1300, and a second suction pipe connected to the outer periphery of the vacuum chamber 1300 in a shape continuously surrounding the first suction pipe on the outer periphery of the first suction pipe. Also, in this case, the connection portions of the first and second suction pipes may have different horizontal areas. Specifically, the connection portion of the first suction pipe into which the vacuum pressure is difficult to introduce may have a smaller horizontal area than the connection portion of the second suction pipe. This ensures that a uniform suction force can be generated over the entire suction surface of the micro LED suction body F.

The connection portions of the multiple suction pipes 1400 may be provided with a distribution member. In the case of the multiple suction pipes 1400, the distribution member may be provided in the suction pipe 1400 or in the connection portions 1400a of the suction pipes 1400 inside the vacuum chamber 1300 and/or at a junction of the suction pipes 1400. Here, the junction of the suction pipes 1400 means a portion where the suction pipes 1400 and the collective pipe are connected to each other in a collective manner between the suction pipes 1400 and the collective pipe. In this case, the distribution member may be embodied by the porous member having the arbitrary pores or the porous member having the vertical pores as described above.

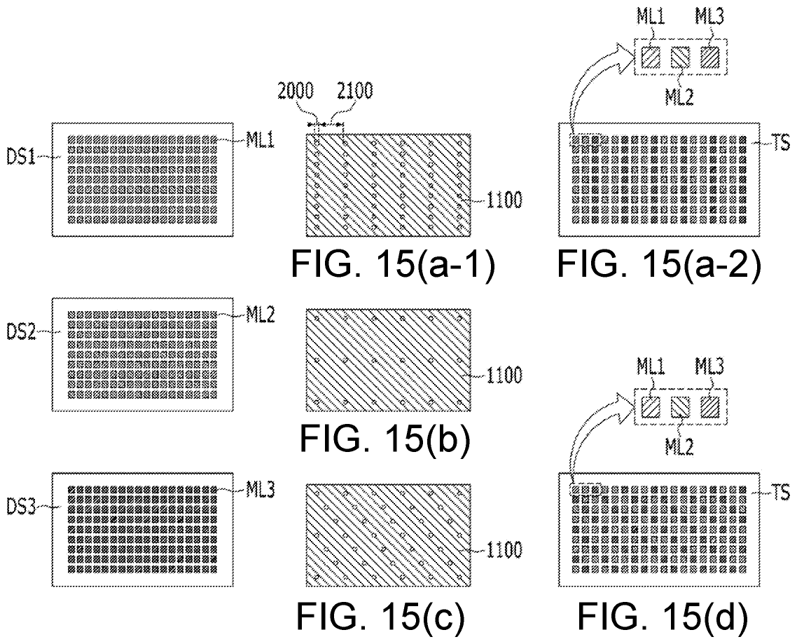

Hereinbelow, an embodiment of the arrangement of the suction regions 2000 of the micro LED suction body according to the present disclosure will be described with reference to FIGS. 15 to 17. Each of the micro LEDs ML to be transferred by the suction regions 2000 may be any one of red ML1, green ML2, blue ML3, and white LEDs. FIGS. 15 to 17 illustrate as an example, the red, green, and blue micro LEDs ML1, ML2, and ML3, in which the red, green, and blue micro LEDs ML1, ML2, and ML3 are transferred to the second substrate (the display substrate 301) to be spaced apart from each other in accordance with the arrangement of the suction regions 2000 to form a pixel array.

The suction regions 2000 are formed to be spaced apart from each other with a regular interval in the column direction (x-direction) and the row direction (y-direction). The pitch of the suction regions 2000 in at least any one of the column direction (x-direction) and the row direction (y-direction) may be equal to or greater than twice the column-direction (x-direction) pitch and the row direction (y-direction) pitch of the micro LEDs ML disposed on the first substrate.

As illustrated in FIG. 15(a-1), when the column-direction (x-direction) pitch and the row-direction (y-direction) pitch of the micro LEDs ML on donor substrates on DS1, DS2, and DS3 are P(n) and P(m), respectively, the column-direction (x-direction) pitch and the row-direction (y-direction) pitch of the suction regions 2000 may be 3P(n) and P(m), respectively. Here, 3p(n) means 3 times the column-direction (x-direction) pitch p(n) of the micro LEDs ML on the donor substrates on DS1, DS2, and DS3. According to the above configuration, the micro LED suction body 1′ vacuum-sucks and transfers only the micro LEDs ML located at (3n)th column. Here, each of the micro LEDs ML transferred to the (3n)th column may be any one of red ML1, green ML2, blue ML3, and white LEDs. With such a configuration, it is possible to transfer the micro LEDs ML of the same luminous color mounted on a target substrate TS with a pitch of 3p(m).

The micro LED suction body 1′ in which the suction regions 2000 having the above pitch are formed selectively sucks the micro LEDs ML disposed on the donor part.

The donor part includes the first donor substrate DS1 on which red micro LEDs ML1 are disposed, the second donor substrate DS2 on which green micro LEDs ML2 are disposed, and the third donor substrate DS3 on which blue micro LEDs ML3 are disposed.

The micro LEDs ML disposed on each of the donor substrates are arranged at a regular interval in the column direction (x-direction) and in the row direction (y-direction). The red, green, and blue micro LEDs ML1, ML2, and ML3 disposed on the first to third donor substrates DS1, DS2, and DS3 are arranged with the same pitches in the column direction (x-direction) and in the row direction (y-direction).

The suction regions 2000 illustrated in FIG. 15 (a-1) is formed with a column-direction (x-direction) pitch three times the column-direction (x-direction) pitch of the micro LEDs ML disposed on the donor part, and with a row-direction (y-direction) pitch equal to the row-direction (y-direction) pitch of the micro LEDs ML disposed on the donor part.

As illustrated in FIG. 15(a-1), the micro LED suction body 1′ configured such that the column-direction (x-direction) pitch and the row-direction (y-direction) pitch of the suction regions 2000 are 3P(n) and P(m), respectively, transfers the red, green, and blue micro LEDs ML1, ML2, and ML3 to the target substrate TS while reciprocating three times between the first to third donor substrates DS1, DS2, and DS3 and the target substrate TS so that the red, green, and blue micro LEDs ML1, ML2, and ML3 form a 1×3 pixel array.

Specifically, as illustrated in FIG. 15, the red micro LEDs ML1 are disposed on the first donor substrate DS1 with a regular interval. The micro LED suction body 1′ is lowered toward the first donor substrate DS1 to selectively suck the red micro LEDs ML1 located at positions corresponding to the suction regions 2000. Referring to FIG. 15(a-1), the micro LED suction body 1′ selectively vacuum-sucks the red micro LEDs ML located at 1st, 4th 7th, 10th, 13th, and 16th columns on the substrate S. When the suction is completed, the micro LED suction body 1′ is lifted and then moved horizontally to a position over the target substrate TS. After that, the micro LED suction body 1′ is lowered to collectively transfer the red micro LEDs ML1 onto the target substrate TS.

Then, the micro LED suction body 1′ sucks the green micro LED ML2 on the second donor substrate DS2 and transfers the same to the target substrate TS. At this point, the micro LED suction body 1′ is moved to the right side in the drawing by a distance corresponding to the x-direction pitch of the micro LEDs ML with respect to the red micro LEDs ML1 already transferred on the target substrate TS, and collectively transfers the green micro LED ML2 onto the target substrate TS.

Then, the micro LED suction body 1′ is moved to a position over the third donor substrate DS3. Then, the micro LED suction body 1′ sucks the blue micro LED ML3 on the third donor substrate DS3 and transfers the same to the target substrate TS by the same process as the previous one of transferring the red micro LEDs ML1. At this point, the micro LED suction body 1′ is moved to the right side in the drawing by a distance corresponding to the x-direction pitch of the micro LEDs ML with respect to the green micro LEDs ML2 already transferred on the target substrate TS, and collectively transfers the blue micro LED ML3 onto the target substrate TS.

The target substrate TS of a 1×3 pixel array according to such a configuration may be implemented as illustrated in FIG. 15(a-2). Here, the target substrate TS may be the display substrate 301 illustrated in FIG. 2, or may be a temporary substrate or a carrier substrate transferred from the growth substrate 101.

On the other hand, as illustrated in FIG. 15(b), the column-direction (x-direction) pitch and the row-direction (y-direction) pitch of the suction regions 2000 may be 3P(n) and 3P(m), respectively. According to the above configuration, the micro LED suction body 1′ vacuum-sucks and transfers only the micro LEDs ML located at (3n)th column and (3n)th row. Here, each of the micro LEDs ML transferred to the (3n)th column and (3n)th row may be any one of red, green, and blue micro LEDs ML1, ML2, and ML3. With such a configuration, it is possible to transfer the micro LEDs ML of the same luminous color mounted on the display substrate 301 with pitches of 3p(n) and 3p(m).

The suction regions 2000 illustrated in FIG. 15 (b) is formed with a column-direction (x-direction) pitch thereof three times the column-direction (x-direction) pitch of the micro LEDs ML disposed on the donor part, and with a row-direction (y-direction) pitch three times the row-direction (y-direction) pitch of the micro LEDs ML disposed on the donor part.

As illustrated in FIG. 15(b), the micro LED suction body 1′ configured such that the column-direction (x-direction) pitch and the row-direction (y-direction) pitch of the suction regions 2000 are 3P(n) and 3P(m), respectively, transfers the red, green, and blue micro LEDs ML1, ML2, and ML3 to the target substrate TS while reciprocating nine times between the first to third donor substrates DS1, DS2, and DS3 and the target substrate TS so that the red, green, and blue micro LEDs ML1, ML2, and ML3 form a 1×3 pixel array.

Specifically, during first transfer, the micro LED suction body 1′ selectively sucks the red micro LEDs ML1 from the first donor substrate DS1 and collectively transfers the red micro LEDs ML1 to the target substrate TS. During second transfer, the micro LED suction body 1′ selectively sucks the green micro LEDs ML2 from the second donor substrate DS2, is moved to the right side in the drawing by a distance corresponding to the x-direction pitch of the micro LEDs ML with respect to the red micro LEDs ML1 already transferred on the target substrate TS, and collectively transfers the green micro LEDs ML2 onto the target substrate TS. Then, during third transfer, the micro LED suction body 1′ selectively sucks the blue micro LEDs ML3 from the third donor substrate DS3. The micro LED suction body 1′ is then moved to the right side in the drawing by a distance corresponding to the x-direction pitch of the micro LEDs ML with respect to the green micro LEDs ML2 already transferred on the target substrate TS, and collectively transfers the blue micro LEDs ML3 onto the target substrate TS.

Then, during fourth transfer, the micro LED suction body 1′ selectively sucks the red micro LEDs ML1 from the first donor substrate DS1. The micro LED suction body 1′ is then moved to the lower side in the drawing by a distance corresponding to the y-direction pitch of the micro LEDs ML with respect to the green micro LEDs ML2 already transferred on the target substrate TS, and collectively transfers the red micro LEDs ML1 onto the target substrate TS. Then, during fifth transfer, the micro LED suction body 1′ selectively sucks the green micro LEDs ML2 from the second donor substrate DS2. The micro LED suction body 1′ is then moved to the right side in the drawing by a distance corresponding to the x-direction pitch of the micro LEDs ML with respect to the red micro LEDs ML1 already transferred on the target substrate TS during fourth transfer, and collectively transfers the green micro LEDs ML onto the target substrate TS. Then, during sixth transfer, the micro LED suction body 1′ selectively sucks the blue micro LEDs ML3 from the third donor substrate DS3. The micro LED suction body 1′ is then moved to the right side in the drawing by a distance corresponding to the x-direction pitch of the micro LEDs ML with respect to the green micro LEDs ML2 already transferred on the target substrate TS during fifth transfer, and collectively transfers the blue micro LEDs ML3 onto the target substrate TS.

Then, during seventh transfer, the micro LED suction body 1′ selectively sucks the red micro LEDs ML1 from the first donor substrate DS1. The micro LED suction body 1′ is then moved to the lower side in the drawing by a distance corresponding to the y-direction pitch of the micro LEDs ML with respect to the blue micro LEDs ML3 already transferred on the target substrate TS, and collectively transfers the red micro LEDs ML1 onto the target substrate TS. Then, during eighth transfer, the micro LED suction body 1′ selectively sucks the green micro LEDs ML2 from the second donor substrate DS2. The micro LED suction body 1′ is then moved to the right side in the drawing by a distance corresponding to the x-direction pitch of the micro LEDs ML with respect to the red micro LEDs ML1 already transferred on the target substrate TS during seventh transfer, and collectively transfers the green micro LEDs ML2 onto the target substrate TS. Then, during ninth transfer, the micro LED suction body 1′ selectively sucks the blue micro LEDs ML3 from the third donor substrate DS3. The micro LED suction body 1′ is then moved to the right side in the drawing by a distance corresponding to the x-direction pitch of the micro LEDs ML with respect to the green micro LEDs ML2 already transferred on the target substrate TS during eighth transfer, and collectively transfers the blue micro LEDs ML3 onto the target substrate TS.

The target substrate TS of a 1×3 pixel array according to such a configuration may be implemented as illustrated in FIG. 15(d). Here, the target substrate TS may be the display substrate 301 illustrated in FIG. 2, or may be the temporary substrate or the carrier substrate transferred from the growth substrate.

On the other hand, as illustrated in FIG. 15(c), the suction regions 2000 may be formed with a pitch equal to a diagonal-direction pitch of the micro LEDs ML disposed on the donor part. With this configuration, the micro LED suction body 1′ transfers the red, green, and blue micro LEDs ML1, ML2, and ML3 to the target substrate TS while reciprocating three times between the first to third donor substrates DS1, DS2, and DS3 and the target substrate TS so that the red, green, and blue micro LEDs ML1, ML2, and ML3 form a 1×3 pixel array.

Specifically, during first transfer, the micro LED suction body 1′ selectively sucks the red micro LEDs ML1 from the first donor substrate DS1 and collectively transfers the red micro LEDs ML1 to the target substrate TS. During second transfer, the micro LED suction body 1′ selectively sucks the green micro LEDs ML2 from the second donor substrate DS2, is moved to the right side in the drawing by a distance corresponding to the x-direction pitch of the micro LEDs ML with respect to the red micro LEDs ML1 already transferred on the target substrate TS, and collectively transfers the green micro LEDs ML2 onto the target substrate TS. Then, during third transfer, the micro LED suction body 1′ selectively sucks the blue micro LEDs ML3 from the third donor substrate DS3. The micro LED suction body 1′ is then moved to the right side in the drawing by a distance corresponding to the x-direction pitch of the micro LEDs ML with respect to the green micro LEDs ML2 already transferred on the target substrate TS, and collectively transfers the blue micro LEDs ML3 onto the target substrate TS.

The target substrate TS of a 1×3 pixel array according to such a configuration may be implemented as illustrated in FIG. 15(d). Here, the target substrate TS may be the display substrate 301 illustrated in FIG. 2, or may be the temporary substrate or the carrier substrate transferred from the growth substrate 101.

On the other hand, the micro LED suction body 1′ may be configured such that the x-direction pitch of the suction regions 2000 is twice the x-direction pitch of the micro LEDs ML disposed on the substrate including the first substrate, and the y-direction pitch of the suction regions 2000 is twice the y-direction pitch of the micro LEDs ML disposed on the first substrate. Therefore, the micro LED suction body 1′ selectively sucks the micro LEDs ML disposed on the first substrate. In this case, the first substrate may include the first to third donor substrates DS1, DS2, and DS3.

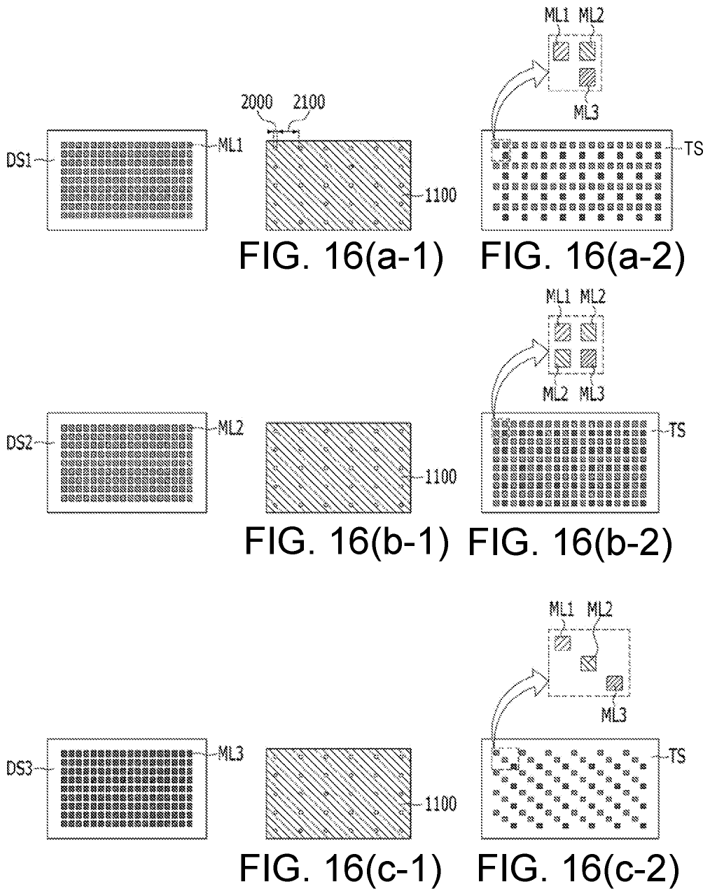

Thus, as illustrated in FIG. 16(a-1), the suction regions 2000 may be formed with a pitch twice the column-direction (x-direction) pitch and the row-direction (y-direction) pitch of the micro LEDs ML disposed on the donor part. With this configuration, the micro LED suction body 1′ transfers the red, green, and blue micro LEDs ML1, ML2, and ML3 to the target substrate TS while reciprocating three times between the first to third donor substrates DS1, DS2, and DS3 and the target substrate TS so that the red, green, and blue micro LEDs ML1, ML2, and ML3 form a 2×2 pixel array.

Specifically, during first transfer, the micro LED suction body 1′ selectively sucks the red micro LEDs ML1 from the first donor substrate DS1 and collectively transfers the red micro LEDs ML1 to the target substrate TS. During second transfer, the micro LED suction body 1′ selectively sucks the green micro LEDs ML2 from the second donor substrate DS2, is moved to the right side in the drawing by a distance corresponding to the x-direction pitch of the micro LEDs ML with respect to the red micro LEDs ML already transferred on the target substrate TS, and collectively transfers the green micro LEDs ML2 onto the target substrate TS. Then, during third transfer, the micro LED suction body 1′ selectively sucks the blue micro LEDs ML3 from the third donor substrate DS3. The micro LED suction body 1′ is then moved to the lower side in the drawing by a distance corresponding to the y-direction pitch of the micro LEDs ML with respect to the green micro LEDs ML2 already transferred on the target substrate TS during second transfer, and collectively transfers the blue micro LEDs ML3 onto the target substrate TS.

The target substrate TS of a 2×2 pixel array according to such a configuration may be implemented as illustrated in FIG. 16(a-2). Here, the target substrate TS may be the display substrate 301 illustrated in FIG. 2, or may be the temporary substrate or the carrier substrate transferred from the growth substrate 101.

The suction regions 2000 may be formed with a pitch twice the column-direction (x-direction) pitch and the row-direction (y-direction) pitch of the micro LEDs ML disposed on the donor part. Thus, as illustrated in FIG. 16(a-2), a 2×2 pixel array may be formed with only three micro LEDs ML1, ML2, and ML3 on the target substrate TS. In this case, a margin region on which additional micro LEDs ML are mounted exists. In consideration of the improvement of individual light emission characteristics of the micro LEDs ML, improvement of visibility, and/or the presence of defective products, the additional micro LED ML may be transferred to the margin region in an empty 2×2 pixel array to form a 2×2 pixel array with a total of 4 micro LEDs.

The micro LED suction body 1′ may additionally transfers any one of the red, green, and blue micro LEDs ML1, ML2, and ML3 to the target substrate TS while reciprocating one time between the first to third donor substrates DS1, DS2, and DS3 and the target substrate TS so that four red, green, and blue micro LEDs ML1, ML2, and ML3 may form a 2×2 pixel array. Here, the additionally transferred micro LED ML may be any one of red, green, and blue micro LEDs ML1, ML2, and ML3. The target substrate TS of a 2×2 pixel array formed by additionally transferring the micro LED ML to the margin region may be implemented as illustrated in FIG. 16(b-2). In FIG. 16(b-2), the micro LED ML transferred to the margin region is illustrated as being a green micro LED ML2, but the micro LED ML transferred to the margin region is not limited thereto, and any one of the blue micro LEDs ML1 and ML3 may be additionally transferred.

Thus, it is possible to supplement the light emission characteristics or visibility of the micro LEDs ML, and when a missing micro LED ML exists because the micro LEDs ML fail to be properly transferred or a defective micro LED ML exists, it is possible to improve image quality of a display device by additionally mounting a normal micro LED ML.

On the other hand, as illustrated in FIG. 16(c-1), the suction regions 2000 may be formed with a pitch three times the column-direction (x-direction) pitch and the row-direction (y-direction) pitch of the micro LEDs ML disposed on the donor part. In FIG. 16(c-1), the pitch of the suction regions 2000 is illustrated as being equal to the pitch of those illustrated FIGS. 16(a-1) and 16(b-1), but this is for convenience of description. Therefore, the pitch of the suction regions 2000 illustrated here is different from the pitch of those illustrated FIGS. 16(a-1) and 16(b-1).

With this configuration, the micro LED suction body 1′ transfers the red, green, and blue micro LEDs ML1, ML2, and ML3 to the target substrate TS while reciprocating three times between the first to third donor substrates DS1, DS2, and DS3 and the target substrate TS so that the red, green, and blue micro LEDs ML1, ML2, and ML3 form a 3×3 pixel array.

Specifically, during first transfer, the micro LED suction body 1′ selectively sucks the red micro LEDs ML1 from the first donor substrate DS1 and collectively transfers the red micro LEDs ML1 to the target substrate TS. During second transfer, the micro LED suction body 1′ selectively sucks the green micro LEDs ML2 from the second donor substrate DS2, is moved to the right side in the drawing by a distance corresponding to the x-direction pitch of the micro LEDs ML and to the lower side by a distance corresponding to the y-direction pitch of the micro LEDs ML with respect to the red micro LEDs ML1 already transferred on the target substrate TS, and collectively transfers the green micro LEDs ML2 onto the target substrate TS. Then, during third transfer, the micro LED suction body 1′ selectively sucks the blue micro LEDs ML3 from the third donor substrate DS3. The micro LED suction body 1′ is then moved to the lower side in the drawing by a distance corresponding to the x-direction pitch of the micro LEDs ML and to the lower side by a distance corresponding to the y-direction pitch of the micro LEDs ML with respect to the green micro LEDs ML2 already transferred on the target substrate TS during second transfer, and collectively transfers the blue micro LEDs ML3 onto the target substrate TS. With this configuration in which the micro LED suction body 1′ reciprocates three times between the first to third donor substrates DS1, DS2, and DS3 and the target substrate TS, three red, green, and blue micro LEDs ML1, ML2, and ML3 form a 3×3 pixel array.

On the other hand, in the case the suction regions 1110 are formed with a pitch equal to the column-direction (x-direction) pitch and the row-direction (y-direction) pitch of the micro LEDs ML disposed on the substrate S, the micro LED suction body 1′ may collectively suck all the micro LEDs ML from the substrate S.

The suction regions 2000 may be formed in an arrangement in which the micro LEDs ML of the growth substrate 101 are transferred to the target substrate TS at an extended pitch than the pitch of the micro LEDs ML of the growth substrate 101. Therefore, the micro LEDs ML of the growth substrate 101 may be transferred to the target substrate TS so that the extended pitch between each of the micro LEDs is the same.

Specifically, the micro LED suction body 1′ selectively sucks the micro LEDs ML disposed on the first substrate (e.g., the growth substrate 101). Here, the pitch of the suction regions 2000 in one direction is M/3 times the pitch of the micro LEDs ML disposed on the first substrate (e.g., the growth substrate 101) in one direction, and M is an integer equal to or greater than 4.

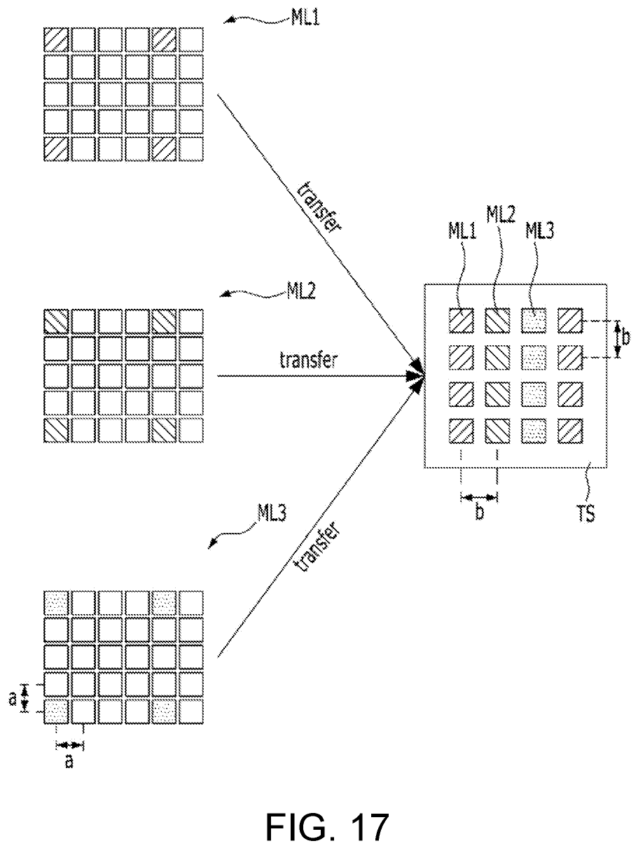

Referring to FIG. 17, a second pitch b of the micro LEDs ML of the target substrate TS is M/3 times a first pitch a of the micro LEDs ML of the donor part. In this case, the pitch of the suction regions 2000 on which the micro LEDs ML of the target substrate TS are sucked is M/3 times the pitch of the micro LEDs ML of the growth substrate 101, and M is an integer equal to or greater than 4.

In order to transfer the micro LEDs ML to the target substrate TS with the second pitch b that is M/3 times the first pitch a of the micro LEDs ML of the donor part, the suction regions 2000 on which the micro LEDs ML of the donor part are sucked may be formed with a pitch equal to or greater than four times the first pitch a of the micro LEDs ML of the donor part. Hereinafter, the suction regions 2000 on which the micro LEDs ML of the donor part are sucked will be described, as an example, as being formed with a pitch four times the first pitch a of the micro LEDs ML of the donor part. Here, a maximum pitch of the suction regions 2000 is a minimum distance required to form a pixel on the target substrate TS.

The micro LED suction body 1′, which is provided with the suction regions 2000 formed with a pitch that is four times the first pitch a of the micro LEDs ML of the donor part, may suck the micro LEDs ML of the donor part and transfer the same to the target substrate TS as illustrated in FIG. 17 so that the suction regions 2000 have a second pitch b that is M/3 times the first pitch a of the micro LEDs ML of the donor part.

Specifically, the red micro LEDs ML1 are disposed on the first donor substrate DS1 with the first pitch a. The green micro LEDs ML2 are disposed on the second donor substrate DS2 with the first pitch a, and blue micro LEDs ML3 are disposed on the third donor substrate DS3 with first pitch a. During first transfer, the micro LED suction body 1′ is lowered toward the first donor substrate DS1 to selectively suck the red micro LEDs ML1 in row 1 and column 1, row 1 and column 5, row 5 and column 1, and row 5 and column 5, which are located at positions corresponding to the suction regions 2000. After that, the micro LED suction body 1′ is moved to a position over the target substrate TS to collectively transfer the red micro LEDs ML1 onto the target substrate TS. During second transfer, the micro LED suction body 1′ selectively sucks the green micro LEDs ML2 in row 1 and column 1, row 1 and column 5, row 5 and column 1, and row 5 and column 5 on the second donor substrate DS2. Then, the micro LED suction body 1′ is moved to the right side in the drawing by a distance corresponding to the second pitch b in the x-direction of the micro LEDs ML with respect to the red micro LEDs ML1 already transferred on the target substrate TS, and collectively transfers the green micro LED ML2 onto the target substrate TS. Then, during third transfer, the micro LED suction body 1′ is moved to a position over the third donor substrate DS3. The micro LED suction body 1′ sucks the blue micro LED ML3 in row 1 and column 1, row 1 and column 5, row 5 and column 1, and row 5 and column 5 on the third donor substrate DS3 and transfers the same to the target substrate TS. In this case, the micro LED suction body 1′ is moved to the right side in the drawing by a distance corresponding to the second pitch b in the x-direction of the micro LEDs ML with respect to the green micro LEDs ML2 already transferred on the target substrate TS during second transfer, and collectively transfers the blue micro LED ML3 onto the target substrate TS.

Then, during fourth transfer, the micro LED suction body 1′ selectively sucks the red micro LEDs ML1 from the first donor substrate DS1, which are located at positions corresponding to the suction regions 2000, is moved to the lower side in the drawing by a distance corresponding to the second pitch b in the y-direction with respect to the red micro LEDs ML1 already transferred on the target substrate TS during first transfer, and collectively transfers the red micro LEDs ML1 onto the target substrate TS. Then, during fifth transfer, the micro LED suction body 1′ selectively sucks the green micro LEDs ML2 from the second donor substrate DS2, which are located at positions corresponding to the suction regions 2000, is moved to the right side in the drawing by a distance corresponding to the second pitch b in the x-direction with respect to the red micro LEDs ML1 already transferred on the target substrate TS during fourth transfer, and collectively transfers the green micro LEDs ML2 onto the target substrate TS. Then, during sixth transfer, the micro LED suction body 1′ selectively sucks the blue micro LEDs ML3 from the third donor substrate DS3, which are located at positions corresponding to the suction regions 2000, is moved to the right side in the drawing by a distance corresponding to the second pitch b in the x-direction with respect to the green micro LEDs ML2 already transferred on the target substrate TS during fifth transfer, and collectively transfers the blue micro LEDs ML3 onto the target substrate TS.

Then, during seventh transfer, the micro LED suction body 1′ selectively sucks the red micro LEDs ML1 from the first donor substrate DS1, which are located at positions corresponding to the suction regions 2000, is moved to the lower side in the drawing by a distance corresponding to the second pitch b in the y-direction with respect to the red micro LEDs ML1 already transferred on the target substrate TS during fourth transfer, and collectively transfers the red micro LEDs ML1 onto the target substrate TS. Then, during eighth transfer, the micro LED suction body 1′ selectively sucks the green micro LEDs ML2 by the same process as in the fifth transfer process, is moved to the right side in the drawing by a distance corresponding to the second pitch b in the x-direction with respect to the red micro LEDs ML1 already transferred on the target substrate TS during seventh transfer, and collectively transfers the green micro LEDs ML2 onto the target substrate TS. Then, during ninth transfer, the micro LED suction body 1′ selectively sucks the blue micro LEDs ML3 by the same process as in the sixth transfer process, is moved to the right side in the drawing by a distance corresponding to the second pitch b in the x-direction with respect to the green micro LEDs ML2 already transferred on the target substrate TS during eighth transfer, and collectively transfers the blue micro LEDs ML3 onto the target substrate TS.

As described above, due to the suction regions 2000 having a pitch four times the first pitch a of the micro LED ML of the donor part, the micro LEDs ML1, ML2, and ML3 are transferred to the target substrate TS with the same column-direction (x-direction) and row-direction (y-direction) pitches, which are greater than the column-direction (x-direction) and row-direction (y-direction) pitches of the micro LEDs ML of the donor part.

With such an arrangement of the suction regions 2000, the micro LED suction body 1′ transfers the red, green, and blue micro LEDs ML1, ML2, and ML3 to the target substrate TS while reciprocating nine times between the first to third donor substrates DS1, DS2, and DS3 and the target substrate TS so that three red, green, and blue micro LEDs ML1, ML2, and ML3 form a 1×3 pixel array, and the same type of micro LEDs ML are transferred to the same column.

A transfer method in which the same type of micro LEDs ML are transferred to the same column is not limited to the above-described transfer method. The micro LED suction body 1′ may transfer the micro LEDs ML by a suitable method whereby the same type of micro LEDs ML are transferred to the same column of the target substrate TS.

On the other hand, the micro LED suction body 1′ may be moved in the column direction (x-direction) and the row direction (y-direction) over the target substrate TS and may transfer the micro LEDs so that three micro LEDs ML1, ML2, and ML3 form a 1×3 pixel array on the target substrate TS, which is different from the arrangement in which the same type of micro LEDs ML are transferred to the same column.

Specifically, the micro LED suction body 1′ may be moved to the right side by a distance corresponding to the second pitch b in the x-direction and to the lower side by a distance corresponding to the second pitch b in the y-direction with respect to the already transferred the same type of micro LEDs ML. During first transfer, the micro LED suction body 1′ selectively sucks the red micro LEDs ML1 from the first donor substrate DS1 and collectively transfers the red micro LEDs ML1 to the target substrate TS. During second transfer, the micro LED suction body 1′ selectively sucks the green micro LEDs ML2 from the second donor substrate DS2, is moved to the right side in the drawing by a distance corresponding to the second pitch b in the x-direction with respect to the red micro LEDs ML1 already transferred on the target substrate TS, and collectively transfers the green micro LEDs ML2 onto the target substrate TS. Then, during third transfer, the micro LED suction body 1′ selectively sucks the blue micro LEDs ML3 from the third donor substrate DS3, is moved to the right side in the drawing by a distance corresponding to the second pitch b in the x-direction with respect to the green micro LEDs ML2 already transferred on the target substrate TS during second transfer, and collectively transfers the blue micro LEDs ML3 onto the target substrate TS.

Then, during fourth transfer, the micro LED suction body 1′ selectively sucks the red micro LEDs ML1 from the first donor substrate DS1, is moved to the lower side in the drawing by a distance corresponding to the second pitch b in the y-direction and to the right side by a distance corresponding to the second pitch b in the x-direction with respect to the red micro LEDs ML1 already transferred on the target substrate TS during first transfer, and collectively transfers the red micro LEDs ML onto the target substrate TS. Then, during fifth transfer, the micro LED suction body 1′ selectively sucks the green micro LEDs ML2 from the second donor substrate DS2, is moved to the lower side in the drawing by a distance corresponding to the second pitch b in the y-direction and to the right side by a distance corresponding to the second pitch b in the x-direction with respect to the green micro LEDs ML2 already transferred on the target substrate TS during second transfer, and collectively transfers the green micro LEDs ML2 onto the target substrate TS. Then, during sixth transfer, the micro LED suction body 1′ selectively sucks the blue micro LEDs ML3 from the third donor substrate DS3, is moved to the lower side in the drawing by a distance corresponding to the second pitch b in the y-direction and to the right side by a distance corresponding to the second pitch b in the x-direction with respect to the blue micro LEDs ML3 already transferred on the target substrate TS during third transfer, and collectively transfers the blue micro LEDs ML3 onto the target substrate TS.

As described above, the micro LED suction body 1′ transfers the micro LEDs by moving to the right side by a distance corresponding to the second pitch b in the x-direction and to the lower side by a distance corresponding to the second pitch b in the y-direction with respect to the same type of micro LEDs ML already transferred. Thus, it is possible to implement an arrangement in which the same type of micro LEDs ML are disposed on the target substrate TS in the diagonal direction.

As described with reference to FIG. 17, in the case the suction regions 2000 being formed in an arrangement in which the micro LEDs ML of the first substrate are transferred to the second substrate at an extended pitch than the pitch of those of the first substrate, it is possible to increase the pitch of the micro LEDs ML after the process of individualizing the micro LEDs ML without requiring a separate film extension means, and to extend the pitch of tens or tens of thousands of micro LEDs ML to the same pitch.

The micro LED suction body according to the present disclosure can be used to manufacture a micro LED display D. In the case of collectively transferring the micro LEDs ML transferred to the second substrate TS at an extended pitch to a third substrate, it is preferable to use a micro LED suction body 1′ configured such that a first-direction pitch of the suction regions 2000 is M/3 times a first-direction pitch of the micro LEDs ML disposed on the first substrate, and M is an integer.

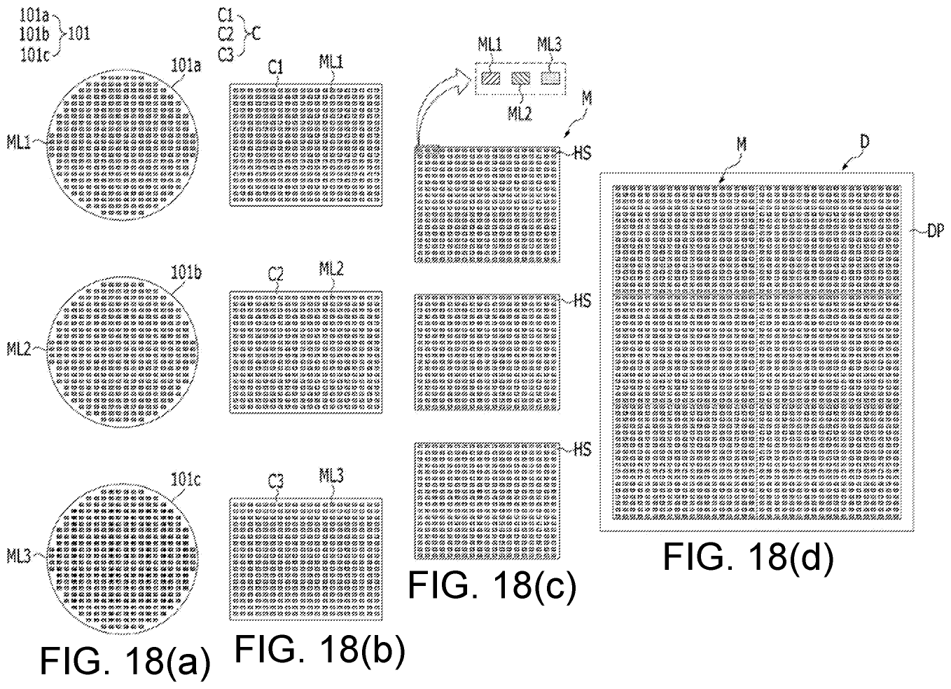

FIGS. 18(a) to 18(d) are views schematically illustrating a process of manufacturing a micro LED display D using the micro LED suction body according to the present disclosure.

In the following description with reference to FIG. 18, the micro LED suction body will be described as being configured such that the first-direction pitch of the suction regions 2000 is M/3 times the first-direction pitch of the micro LEDs ML disposed on the first substrate, and M is an integer.

To manufacture the micro LED display D, the micro LED suction body may perform a process of sucking the micro LEDs of the first substrate and transferring the micro LEDs to the second substrate. In this case, the first substrate from which the micro LED suction body sucks the micro LEDs ML may be the growth substrate 101 or the carrier substrate C. On the other hand, the second substrate onto which the micro LED suction body transfers the micro LEDs ML of the first substrate may be the carrier substrate C or a circuit board HS.

The first substrate and the second substrate may be classified into a substrate from which the micro LED suction body sucks the micro LEDs ML and a substrate onto which the sucked micro LEDs ML are transferred.

Specifically, the first substrate means a substrate from which the micro LED suction body sucks the micro LEDs ML. In addition, the second substrate means a substrate onto which the micro LED suction body transfers the micro LEDs ML sucked from the first substrate. Therefore, in the case the micro LED suction body sucks the micro LEDs ML of the growth substrate 101, the growth substrate 101 may be the first substrate. In addition, in the case the micro LEDs ML of the growth substrate 101 is sucked and transferred to the carrier substrate C, the second substrate may be the carrier substrate C.

On the other hand, in the case the micro LED suction body sucks the micro LEDs ML of the carrier substrate C and transfers the same to the circuit board HS, the first substrate may be the temporary substrate HS, and the second substrate may be the circuit board HS. As such, the first substrate and the second substrate may be classified into the substrate from which the micro LED suction body sucks the micro LEDs ML and the substrate onto which the sucked micro LEDs ML are transferred.

A method of manufacturing a micro LED display D includes the steps of: preparing a first substrate provided with micro LEDs ML; preparing a circuit board HS; a manufacturing a unit module M by transferring the micro LEDs ML of the first substrate to the circuit board HS using a micro LED suction body 1′ configured such that a first-direction pitch of suction regions 2000 is M/3 times a first-direction pitch of the micro LEDs ML disposed on the first substrate, and M is an integer equal to or greater than 4; preparing a display wiring board DP; and mounting the unit module M on the display wiring board DP by transferring the unit module M to the display wiring board DP so that a micro LED ML pixel array in the display wiring board DP is equal to a micro LED ML pixel array in the unit module M and the pitch of the pixel array in the display wiring board DP is equal to the pitch of the pixel array in the unit module M.

The step of preparing the first substrate provided with the micro LEDs ML may be a preparation step of manufacturing the micro LEDs ML on a growth substrate 101 through an epitaxial process. The growth substrate 101 may include a first growth substrate 101a provided with red micro LEDs ML, a second growth substrate 102a provided with green micro LEDs ML, and a third growth substrate 103a provided with blue micro LEDs ML.

As illustrated in FIG. 18(a), the micro LEDs ML1, ML2, and ML3 are manufactured and prepared on the respective growth substrates 101a, 101b, and 101c through the epitaxial process. Therefore, multiple first substrates may be provided.

The micro LEDs ML1, ML2, and ML3 of the growth substrates 101a, 101b, and 101c may be transferred to associated carrier substrates C or the circuit board HS with a regular pitch by the micro LED suction body. The carrier substrate C may include a first carrier substrate C1 onto which the red micro LEDs ML1 are transferred, a second carrier substrate C2 onto which the green micro LEDs ML2 are transferred, and a third carrier substrate C3 onto which the blue micro LEDs ML3 are transferred.

First, when the micro LEDs ML1, ML2, and ML3 of the growth substrates 101a, 101b, and 101c are transferred to the associated carrier substrates C1, C2, and C3, respectively, the carrier substrates C1, C2, and C3 function as second substrates onto which the micro LEDs ML1, ML2, and ML3 of the first substrates 101a, 101b, and 101c are transferred. A form in which the micro LEDs ML1, ML2, and ML3 are transferred respectively to the associated carrier substrates C1, C2, and C3 may be implemented as illustrated in FIG. 18(b). Each of the carrier substrates C1, C2, and C3 may be in the form in which the same type of micro LEDs are formed with a regular pitch.

To transfer the micro LEDs ML of the carrier substrate C to the circuit board HS, the step of preparing the circuit board HS may be performed. The micro LEDs ML of the carrier substrate C may be transferred to the prepared circuit board HS by the micro LED suction body.

The micro LED suction body configured such that the first-direction pitch of the suction regions 2000 is M/3 times the first-direction pitch of the micro LEDs ML disposed on the first substrate and M is an integer equal to or greater than 4 may selectively suck and transfer the micro LEDs ML. As a result, the micro LEDs ML1, ML2, and ML3 of the carrier substrate C may be transferred to one circuit board HS with a regular pitch. In this case, the same type of micro LEDs ML may be transferred to the same column. A 1×3 pixel array is formed on the circuit board HS on which the micro LEDs ML1, ML2, and ML3 are transferred with a regular pitch. As the 1×3 pixel array is formed on the circuit board HS, the unit module M having the 1×3 pixel array is manufactured. In the step of manufacturing the unit module M as described above, a process of mounting different types of micro LEDs ML1, ML2, and ML3 on the circuit board HS to form a pixel array may be performed. As illustrated in FIG. 18(c), multiple unit modules M may be individually provided. The multiple unit modules M configured by transferring the micro LEDs ML to the circuit board HS may enable the implementation of a borderless (bezel-less) large-area display.

A relatively small number of micro LEDs ML may be mounted on each of the multiple unit modules M through the unit module manufacturing step. This allows inspection of normal and defective products to be performed easily, and allows a repair process based on such inspection to be performed easily. Thus, it is possible to mount the unit module M composed only of normal micro LEDs on a large-area display, thereby improving the yield of a large-area display manufacturing process and reducing the manufacturing time.

Then, the step of preparing the display wiring board DP for transferring the unit module M may be performed. Then, the step of mounting the multiple unit modules M on the prepared display wiring board DP may be performed.

The step of mounting the unit modules M may be performed by providing a suction body for transferring the unit modules M to the display wiring board DP separately from the micro LED suction body. In the step of mounting the unit modules M on the display wiring board DP, a process of transferring the multiple unit modules M to the display wiring board DP may be performed. Accordingly, a micro LED pixel array in the display wiring board DP may be formed to correspond to a micro LED pixel array in the unit modules M. In addition, the pixel pitch of the micro LED pixel array in the display wiring board DP may be equal to the pixel pitch of the micro LED pixel array in the unit modules M.

Specifically, as illustrated in FIG. 18(d), a 1×3 micro LED pixel array is formed on the display wiring board DP as a result of transferring the unit modules M. The micro LEDs may be transferred to the display wiring board DP with a pitch equal to the pixel pitch of the micro LED pixel array formed by transferring the micro LEDs ML1, ML2, and ML3 to the circuit board HS by the micro LED suction body, which is configured such that the first-direction pitch of the suction regions 2000 is M/3 times the first-direction pitch of the micro LEDs ML disposed on the first substrate and M is an integer equal to or greater than 4. The micro LED pixel array and the pixel pitch configured as such may correspond to those of the micro LED display D implemented as illustrated in FIG. 18(d).

As described above, the micro LED display D may be manufactured by the steps of manufacturing and preparing the micro LEDs ML on the growth substrate 101 through the epitaxial process, manufacturing the unit module M by transferring the micro LEDs ML of the growth substrate 101 to the carrier substrate C and then transferring the micro LEDs ML of the carrier substrate C to the circuit board HS prepared in the circuit board HS preparation step, and mounting the unit module M on the display wiring board DP.

On the other hand, the micro LED display D may be manufactured by the steps of manufacturing and preparing micro LEDs ML on a growth substrate 101 through an epitaxial process, preparing a circuit board HS, manufacturing a unit module M by transferring the micro LEDs ML of the growth substrate 101 to the circuit board HS; and mounting the unit module M on a display wiring board DP.

Meanwhile, the step of preparing the first substrate provided with the micro LEDs ML may be a preparation step of transferring the micro LEDs ML from the growth substrate 101 to the carrier substrate C. In this case, the step of preparing the first substrate provided with the micro LEDs ML to manufacture the micro LED display D may be a preparation step of manufacturing the micro LEDs ML on the growth substrate 101 through the epitaxial process or may be a preparation step of transferring the micro LEDs ML from the growth substrate 101 to the carrier substrate C. In other words, the step of preparing the first substrate provided with the micro LEDs ML may be a preparation step of providing the same type of micro LEDs ML with a regular pitch. Alternatively, it may be a preparation step of providing different types of micro LEDs ML1, ML2, and ML3 to form a pixel array.

As illustrated in FIGS. 18(a) and 18(b), the micro LEDs ML1, ML2, and ML3 of the growth substrates 101a, 101b, and 101c and the carrier substrates C1, C2, and C3 are formed with a regular pitch.

As illustrated in FIGS. 18(a) and 18(b), the respective micro LEDs ML1, ML2, and ML3 of the growth substrates 101a, 101b, and 101c and the carrier substrates C1, C2, and C3 may be in a state in which different types of micro LEDs ML are prepared to form a pixel array before being transferred to the circuit board HS.

Therefore, even when the first substrate is classified as any one of the growth substrate 101 and the carrier substrate C in the step of preparing the first substrate provided with the micro LEDs ML to manufacture the micro LED display D, the step of preparing the first substrate may be a preparation step of providing the same type of micro LEDs ML to have a regular pitch or may be a preparation step of providing the different types of micro LEDs ML1, ML2, and ML3 to form a pixel array.

With reference to FIG. 18(b) again, a description will be given of a case where the step of preparing the first substrate provided with the micro LEDs ML is a preparation step of transferring the micro LEDs ML from the carrier substrate C. In this case, the step of preparing the circuit board HS may be performed to transfer the micro LEDs ML of the carrier substrate C to the circuit board HS. Then, the respective micro LEDs ML1, ML2, and ML3 of the carrier substrates C1, C2, and C3 may be transferred to the circuit board HS by the micro LED suction body, which is configured such that the first-direction pitch of the suction regions 2000 is M/3 times the first-direction pitch of the micro LEDs ML disposed on the first substrate and M is an integer equal to or greater than 4. This process may be performed in the unit module manufacturing step, and thus the unit module M may be manufactured.

The unit module M thus manufactured in the unit module manufacturing step may have a structure in which the different types of micro LEDs ML1, ML2, and ML3 are mounted to form a pixel array since it is manufactured by transferring the micro LEDs ML1, ML2, and ML3 of the carrier substrates C1, C2, and C3 to the circuit board HS by the micro LED suction body, which is configured such that the first-direction pitch of the suction regions 2000 is M/3 times the first-direction pitch of the micro LEDs ML disposed on the first substrate and M is an integer equal to or greater than 4.

The unit module M manufactured in the unit module manufacturing step may be transferred to the display wiring board DP. To transfer the unit module M to the display wiring board DP, the step of preparing the display wiring board DP may be performed. The unit module M may be transferred to the display wiring board DP thus prepared. The unit module M may be transferred to the display wiring board DP by an suction body that functions to transfer the unit module M to the display wiring board DP. In this case, the suction body may perform the step of mounting the unit module M on the display wiring board DP so that the micro LED pixel array in the display wiring board DP is formed to correspond to the micro LED pixel array in the unit module M and the pixel pitch of the pixel array in the display wiring board is equal to the pixel pitch of the pixel array in the unit module M. As a result, the micro LED display D may be manufactured.

As described above, the micro LED display D may be manufactured by the steps of preparing the first substrate provided with the micro LEDs ML by transferring the micro LEDs ML from the growth substrate 101 to the carrier substrate C, preparing the circuit board HS, manufacturing the unit module M by transferring the micro LEDs ML of the carrier substrate C to the circuit board HS, and mounting the unit module M on the display wiring board DP.

In the method of manufacturing the micro LED display D, the steps of preparing the first substrate provided with the micro LEDs ML, preparing the circuit board HS, and preparing the display wiring board DP are not performed sequentially. Therefore, the above steps may be performed without being limited to any order.

When the micro LED display D is manufactured using the micro LED suction body according to the present disclosure, it is possible to configure the multiple unit modules M, thereby easily performing inspection of normal and defective products and easily performing a repair process based on such inspection. This enables mounting of the unit module M composed only of normal micro LEDs on a large-area display, thereby improving the yield of a large-area display manufacturing process and reducing the manufacturing time. In addition, the structure in which the multiple unit modules M configured by transferring the micro LEDs ML to the circuit board HS enables the implementation of a borderless (bezel-less) large-area display.

The micro LED display D manufactured using the micro LED suction body according to the present disclosure may include the display wiring board DP and the multiple unit modules M coupled to the display wiring board DP. In this case, each of the unit modules M may be constructed by mounting the micro LEDs ML on the circuit board HS.

The display wiring board DP may be a wiring board capable of individually driving each of the multiple unit modules M. The unit modules M are bonded to the display wiring board DP so that each of the micro LEDs ML of each of the unit modules M can be individually driven by the display wiring board. The display wiring board DP may be provided with driving circuits in a number corresponding to the number of the micro LEDs ML to individually drive each of the micro LEDs ML.

On the other hand, the display wiring board DP may be a wiring board capable of individually driving each of the unit modules M. The unit modules M are bonded to the display wiring board DP so that each of the unit modules M can be individually driven by the display wiring board DP. Therefore, the display wiring board DP may be provided with driving circuits in a number corresponding to the number of the unit modules M to individually drive each of the unit modules M.

On the other hand, the display wiring board DP may be a wiring board capable of collectively driving all the micro LEDs ML of each of the unit modules M. The unit modules M are bonded to the display wiring board DP so that all the micro LEDs ML of the unit modules M can be driven collectively by the display wiring board DP. In other words, regardless of the number of the unit modules M and the number of the micro LEDs ML, the display wiring board DP may drive all the micro LEDs ML simultaneously.

The micro LED pixel array in the display wiring board DP may be formed to correspond to the micro LED pixel array in the unit modules M. In addition, the pixel pitch of the micro LED pixel array in the display wiring board DP may be equal to the pixel pitch of the micro LED pixel array in the unit modules M.

The micro LED pixel array in the unit modules M is a one-dimensional array of the red micro LEDs, the green micro LEDs, and the blue micro LEDs to form unit pixels. Here, the arrangement order of the unit pixels in row 1 and column M is equal to that of unit pixels in row 1 and column 1, and the arrangement order of the unit pixels in row N and column 1 and the arrangement order of the unit pixels in row N and column M are equal to that (GBR) of the unit pixels in row 11 and column 2. Here, M is an integer equal to or greater than 2, and N is a multiple of 3. Alternatively, the micro LED pixel array in the unit module M includes unit pixels in which the red micro LEDs, the green micro LEDs, and the blue micro LEDs are arranged in a two-dimensional array. Here, the unit pixels may be arranged in a matrix form with N rows and M columns. With such a configuration, even when the multiple unit modules M are disposed adjacent to each other on the display wiring board DP, the micro LED pixel array in the display wiring board DP may be formed to correspond to that in the unit modules M.

Assuming that the distance between adjacent unit pixels in each of the unit modules M is ‘d’, the distance between the outermost unit pixels at the end of the unit module M is less than half the distance d between the unit pixels. With such a configuration, even when the multiple unit modules M are disposed adjacent to each other on the display wiring board DP, the pixel pitch of the pixel array in the display wiring board DP may be equal to that of the pixel array in the unit modules M.

Since such a configuration is formed by mounting the multiple unit modules M on the display wiring board D, the micro LED pixel array and the pixel pitch of the pixel array in the display wiring board may be correspond to the micro LED pixel array and the pixel pitch of the pixel array in the unit module M.

Each of the unit modules M may be constructed by mounting the micro LEDs ML on the circuit board HS, and alternatively may be constructed by mounting the micro LEDs ML on an anisotropic conductive film. The anisotropic conductive film (ACF) is a state of containing multiple particles each of which a core of a conductive material is coated with an insulating film. When pressure or heat is applied to the anisotropic conductive film, the insulating film is broken only in a portion where the pressure or heat has been applied and thus the electrical connection is formed by the core. A release film may be further provided under the anisotropic conductive film. The release film is attached to a lower portion of the anisotropic conductive film to prevent particles from adhering to the lower portion of the anisotropic conductive film. The release film is configured to be easily removable when bonding the unit modules M to the display wiring board DP. When the unit modules M are mounted on the display wiring board DP, the release film attached to the lower portion of the anisotropic conductive film is separated. Then, the micro LEDs ML are subjected to thermocompression bonding from top to bottom so that the micro LEDs ML and individual electrodes formed on the display wiring board DP are electrically connected to each other. As a result, only a thermocompression-bonded portion has conductivity, so that the individual electrodes of the display wiring board DP and the micro LEDs ML are electrically connected to each other.

The micro LED pixel array of the micro LED display D illustrated in FIG. 18(d) is only an example. The micro LED pixel array of the micro LED display D may be configured such that a minimum pixel unit including a red micro LED ML1, a green micro LED ML2, and a blue micro LED ML3 is formed according to the arrangement of the suction regions of the micro LED suction body, and may be configured differently from the array in which the same type of micro LEDs ML are arranged in the same column, which is illustrated in FIG. 18(d).

As described above, the present disclosure has been described with reference to the exemplary embodiments. However, those skilled in the art will appreciate that various modifications, additions, and substitutions are possible, without departing from the scope and spirit of the disclosure as disclosed in the accompanying claims.

[Description of the Reference Numerals in the Drawings]

| 1, 1′, 1″, 1″′: micro LED suction body | |
|---|---|
| 1000: porous member | |
| 1100: first porous member, suction member | |
| 1200: second porous member, support member | |
| 1500, 1500′: suction hole | 1700: suction recess |
| 1800: receiving recess | 1900: escape recess |
| 2000: suction region | |
| 2100: non-suction region | |
| 2200: protruding region | 2300: first protruding dam |
| 2400: depression | 2500: land |
| 2600: buffer part | |
| 2700: terminal avoidance recess | |
| 2800: second protruding dam | 2900: protrusion |
| 3000: mask | |

ML: micro LED

1. A micro LED suction body, comprising:
a suction member embodied by an anodic aluminum oxide film having vertical pores; and
a support member having arbitrary pores and configured to support the suction member,
wherein the suction member includes suction regions configured to suck micro LEDs using a vacuum suction force and a non-suction region configured not to suck the micro LEDs, and selectively transfers the micro LEDs.

2. The micro LED suction body of claim 1, wherein the suction regions are formed by removing a barrier layer formed during manufacture of the anodic aluminum oxide film so that the vertical pores are formed to have open upper and lower ends.

3. The micro LED suction body of claim 1, wherein the suction regions are formed by suction holes having open upper and lower ends and having a width larger than that of the vertical pores formed during manufacture of the anodic aluminum oxide film.

4. The micro LED suction body of claim 1, wherein the non-suction region is formed by a shielding portion that closes at least one of the upper and lower ends of the vertical pores formed during manufacture of the anodic aluminum oxide film.

5. The micro LED suction body of claim 4, wherein the shielding portion is a barrier layer formed during manufacture of the anodic aluminum oxide film.

6. The micro LED suction body of claim 1, further comprising:
a buffer part provided on the suction member.

7. (canceled)

8. (canceled)

9. (canceled)

10. (canceled)

11. (canceled)

12. A micro LED suction body, comprising:
a suction member sucking micro LEDs, and including suction regions configured to suck micro LEDs and a non-suction region configured not to suck the micro LEDs;
a support member provided on the suction member and embodied by a porous material; and
a vacuum chamber,
wherein a vacuum pressure of the vacuum chamber is reduced by the porous material of the support member and then transmitted to the suction regions of the suction member, thereby causing the micro LEDs to be sucked, and
the vacuum pressure of the vacuum chamber is transmitted to the non-suction regions of the suction member through the porous material of the support member, thereby causing the suction member to be sucked.

13. The micro LED suction body of claim 12, wherein the suction regions are formed by suction holes passing through the suction member from top to bottom, and the non-suction region is a region where the suction holes are not formed.

14. The micro LED suction body of claim 12, wherein the suction member is made of at least one of an anodic aluminum oxide film, a wafer substrate, Invar, a metal, a non-metal, a polymer, paper, a photoresist, and PDMS.

15. (canceled)

16. (canceled)

17. A micro LED suction body of claim 1, further comprising:
a protrusion provided outside the suction member, and formed to protrude from a suction surface of the suction member.

18. The micro LED suction body of claim 17, wherein the protrusion is made of an elastic material.

19. (canceled)

20. (canceled)

21. (canceled)

22. (canceled)

23. (canceled)

24. A micro LED suction body of claim 1, wherein the micro LED suction body selectively sucks the micro LEDs disposed on a first substrate, and
a first-direction pitch of the suction regions is M/3 times a first-direction pitch of the micro LEDs disposed on the first substrate, wherein M is an integer equal to or greater than 4.

25. A method of manufacturing a micro LED display using the micro LED suction body of claim 1.

26. A method of manufacturing a micro LED display, comprising:
preparing a first substrate provided with micro LEDs;
preparing a circuit board; and
manufacturing a unit module by transferring the micro LEDs of the first substrate to the circuit board using a micro LED suction body being configured such that a first-direction pitch of suction regions is M/3 times a first-direction pitch of the micro LEDs disposed on the first substrate, in which M is an integer equal to or greater than 4.

27. The method of claim 26, further comprising:
preparing a display wiring board; and
mounting the unit module on the display wiring board by transferring the unit module to the display wiring board so that a micro LED pixel array in the display wiring board is formed to correspond to a micro LED pixel array in the unit module and a pixel pitch of the pixel array in the display wiring board is equal to a pixel pitch of the pixel array in the unit module.

28. (canceled)

29. (canceled)

30. (canceled)

31. (canceled)
